(19) United States
(12) Patent Application Publication
(10) Pub. No.: US 2022/0099813 A1
(43) Pub. Date: Mar. 31, 2022

(54) LIDAR SYSTEM WITH LOW-NOISE AVALANCHE PHOTODIODE

(71) Applicant: Luminar, LLC, Orlando, FL (US)

(72) Inventors: James L. Gates, Las Vegas, NV (US); Joseph G. LaChapelle, Philomath, OR (US); Jason M. Eichenholz, Orlando, FL (US); Stephen D. Gaalema, Colorado Springs, CO (US)

(21) Appl. No.: 17/475,956

(22) Filed: Sep. 15, 2021

Related U.S. Application Data
(60) Provisional application No. 63/084,221, filed on Sep. 28, 2020.

(51) Int. Cl. G01S 7/4863; G01S 17/08; H01L 31/107

(52) U.S. Cl. CPC G01S 7/4863; H01L 31/107; G01S 17/08

(57) ABSTRACT

In one embodiment, a lidar system includes a light source configured to emit an optical signal and a receiver configured to detect an input optical signal that includes a portion of the emitted optical signal scattered by a target located a distance from the lidar system. The receiver includes an avalanche photodiode (APD) configured to receive the input optical signal and produce a photocurrent signal corresponding to the input optical signal. The APD includes a multiplication region that includes a digital-alloy region that includes two or more semiconductor alloy materials arranged in successive layers. The digital-alloy region is configured to produce at least a portion of the photocurrent signal by impact ionization. The receiver is configured to determine, based on the photocurrent signal produced by the APD, a round-trip time for the portion of the emitted optical signal to travel to the target and back to the lidar system.

### CROSS-REFERENCE TO RELATED APPLICATIONS

This application claims the benefit of U.S. Provisional Patent Application No. 63/084,221, filed 28 Sep. 2020, which is incorporated by reference herein in its entirety.

### TECHNICAL FIELD

This disclosure generally relates to lidar systems.

### BACKGROUND

Light detection and ranging (lidar) is a technology that can be used to measure distances to remote targets. Typically, a lidar system includes a light source and an optical receiver. The light source can include, for example, a laser which emits light having a particular operating wavelength. The operating wavelength of a lidar system may lie, for example, in the infrared, visible, or ultraviolet portions of the electromagnetic spectrum. The light source emits light toward a target which scatters the light, and some of the scattered light is received back at the receiver. The system determines the distance to the target based on one or more characteristics associated with the received light. For example, the lidar system may determine the distance to the target based on the time of flight for a pulse of light emitted by the light source to travel to the target and back to the lidar system.

### BRIEF DESCRIPTION OF THE DRAWINGS

FIG. 1 illustrates an example light detection and ranging (lidar) system.

FIG. 2 illustrates an example scan pattern produced by a lidar system.

FIG. 3 illustrates an example lidar system with an example rotating polygon mirror.

FIG. 4 illustrates an example light-source field of view (FOV_{L}) and receiver field of view (FOV_{R}) for a lidar system.

FIG. 5 illustrates an example unidirectional scan pattern that includes multiple pixels and multiple scan lines.

FIG. 6 illustrates an example light-source field of view and receiver field of view with a corresponding scan direction.

FIG. 7 illustrates an example receiver field of view that is offset from a light-source field of view.

FIG. 8 illustrates an example forward-scan direction and reverse-scan direction for a light-source field of view and a receiver field of view.

FIG. 9 illustrates an example receiver that includes an avalanche photodiode (APD) coupled to a signal-detection circuit.

FIG. 10 illustrates an example receiver and an example voltage signal corresponding to a received pulse of light.

FIGS. 11 and 12 each illustrates an example avalanche photodiode.

FIGS. 13 and 14 each illustrates an example planar avalanche photodiode.

FIGS. 15 and 16 each illustrates an example avalanche photodiode with an indium-aluminum-arsenide (InAlAs) multiplication region.

FIGS. 17 and 18 each illustrates an example avalanche photodiode with an aluminum-indium-arsenide-antimonide (AlInAsSb) multiplication region.

FIG. 19 illustrates an example ternary random alloy.

FIG. 20 illustrates an example quaternary random alloy.

FIG. 21 illustrates an example ternary digital alloy.

FIG. 22 illustrates an example quaternary digital alloy.

FIG. 23 illustrates an example InAlAs random alloy.

FIG. 24 illustrates an example InAlAs digital alloy.

FIG. 25 illustrates an example AlAsSb random alloy.

FIG. 26 illustrates an example AlAsSb digital alloy.

FIG. 27 illustrates an example InGaAlAs random alloy.

FIG. 28 illustrates an example InGaAlAs digital alloy.

FIG. 29 illustrates an example AlInAsSb random alloy.

FIG. 30 illustrates an example AlInAsSb digital alloy.

FIG. 31 illustrates an example AlGaAsSb random alloy.

FIG. 32 illustrates an example AlGaAsSb digital alloy.

FIG. 33 illustrates an example avalanche photodiode with a multiplication region that includes a digital alloy.

FIG. 34 illustrates an example avalanche photodiode with a multiplication region that includes a random alloy and a digital alloy.

FIG. 35 illustrates an example avalanche photodiode with a multiplication region that includes two digital alloys.

FIG. 36 illustrates an example avalanche photodiode with a multiplication region that includes a random alloy and two digital alloys.

FIG. 37 illustrates an example avalanche photodiode with a multiplication region that includes a digital alloy and two random alloys.

FIG. 38 illustrates an example avalanche photodiode with a multiplication region that includes three digital alloys.

FIG. 39 illustrates an example avalanche photodiode with a multiplication region that includes two random alloys and two digital alloys.

FIG. 40 illustrates an example avalanche photodiode with multiple cascaded multiplication regions.

FIG. 41 illustrates an example computer system.

### DESCRIPTION OF EXAMPLE EMBODIMENTS

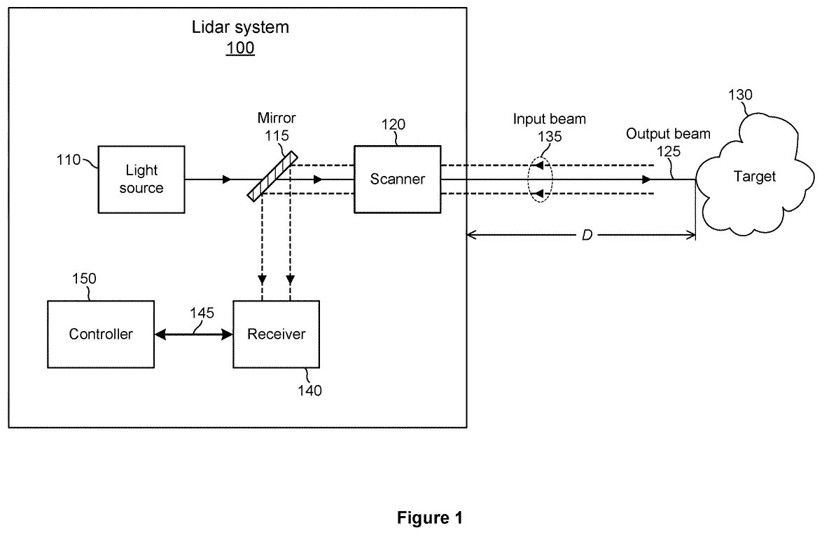

FIG. 1 illustrates an example light detection and ranging (lidar) system 100. In particular embodiments, a lidar system 100 may be referred to as a laser ranging system, a laser radar system, a LIDAR system, a lidar sensor, or a laser detection and ranging (LADAR or ladar) system. In particular embodiments, a lidar system 100 may include a light source 110, mirror 115, scanner 120, receiver 140, or controller 150. The light source 110 may include, for example, a laser which emits light having a particular operating wavelength in the infrared, visible, or ultraviolet portions of the electromagnetic spectrum. As an example, light source 110 may include a laser with one or more operating wavelengths between approximately 900 nanometers (nm) and 2000 nm. The light source 110 emits an output beam of light 125 which may be continuous wave (CW), pulsed, or modulated in any suitable manner for a given application. The output beam of light 125 is directed downrange toward a remote target 130. As an example, the remote target 130 may be located a distance D of approximately 1 m to 1 km from the lidar system 100.

Once the output beam 125 reaches the downrange target 130, the target may scatter or reflect at least a portion of light from the output beam 125, and some of the scattered or reflected light may return toward the lidar system 100. In the example of FIG. 1, the scattered or reflected light is represented by input beam 135, which passes through scanner 120 and is reflected by mirror 115 and directed to receiver 140. In particular embodiments, a relatively small fraction of the light from output beam 125 may return to the lidar system 100 as input beam 135. As an example, the ratio of input beam 135 average power, peak power, or pulse energy to output beam 125 average power, peak power, or pulse energy may be approximately 10⁻¹, 10⁻², 10⁻³, 10⁻⁴, 10⁻⁵, 10⁻⁶, 10⁻⁷, 10⁻⁸, 10⁻⁹, 10⁻¹⁰, 10⁻¹¹, or 10⁻¹². As another example, if a pulse of output beam 125 has a pulse energy of 1 microjoule (μJ), then the pulse energy of a corresponding pulse of input beam 135 may have a pulse energy of approximately 10 nanojoules (nJ), 1 nJ, 100 picojoules (pJ), 10 pJ, 1 pJ, 100 femtojoules (fJ), 10 fJ, 1 fJ, 100 attojoules (aJ), 10 aJ, 1 aJ, or 0.1 aJ.

In particular embodiments, output beam 125 may include or may be referred to as an optical signal, output optical signal, emitted optical signal, emitted pulse of light, laser beam, light beam, optical beam, emitted beam, emitted light, or beam. In particular embodiments, input beam 135 may include or may be referred to as a received optical signal, received pulse of light, input pulse of light, input optical signal, input signal, return beam, received beam, return light, received light, input light, scattered light, or reflected light. As used herein, scattered light may refer to light that is scattered or reflected by a target 130. As an example, an input beam 135 may include: light from the output beam 125 that is scattered by target 130; light from the output beam 125 that is reflected by target 130; or a combination of scattered and reflected light from target 130.

In particular embodiments, receiver 140 may receive or detect photons from input beam 135 and produce one or more representative signals. For example, the receiver 140 may produce an output electrical signal 145 that is representative of the input beam 135, and the electrical signal 145 may be sent to controller 150. In particular embodiments, receiver 140 or controller 150 may include a processor, computing system (e.g., an ASIC or FPGA), or other suitable circuitry. A controller 150 may be configured to analyze one or more characteristics of the electrical signal 145 from the receiver 140 to determine one or more characteristics of the target 130, such as its distance downrange from the lidar system 100. This may be done, for example, by analyzing a time of flight or a frequency or phase of a transmitted beam of light 125 or a received beam of light 135. If lidar system 100 measures a time of flight of T (e.g., T represents a round-trip time of flight for an emitted pulse of light to travel from the lidar system 100 to the target 130 and back to the lidar system 100), then the distance D from the target 130 to the lidar system 100 may be expressed as D=c·T/2, where c is the speed of light (approximately 3.0×10⁸ m/s). As an example, if a time of flight is measured to be T=300 ns, then the distance from the target 130 to the lidar system 100 may be determined to be approximately D=45.0 m. As another example, if a time of flight is measured to be T=1.33 μs, then the distance from the target 130 to the lidar system 100 may be determined to be approximately D=199.5 m. In particular embodiments, a distance D from lidar system 100 to a target 130 may be referred to as a distance, depth, or range of target 130. As used herein, the speed of light c refers to the speed of light in any suitable medium, such as for example in air, water, or vacuum. As an example, the speed of light in vacuum is approximately 2.9979×10⁸ m/s, and the speed of light in air (which has a refractive index of approximately 1.0003) is approximately 2.9970×10⁸ m/s.

In particular embodiments, light source 110 may include a pulsed or CW laser. As an example, light source 110 may be a pulsed laser configured to produce or emit pulses of light with a pulse duration or pulse width of approximately 10 picoseconds (ps) to 100 nanoseconds (ns). The pulses may have a pulse duration of approximately 100 ps, 200 ps, 400 ps, 1 ns, 2 ns, 5 ns, 10 ns, 20 ns, 50 ns, 100 ns, or any other suitable pulse duration. As another example, light source 110 may be a pulsed laser that produces pulses with a pulse duration of approximately 1-5 ns. As another example, light source 110 may be a pulsed laser that produces pulses at a pulse repetition frequency of approximately 80 kHz to 10 MHz or a pulse period (e.g., a time between consecutive pulses) of approximately 100 ns to 12.5 μs. In particular embodiments, light source 110 may have a substantially constant pulse repetition frequency, or light source 110 may have a variable or adjustable pulse repetition frequency. As an example, light source 110 may be a pulsed laser that produces pulses at a substantially constant pulse repetition frequency of approximately 640 kHz (e.g., 640,000 pulses per second), corresponding to a pulse period of approximately 1.56 μs. As another example, light source 110 may have a pulse repetition frequency (which may be referred to as a repetition rate) that can be varied from approximately 200 kHz to 3 MHz. As used herein, a pulse of light may be referred to as an optical pulse, a light pulse, or a pulse.

In particular embodiments, light source 110 may include a pulsed or CW laser that produces a free-space output beam 125 having any suitable average optical power. As an example, output beam 125 may have an average power of approximately 1 milliwatt (mW), 10 mW, 100 mW, 1 watt (W), 10 W, or any other suitable average power. In particular embodiments, output beam 125 may include optical pulses with any suitable pulse energy or peak optical power. As an example, output beam 125 may include pulses with a pulse energy of approximately 0.01 μJ, 0.1 μJ, 0.5 μJ, 1 μJ, 2 μJ, 10 μJ, 100 μJ, 1 mJ, or any other suitable pulse energy. As another example, output beam 125 may include pulses with a peak power of approximately 10 W, 100 W, 1 kW, 5 kW, 10 kW, or any other suitable peak power. The peak power (Pₚₑₐₖ) of a pulse of light can be related to the pulse energy (E) by the expression E=Pₚₑₐₖ·Δt, where Δt is the duration of the pulse, and the duration of a pulse may be defined as the full width at half maximum duration of the pulse. For example, an optical pulse with a duration of 1 ns and a pulse energy of 1 μJ has a peak power of approximately 1 kW. The average power (Pₐᵥ) of an output beam 125 can be related to the pulse repetition frequency (PRF) and pulse energy by the expression Pₐᵥ=PRF·E. For example, if the pulse repetition frequency is 500 kHz, then the average power of an output beam 125 with 1-0 pulses is approximately 0.5 W.

In particular embodiments, light source 110 may include a laser diode, such as for example, a Fabry-Perot laser diode, a quantum well laser, a distributed Bragg reflector (DBR) laser, a distributed feedback (DFB) laser, a vertical-cavity surface-emitting laser (VCSEL), a quantum dot laser diode, a grating-coupled surface-emitting laser (GCSEL), a slab-coupled optical waveguide laser (SCOWL), a single-transverse-mode laser diode, a multi-mode broad area laser diode, a laser-diode bar, a laser-diode stack, or a tapered-stripe laser diode. As an example, light source 110 may include an aluminum-gallium-arsenide (AlGaAs) laser diode, an indium-gallium-arsenide (InGaAs) laser diode, an indium-gallium-arsenide-phosphide (InGaAsP) laser diode, or a laser diode that includes any suitable combination of aluminum (Al), indium (In), gallium (Ga), arsenic (As), phosphorous (P), or any other suitable material. In particular embodiments, light source 110 may include a pulsed or CW laser diode with a peak emission wavelength between 1200 nm and 1600 nm. As an example, light source 110 may include a current-modulated InGaAsP DFB laser diode that produces optical pulses at a wavelength of approximately 1550 nm. As another example, light source 110 may include a laser diode that emits light at a wavelength between 1500 nm and 1510 nm.

In particular embodiments, light source 110 may include a pulsed or CW laser diode followed by one or more optical-amplification stages. For example, a seed laser diode may produce a seed optical signal, and an optical amplifier may amplify the seed optical signal to produce an amplified optical signal that is emitted by the light source 110. In particular embodiments, an optical amplifier may include a fiber-optic amplifier or a semiconductor optical amplifier (SOA). For example, a pulsed seed laser diode may produce relatively low-power optical seed optical pulses which are amplified by a fiber-optic amplifier. As another example, a light source 110 may include a fiber-laser module that includes a current-modulated seed laser diode with an operating wavelength of approximately 1550 nm followed by a single-stage or a multi-stage erbium-doped fiber amplifier (EDFA) or erbium-ytterbium-doped fiber amplifier (EYDFA) that amplifies the seed light from the laser diode. As another example, light source 110 may include a continuous-wave (CW) or quasi-CW laser diode followed by an external optical modulator (e.g., an electro-optic amplitude modulator). The optical modulator may modulate the CW light from the laser diode to produce optical pulses which are sent to a fiber-optic amplifier or SOA. As another example, light source 110 may include a pulsed or CW seed laser diode followed by a semiconductor optical amplifier (SOA). The SOA may include an active optical waveguide configured to receive a seed optical signal (e.g., pulses of light or CW light) from the seed laser diode and amplify the seed optical signal as it propagates through the waveguide. For example, the seed laser diode may produce relatively low-power seed optical pulses, and the SOA may receive pulses of electrical current to amplify each seed optical pulse and produce emitted pulses of light. As another example, the seed laser diode may produce CW seed light, and the SOA may receive pulses of electrical current, where each pulse of electrical current causes the SOA to amplify a temporal portion of the seed light to produce an emitted pulse of light. The optical gain of the SOA may be provided by pulsed or direct-current (DC) electrical current supplied to the SOA. The SOA may be integrated on the same chip as the seed laser diode, or the SOA may be a separate device with an anti-reflection coating on its input facet or output facet. As another example, light source 110 may include a seed laser diode followed by a SOA, which in turn is followed by a fiber-optic amplifier. For example, the seed laser diode may produce CW light or relatively low-power seed optical pulses, and the SOA may amplify the seed light to produce optical pulses. The fiber-optic amplifier may further amplify the optical pulses to produce emitted pulses of light.

In particular embodiments, light source 110 may include a direct-emitter laser diode configured to produce an output beam 125. A direct-emitter laser diode (which may be referred to as a direct emitter) may include a laser diode which produces light that is not subsequently amplified by an optical amplifier. A light source 110 that includes a direct-emitter laser diode may not include an optical amplifier, and the output light produced by a direct emitter may not be amplified after it is emitted by the laser diode. The light produced by a direct-emitter laser diode (e.g., optical pulses, CW light, or frequency-modulated light) may be emitted directly as a free-space output beam 125 without being amplified. For example, a direct-emitter laser diode may be driven by an electrical power source that supplies current pulses to the laser diode, and each current pulse may result in the emission of an output optical pulse. A direct-emitter light source 110 may include a collimating lens that receives the light produced by a direct-emitter laser diode and collimates the light to produce a collimated output beam 125 that is directed to a scanner 120 (without an intervening optical amplifier located between the direct-emitter laser diode and the scanner).

In particular embodiments, light source 110 may include a diode-pumped solid-state (DPSS) laser. A DPSS laser (which may be referred to as a solid-state laser) may refer to a laser that includes a solid-state, glass, ceramic, or crystal-based gain medium that is pumped by one or more pump laser diodes. The gain medium may include a host material that is doped with rare-earth ions (e.g., neodymium, erbium, ytterbium, or praseodymium). For example, a gain medium may include a yttrium aluminum garnet (YAG) crystal that is doped with neodymium (Nd) ions, and the gain medium may be referred to as a Nd:YAG crystal. A DPSS laser with a Nd:YAG gain medium may produce light at a wavelength between approximately 1300 nm and approximately 1400 nm, and the Nd:YAG gain medium may be pumped by one or more pump laser diodes with an operating wavelength between approximately 730 nm and approximately 900 nm. A DPSS laser may be a passively Q-switched laser that includes a saturable absorber (e.g., a vanadium-doped crystal that acts as a saturable absorber). Alternatively, a DPSS laser may be an actively Q-switched laser that includes an active Q-switch (e.g., an acousto-optic modulator or an electro-optic modulator). A passively or actively Q-switched DPSS laser may produce output optical pulses that form an output beam 125 of a lidar system 100.

In particular embodiments, an output beam of light 125 emitted by light source 110 may be a collimated optical beam having any suitable beam divergence, such as for example, a full-angle beam divergence of approximately 0.5 to 10 milliradians (mrad). A divergence of output beam 125 may refer to an angular measure of an increase in beam size (e.g., a beam radius or beam diameter) as output beam 125 travels away from light source 110 or lidar system 100. In particular embodiments, output beam 125 may have a substantially circular cross section with a beam divergence characterized by a single divergence value. As an example, an output beam 125 with a circular cross section and a full-angle beam divergence of 2 mrad may have a beam diameter or spot size of approximately 20 cm at a distance of 100 m from lidar system 100. In particular embodiments, output beam 125 may have a substantially elliptical cross section characterized by two divergence values. As an example, output beam 125 may have a fast axis and a slow axis, where the fast-axis divergence is greater than the slow-axis divergence. As another example, output beam 125 may be an elliptical beam with a fast-axis divergence of 4 mrad and a slow-axis divergence of 2 mrad.

In particular embodiments, an output beam of light 125 emitted by light source 110 may be unpolarized or randomly polarized, may have no specific or fixed polarization (e.g., the polarization may vary with time), or may have a particular polarization (e.g., output beam 125 may be linearly polarized, elliptically polarized, or circularly polarized). As an example, light source 110 may produce light with no specific polarization or may produce light that is linearly polarized.

In particular embodiments, lidar system 100 may include one or more optical components configured to reflect, focus, filter, shape, modify, steer, or direct light within the lidar system 100 or light produced or received by the lidar system 100 (e.g., output beam 125 or input beam 135). As an example, lidar system 100 may include one or more lenses, mirrors, filters (e.g., bandpass or interference filters), beam splitters, polarizers, polarizing beam splitters, wave plates (e.g., half-wave or quarter-wave plates), diffractive elements, holographic elements, isolators, couplers, detectors, beam combiners, or collimators. The optical components in a lidar system 100 may be free-space optical components, fiber-coupled optical components, or a combination of free-space and fiber-coupled optical components.

In particular embodiments, lidar system 100 may include a telescope, one or more lenses, or one or more mirrors configured to expand, focus, or collimate the output beam 125 or the input beam 135 to a desired beam diameter or divergence. As an example, the lidar system 100 may include one or more lenses to focus the input beam 135 onto a photodetector of receiver 140. As another example, the lidar system 100 may include one or more flat mirrors or curved mirrors (e.g., concave, convex, or parabolic mirrors) to steer or focus the output beam 125 or the input beam 135. For example, the lidar system 100 may include an off-axis parabolic mirror to focus the input beam 135 onto a photodetector of receiver 140. As illustrated in FIG. 1, the lidar system 100 may include mirror 115 (which may be a metallic or dielectric mirror), and mirror 115 may be configured so that light beam 125 passes through the mirror 115 or passes along an edge or side of the mirror 115 and input beam 135 is reflected toward the receiver 140. As an example, mirror 115 (which may be referred to as an overlap mirror, superposition mirror, or beam-combiner mirror) may include a hole, slot, or aperture which output light beam 125 passes through. As another example, rather than passing through the mirror 115, the output beam 125 may be directed to pass alongside the mirror 115 with a gap (e.g., a gap of width approximately 0.1 mm, 0.5 mm, 1 mm, 2 mm, 5 mm, or 10 mm) between the output beam 125 and an edge of the mirror 115.

In particular embodiments, mirror 115 may provide for output beam 125 and input beam 135 to be substantially coaxial so that the two beams travel along approximately the same optical path (albeit in opposite directions). The input and output beams being substantially coaxial may refer to the beams being at least partially overlapped or sharing a common propagation axis so that input beam 135 and output beam 125 travel along substantially the same optical path (albeit in opposite directions). As an example, output beam 125 and input beam 135 may be parallel to each other to within less than 10 mrad, 5 mrad, 2 mrad, 1 mrad, 0.5 mrad, or 0.1 mrad. As output beam 125 is scanned across a field of regard, the input beam 135 may follow along with the output beam 125 so that the coaxial relationship between the two beams is maintained.

In particular embodiments, lidar system 100 may include a scanner 120 configured to scan an output beam 125 across a field of regard of the lidar system 100. As an example, scanner 120 may include one or more scanning mirrors configured to pivot, rotate, oscillate, or move in an angular manner about one or more rotation axes. The output beam 125 may be reflected by a scanning mirror, and as the scanning mirror pivots or rotates, the reflected output beam 125 may be scanned in a corresponding angular manner. As an example, a scanning mirror may be configured to periodically pivot back and forth over a 30-degree range, which results in the output beam 125 scanning back and forth across a 60-degree range (e.g., a 0-degree rotation by a scanning mirror results in a 20-degree angular scan of output beam 125).

In particular embodiments, a scanning mirror (which may be referred to as a scan mirror) may be attached to or mechanically driven by a scanner actuator or mechanism which pivots or rotates the mirror over a particular angular range (e.g., over a 5° angular range, 30° angular range, 60° angular range, 120° angular range, 360° angular range, or any other suitable angular range). A scanner actuator or mechanism configured to pivot or rotate a mirror may include a galvanometer scanner, a resonant scanner, a piezoelectric actuator, a voice coil motor, an electric motor (e.g., a DC motor, a brushless DC motor, a synchronous electric motor, or a stepper motor), a microelectromechanical systems (MEMS) device, or any other suitable actuator or mechanism. As an example, a scanner 120 may include a scanning mirror attached to a galvanometer scanner configured to pivot back and forth over a 1° to 30° angular range. As another example, a scanner 120 may include a scanning mirror that is attached to or is part of a MEMS device configured to scan over a 1° to 30° angular range. As another example, a scanner 120 may include a polygon mirror configured to rotate continuously in the same direction (e.g., rather than pivoting back and forth, the polygon mirror continuously rotates 360 degrees in a clockwise or counterclockwise direction). The polygon mirror may be coupled or attached to a synchronous motor configured to rotate the polygon mirror at a substantially fixed rotational frequency (e.g., a rotational frequency of approximately 1 Hz, 10 Hz, 50 Hz, 100 Hz, 500 Hz, or 1,000 Hz).

In particular embodiments, scanner 120 may be configured to scan the output beam 125 (which may include at least a portion of the light emitted by light source 110) across a field of regard of the lidar system 100. A field of regard (FOR) of a lidar system 100 may refer to an area, region, or angular range over which the lidar system 100 may be configured to scan or capture distance information. As an example, a lidar system 100 with an output beam 125 with a 30-degree scanning range may be referred to as having a 30-degree angular field of regard. As another example, a lidar system 100 with a scanning mirror that rotates over a 30-degree range may produce an output beam 125 that scans across a 60-degree range (e.g., a 60-degree FOR). In particular embodiments, lidar system 100 may have a FOR of approximately 10°, 20°, 40°, 60°, 120°, 360°, or any other suitable FOR.

In particular embodiments, scanner 120 may be configured to scan the output beam 125 horizontally and vertically, and lidar system 100 may have a particular FOR along the horizontal direction and another particular FOR along the vertical direction. As an example, lidar system 100 may have a horizontal FOR of 10° to 120° and a vertical FOR of 2° to 45°. In particular embodiments, scanner 120 may include a first scan mirror and a second scan mirror, where the first scan mirror directs the output beam 125 toward the second scan mirror, and the second scan mirror directs the output beam 125 downrange from the lidar system 100. As an example, the first scan mirror may scan the output beam 125 along a first direction, and the second scan mirror may scan the output beam 125 along a second direction that is different from the first direction. As another example, the first scan mirror may scan the output beam 125 along a substantially horizontal direction, and the second scan mirror may scan the output beam 125 along a substantially vertical direction (or vice versa). As another example, the first and second scan mirrors may each be driven by galvanometer scanners. As another example, the first or second scan mirror may include a polygon mirror driven by an electric motor. In particular embodiments, scanner 120 may be referred to as a beam scanner, optical scanner, or laser scanner.

In particular embodiments, one or more scanning mirrors may be communicatively coupled to controller 150 which may control the scanning mirror(s) so as to guide the output beam 125 in a desired direction downrange or along a desired scan pattern. In particular embodiments, a scan pattern may refer to a pattern or path along which the output beam 125 is directed. As an example, scanner 120 may include two scanning mirrors configured to scan the output beam 125 across a 60° horizontal FOR and a 20° vertical FOR. The two scanner mirrors may be controlled to follow a scan path that substantially covers the 60°×20° FOR. As an example, the scan path may result in a point cloud with pixels that substantially cover the 60°×20° FOR. The pixels may be approximately evenly distributed across the 60°×20° FOR. Alternatively, the pixels may have a particular nonuniform distribution (e.g., the pixels may be distributed across all or a portion of the 60°×20° FOR, and the pixels may have a higher density in one or more particular regions of the 60°×20° FOR).

In particular embodiments, a lidar system 100 may include a scanner 120 with a solid-state scanning device. A solid-state scanning device may refer to a scanner 120 that scans an output beam 125 without the use of moving parts (e.g., without the use of a mechanical scanner, such as a mirror that rotates or pivots). For example, a solid-state scanner 120 may include one or more of the following: an optical phased array scanning device; a liquid-crystal scanning device; or a liquid lens scanning device. A solid-state scanner 120 may be an electrically addressable device that scans an output beam 125 along one axis (e.g., horizontally) or along two axes (e.g., horizontally and vertically). In particular embodiments, a scanner 120 may include a solid-state scanner and a mechanical scanner. For example, a scanner 120 may include an optical phased array scanner configured to scan an output beam 125 in one direction and a galvanometer scanner that scans the output beam 125 in an orthogonal direction. The optical phased array scanner may scan the output beam relatively rapidly in a horizontal direction across the field of regard (e.g., at a scan rate of 50 to 1,000 scan lines per second), and the galvanometer may pivot a mirror at a rate of 1-30 Hz to scan the output beam 125 vertically.

In particular embodiments, a lidar system 100 may include a light source 110 configured to emit pulses of light and a scanner 120 configured to scan at least a portion of the emitted pulses of light across a field of regard of the lidar system 100. One or more of the emitted pulses of light may be scattered by a target 130 located downrange from the lidar system 100, and a receiver 140 may detect at least a portion of the pulses of light scattered by the target 130. A receiver 140 may be referred to as a photoreceiver, optical receiver, optical sensor, detector, photodetector, or optical detector. In particular embodiments, lidar system 100 may include a receiver 140 that receives or detects at least a portion of input beam 135 and produces an electrical signal that corresponds to input beam 135. As an example, if input beam 135 includes an optical pulse, then receiver 140 may produce an electrical current or voltage pulse that corresponds to the optical pulse detected by receiver 140. As another example, receiver 140 may include one or more avalanche photodiodes (APDs) or one or more single-photon avalanche diodes (SPADs). As another example, receiver 140 may include one or more PN photodiodes (e.g., a photodiode structure formed by a p-type semiconductor and a n-type semiconductor, where the PN acronym refers to the structure having p-doped and n-doped regions) or one or more PIN photodiodes (e.g., a photodiode structure formed by an undoped intrinsic semiconductor region located between p-type and n-type regions, where the PIN acronym refers to the structure having p-doped, intrinsic, and n-doped regions). An APD, SPAD, PN photodiode, or PIN photodiode may each be referred to as a detector, photodetector, or photodiode. A detector may have an active region or an avalanche-multiplication region that includes silicon, germanium, InGaAs, or AlInAsSb (aluminum indium arsenide antimonide). The active region may refer to an area over which a detector may receive or detect input light. An active region may have any suitable size or diameter, such as for example, a diameter of approximately 10 micrometers (μm), 25 μm, 50 μm, 80 μm, 100 μm, 200 μm, 500 μm, 1 mm, 2 mm, or 5 mm.

In particular embodiments, receiver 140 may include electronic circuitry that performs signal amplification, sampling, filtering, signal conditioning, analog-to-digital conversion, time-to-digital conversion, pulse detection, threshold detection, rising-edge detection, or falling-edge detection. As an example, receiver 140 may include a transimpedance amplifier that converts a received photocurrent (e.g., a current produced by an APD in response to a received optical signal) into a voltage signal. The voltage signal may be sent to signal-detection circuitry that produces an analog or digital output signal 145 that corresponds to one or more optical characteristics (e.g., rising edge, falling edge, amplitude, duration, or energy) of a received optical pulse. As an example, the signal-detection circuitry may perform a time-to-digital conversion to produce a digital output signal 145. The electrical output signal 145 may be sent to controller 150 for processing or analysis (e.g., to determine a time-of-flight value corresponding to a received optical pulse).

In particular embodiments, a controller 150 (which may include or may be referred to as a processor, an FPGA, an ASIC, a computer, or a computing system) may be located within a lidar system 100 or outside of a lidar system 100. Alternatively, one or more parts of a controller 150 may be located within a lidar system 100, and one or more other parts of a controller 150 may be located outside a lidar system 100. In particular embodiments, one or more parts of a controller 150 may be located within a receiver 140 of a lidar system 100, and one or more other parts of a controller 150 may be located in other parts of the lidar system 100. For example, a receiver 140 may include an FPGA or ASIC configured to process an output electrical signal from the receiver 140, and the processed signal may be sent to a computing system located elsewhere within the lidar system 100 or outside the lidar system 100. In particular embodiments, a controller 150 may include any suitable arrangement or combination of logic circuitry, analog circuitry, or digital circuitry.

In particular embodiments, controller 150 may be electrically coupled or communicatively coupled to light source 110, scanner 120, or receiver 140. As an example, controller 150 may receive electrical trigger pulses or edges from light source 110, where each pulse or edge corresponds to the emission of an optical pulse by light source 110. As another example, controller 150 may provide instructions, a control signal, or a trigger signal to light source 110 indicating when light source 110 should produce optical pulses. Controller 150 may send an electrical trigger signal that includes electrical pulses, where each electrical pulse results in the emission of an optical pulse by light source 110. In particular embodiments, the frequency, period, duration, pulse energy, peak power, average power, or wavelength of the optical pulses produced by light source 110 may be adjusted based on instructions, a control signal, or trigger pulses provided by controller 150. In particular embodiments, controller 150 may be coupled to light source 110 and receiver 140, and controller 150 may determine a time-of-flight value for an optical pulse based on timing information associated with when the pulse was emitted by light source 110 and when a portion of the pulse (e.g., input beam 135) was detected or received by receiver 140. In particular embodiments, controller 150 may include circuitry that performs signal amplification, sampling, filtering, signal conditioning, analog-to-digital conversion, time-to-digital conversion, pulse detection, threshold detection, rising-edge detection, or falling-edge detection.

In particular embodiments, lidar system 100 may include one or more processors (e.g., a controller 150) configured to determine a distance D from the lidar system 100 to a target 130 based at least in part on a round-trip time of flight for an emitted pulse of light to travel from the lidar system 100 to the target 130 and back to the lidar system 100. The target 130 may be at least partially contained within a field of regard of the lidar system 100 and located a distance D from the lidar system 100 that is less than or equal to an operating range (R_{OP}) of the lidar system 100. In particular embodiments, an operating range (which may be referred to as an operating distance) of a lidar system 100 may refer to a distance over which the lidar system 100 is configured to sense or identify targets 130 located within a field of regard of the lidar system 100. The operating range of lidar system 100 may be any suitable distance, such as for example, 25 m, 50 m, 100 m, 200 m, 250 m, 500 m, or 1 km. As an example, a lidar system 100 with a 200-m operating range may be configured to sense or identify various targets 130 located up to 200 m away from the lidar system 100. The operating range R_{OP} of a lidar system 100 may be related to the time τ between the emission of successive optical signals by the expression R_{OP}=c·τ/2. For a lidar system 100 with a 200-m operating range (R_{OP}=200 m), the time τ between successive pulses (which may be referred to as a pulse period, a pulse repetition interval (PRI), or a time period between pulses) is approximately 2·R_{OP}/c≅1.33 μs. The pulse period τ may also correspond to the time of flight for a pulse to travel to and from a target 130 located a distance R_{OP} from the lidar system 100. Additionally, the pulse period τ may be related to the pulse repetition frequency (PRF) by the expression τ=1/PRF. For example, a pulse period of 1.33 μs corresponds to a PRF of approximately 752 kHz.

In particular embodiments, a lidar system 100 may be used to determine the distance to one or more downrange targets 130. By scanning the lidar system 100 across a field of regard, the system may be used to map the distance to a number of points within the field of regard. Each of these depth-mapped points may be referred to as a pixel or a voxel. A collection of pixels captured in succession (which may be referred to as a depth map, a point cloud, or a frame) may be rendered as an image or may be analyzed to identify or detect objects or to determine a shape or distance of objects within the FOR. As an example, a point cloud may cover a field of regard that extends 60° horizontally and 15° vertically, and the point cloud may include a frame of 100-2000 pixels in the horizontal direction by 4-400 pixels in the vertical direction.

In particular embodiments, lidar system 100 may be configured to repeatedly capture or generate point clouds of a field of regard at any suitable frame rate between approximately 0.1 frames per second (FPS) and approximately 1,000 FPS. As an example, lidar system 100 may generate point clouds at a frame rate of approximately 0.1 FPS, 0.5 FPS, 1 FPS, 2 FPS, 5 FPS, 10 FPS, 20 FPS, 100 FPS, 500 FPS, or 1,000 FPS. As another example, lidar system 100 may be configured to produce optical pulses at a rate of 5×10⁵ pulses/second (e.g., the system may determine 500,000 pixel distances per second) and scan a frame of 1000×50 pixels (e.g., 50,000 pixels/frame), which corresponds to a point-cloud frame rate of 10 frames per second (e.g., 10 point clouds per second). In particular embodiments, a point-cloud frame rate may be substantially fixed, or a point-cloud frame rate may be dynamically adjustable. As an example, a lidar system 100 may capture one or more point clouds at a particular frame rate (e.g., 1 Hz) and then switch to capture one or more point clouds at a different frame rate (e.g., 10 Hz). A slower frame rate (e.g., 1 Hz) may be used to capture one or more high-resolution point clouds, and a faster frame rate (e.g., 10 Hz) may be used to rapidly capture multiple lower-resolution point clouds.

In particular embodiments, a lidar system 100 may be configured to sense, identify, or determine distances to one or more targets 130 within a field of regard. As an example, a lidar system 100 may determine a distance to a target 130, where all or part of the target 130 is contained within a field of regard of the lidar system 100. All or part of a target 130 being contained within a FOR of the lidar system 100 may refer to the FOR overlapping, encompassing, or enclosing at least a portion of the target 130. In particular embodiments, target 130 may include all or part of an object that is moving or stationary relative to lidar system 100. As an example, target 130 may include all or a portion of a person, vehicle, motorcycle, truck, train, bicycle, wheelchair, pedestrian, animal, road sign, traffic light, lane marking, road-surface marking, parking space, pylon, guard rail, traffic barrier, pothole, railroad crossing, obstacle in or near a road, curb, stopped vehicle on or beside a road, utility pole, house, building, trash can, mailbox, tree, any other suitable object, or any suitable combination of all or part of two or more objects. In particular embodiments, a target may be referred to as an object.

In particular embodiments, light source 110, scanner 120, and receiver 140 may be packaged together within a single housing, where a housing may refer to a box, case, or enclosure that holds or contains all or part of a lidar system 100. As an example, a lidar-system enclosure may contain a light source 110, mirror 115, scanner 120, and receiver 140 of a lidar system 100. Additionally, the lidar-system enclosure may include a controller 150. The lidar-system enclosure may also include one or more electrical connections for conveying electrical power or electrical signals to or from the enclosure. In particular embodiments, one or more components of a lidar system 100 may be located remotely from a lidar-system enclosure. As an example, all or part of light source 110 may be located remotely from a lidar-system enclosure, and pulses of light produced by the light source 110 may be conveyed to the enclosure via optical fiber. As another example, all or part of a controller 150 may be located remotely from a lidar-system enclosure.

In particular embodiments, light source 110 may include an eye-safe laser, or lidar system 100 may be classified as an eye-safe laser system or laser product. An eye-safe laser, laser system, or laser product may refer to a system that includes a laser with an emission wavelength, average power, peak power, peak intensity, pulse energy, beam size, beam divergence, exposure time, or scanned output beam such that emitted light from the system presents little or no possibility of causing damage to a person's eyes. As an example, light source 110 or lidar system 100 may be classified as a Class 1 laser product (as specified by the 60825-1:2014 standard of the International Electrotechnical Commission (IEC)) or a Class I laser product (as specified by Title 21, Section 1040.10 of the United States Code of Federal Regulations (CFR)) that is safe under all conditions of normal use. In particular embodiments, lidar system 100 may be an eye-safe laser product (e.g., with a Class 1 or Class I classification) configured to operate at any suitable wavelength between approximately 900 nm and approximately 2000 nm. As an example, lidar system 100 may include a laser with an operating wavelength between approximately 1200 nm and approximately 1400 nm or between approximately 1400 nm and approximately 1600 nm, and the laser or the lidar system 100 may be operated in an eye-safe manner. As another example, lidar system 100 may be an eye-safe laser product that includes a scanned laser with an operating wavelength between approximately 900 nm and approximately 1700 nm. As another example, lidar system 100 may be a Class 1 or Class I laser product that includes a laser diode, fiber laser, or solid-state laser with an operating wavelength between approximately 1200 nm and approximately 1600 nm. As another example, lidar system 100 may have an operating wavelength between approximately 1500 nm and approximately 1510 nm.

In particular embodiments, one or more lidar systems 100 may be integrated into a vehicle. As an example, multiple lidar systems 100 may be integrated into a car to provide a complete 360-degree horizontal FOR around the car. As another example, 2-10 lidar systems 100, each system having a 45-degree to 180-degree horizontal FOR, may be combined together to form a sensing system that provides a point cloud covering a 360-degree horizontal FOR. The lidar systems 100 may be oriented so that adjacent FORs have an amount of spatial or angular overlap to allow data from the multiple lidar systems 100 to be combined or stitched together to form a single or continuous 360-degree point cloud. As an example, the FOR of each lidar system 100 may have approximately 1-30 degrees of overlap with an adjacent FOR. In particular embodiments, a vehicle may refer to a mobile machine configured to transport people or cargo. For example, a vehicle may include, may take the form of, or may be referred to as a car, automobile, motor vehicle, truck, bus, van, trailer, off-road vehicle, farm vehicle, lawn mower, construction equipment, forklift, robot, golf cart, motorhome, taxi, motorcycle, scooter, bicycle, skateboard, train, snowmobile, watercraft (e.g., a ship or boat), aircraft (e.g., a fixed-wing aircraft, helicopter, or dirigible), unmanned aerial vehicle (e.g., drone), or spacecraft. In particular embodiments, a vehicle may include an internal combustion engine or an electric motor that provides propulsion for the vehicle.

In particular embodiments, one or more lidar systems 100 may be included in a vehicle as part of an advanced driver assistance system (ADAS) to assist a driver of the vehicle in operating the vehicle. For example, a lidar system 100 may be part of an ADAS that provides information (e.g., about the surrounding environment) or feedback to a driver (e.g., to alert the driver to potential problems or hazards) or that automatically takes control of part of a vehicle (e.g., a braking system or a steering system) to avoid collisions or accidents. A lidar system 100 may be part of a vehicle ADAS that provides adaptive cruise control, automated braking, automated parking, collision avoidance, alerts the driver to hazards or other vehicles, maintains the vehicle in the correct lane, or provides a warning if an object or another vehicle is in a blind spot.

In particular embodiments, one or more lidar systems 100 may be integrated into a vehicle as part of an autonomous-vehicle driving system. As an example, a lidar system 100 may provide information about the surrounding environment to a driving system of an autonomous vehicle. An autonomous-vehicle driving system may be configured to guide the autonomous vehicle through an environment surrounding the vehicle and toward a destination. An autonomous-vehicle driving system may include one or more computing systems that receive information from a lidar system 100 about the surrounding environment, analyze the received information, and provide control signals to the vehicle's driving systems (e.g., steering wheel, accelerator, brake, or turn signal). As an example, a lidar system 100 integrated into an autonomous vehicle may provide an autonomous-vehicle driving system with a point cloud every 0.1 seconds (e.g., the point cloud has a 10 Hz update rate, representing 10 frames per second). The autonomous-vehicle driving system may analyze the received point clouds to sense or identify targets 130 and their respective locations, distances, or speeds, and the autonomous-vehicle driving system may update control signals based on this information. As an example, if lidar system 100 detects a vehicle ahead that is slowing down or stopping, the autonomous-vehicle driving system may send instructions to release the accelerator and apply the brakes.

In particular embodiments, an autonomous vehicle may be referred to as an autonomous car, driverless car, self-driving car, robotic car, or unmanned vehicle. In particular embodiments, an autonomous vehicle may refer to a vehicle configured to sense its environment and navigate or drive with little or no human input. As an example, an autonomous vehicle may be configured to drive to any suitable location and control or perform all safety-critical functions (e.g., driving, steering, braking, parking) for the entire trip, with the driver not expected to control the vehicle at any time. As another example, an autonomous vehicle may allow a driver to safely turn their attention away from driving tasks in particular environments (e.g., on freeways), or an autonomous vehicle may provide control of a vehicle in all but a few environments, requiring little or no input or attention from the driver.

In particular embodiments, an autonomous vehicle may be configured to drive with a driver present in the vehicle, or an autonomous vehicle may be configured to operate the vehicle with no driver present. As an example, an autonomous vehicle may include a driver's seat with associated controls (e.g., steering wheel, accelerator pedal, and brake pedal), and the vehicle may be configured to drive with no one seated in the driver's seat or with little or no input from a person seated in the driver's seat. As another example, an autonomous vehicle may not include any driver's seat or associated driver's controls, and the vehicle may perform substantially all driving functions (e.g., driving, steering, braking, parking, and navigating) without human input. As another example, an autonomous vehicle may be configured to operate without a driver (e.g., the vehicle may be configured to transport human passengers or cargo without a driver present in the vehicle). As another example, an autonomous vehicle may be configured to operate without any human passengers (e.g., the vehicle may be configured for transportation of cargo without having any human passengers onboard the vehicle).

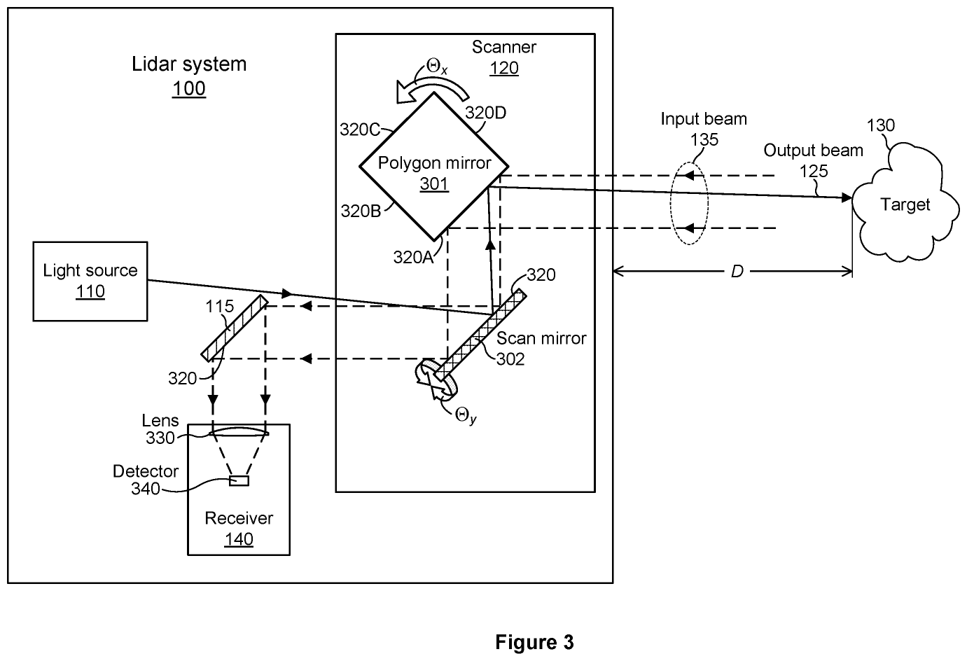

In particular embodiments, an optical signal (which may be referred to as a light signal, a light waveform, an optical waveform, an output beam, an emitted optical signal, or emitted light) may include pulses of light, CW light, amplitude-modulated light, frequency-modulated (FM) light, or any suitable combination thereof. For example, a lidar system 100 as described or illustrated herein may be a pulsed lidar system and may include a light source 110 that produces pulses of light. The pulsed lidar system 100 may include a light source 110 that emits an output beam 125 with optical pulses having one or more of the following optical characteristics: one or more wavelengths between 900 nm and 2000 nm (e.g., a wavelength of approximately 905 nm, a wavelength between 1500 nm and 1510 nm, a wavelength between 1400 nm and 1600 nm, or any other suitable operating wavelengths between 900 nm and 2000 nm); a pulse energy between 0.01 μJ and 100 μJ; a pulse repetition frequency between 80 kHz and 10 MHz; and a pulse duration between 1 ns and 100 ns. For example, the light source 110 in FIG. 1 or FIG. 3 may emit an output beam 125 with optical pulses having a wavelength of approximately 1550 nm, a pulse energy of approximately 0.5 μJ, a pulse repetition frequency of approximately 600 kHz, and a pulse duration of approximately 5 ns. Although this disclosure describes or illustrates example embodiments of lidar systems 100 or light sources 110 that produce optical signals that include pulses of light, the embodiments described or illustrated herein may also be applied, where appropriate, to other types of optical signals, including continuous-wave (CW) light, amplitude-modulated optical signals, or frequency-modulated optical signals. For example, a lidar system 100 may be configured to operate as a frequency-modulated continuous-wave (FMCW) lidar system and may include a light source 110 that produces CW light or a frequency-modulated optical signal.

In particular embodiments, a lidar system 100 may be a FMCW lidar system where the emitted light from the light source 110 (e.g., output beam 125 in FIG. 1 or FIG. 3) includes frequency-modulated light. A pulsed lidar system is a type of lidar system 100 in which the light source 110 emits pulses of light, and the distance to a remote target 130 is determined based on the round-trip time-of-flight for a pulse of light to travel to the target 130 and back. Another type of lidar system 100 is a frequency-modulated lidar system, which may be referred to as a frequency-modulated continuous-wave (FMCW) lidar system. A FMCW lidar system uses frequency-modulated light to determine the distance to a remote target 130 based on a frequency of received light (which includes emitted light scattered by the remote target) relative to a frequency of local-oscillator (LO) light. A round-trip time for the emitted FM light to travel to a target 130 and back to the lidar system may correspond to a frequency difference between the received scattered light and the LO light. A larger frequency difference may correspond to a longer round-trip time and a greater distance to the target 130.

A light source 110 for a FMCW lidar system may include (i) a direct-emitter laser diode, (ii) a seed laser diode followed by a SOA, (iii) a seed laser diode followed by a fiber-optic amplifier, or (iv) a seed laser diode followed by a SOA and then a fiber-optic amplifier. A seed laser diode or a direct-emitter laser diode may be operated in a CW manner (e.g., by driving the laser diode with a substantially constant DC current), and a frequency modulation may be provided by an external modulator (e.g., an electro-optic phase modulator may apply a frequency modulation to seed-laser light). Alternatively, a frequency modulation may be produced by applying a current modulation to a seed laser diode or a direct-emitter laser diode. The current modulation (which may be provided along with a DC bias current) may produce a corresponding refractive-index modulation in the laser diode, which results in a frequency modulation of the light emitted by the laser diode. The current-modulation component (and the corresponding frequency modulation) may have any suitable frequency or shape (e.g., piecewise linear, sinusoidal, triangle-wave, or sawtooth). For example, the current-modulation component (and the resulting frequency modulation of the emitted light) may increase or decrease monotonically over a particular time interval. As another example, the current-modulation component may include a triangle or sawtooth wave with an electrical current that increases or decreases linearly over a particular time interval, and the light emitted by the laser diode may include a corresponding frequency modulation in which the optical frequency increases or decreases approximately linearly over the particular time interval. For example, a light source 110 that emits light with a linear frequency change of 200 MHz over a 2-μs time interval may be referred to as having a frequency modulation m of 10¹⁴ Hz/s (or, 100 MHz/μs).

In addition to producing frequency-modulated emitted light, a light source 110 may also produce frequency-modulated local-oscillator (LO) light. The LO light may be coherent with the emitted light, and the frequency modulation of the LO light may match that of the emitted light. The LO light may be produced by splitting off a portion of the emitted light prior to the emitted light exiting the lidar system. Alternatively, the LO light may be produced by a seed laser diode or a direct-emitter laser diode that is part of the light source 110. For example, the LO light may be emitted from the back facet of a seed laser diode or a direct-emitter laser diode, or the LO light may be split off from the seed light emitted from the front facet of a seed laser diode. The received light (e.g., emitted light that is scattered by a target 130) and the LO light may each be frequency modulated, with a frequency difference or offset that corresponds to the distance to the target 130. For a linearly chirped light source (e.g., a frequency modulation that produces a linear change in frequency with time), the larger the frequency difference is between the received light and the LO light, the farther away the target 130 is located.

A frequency difference between received light and LO light may be determined by mixing the received light with the LO light (e.g., by coupling the two beams onto a detector so they are coherently mixed together at the detector) and determining the resulting beat frequency. For example, a photocurrent signal produced by an APD may include a beat signal resulting from the coherent mixing of the received light and the LO light, and a frequency of the beat signal may correspond to the frequency difference between the received light and the LO light. The photocurrent signal from an APD (or a voltage signal that corresponds to the photocurrent signal) may be analyzed using a frequency-analysis technique (e.g., a fast Fourier transform (FFT) technique) to determine the frequency of the beat signal. If a linear frequency modulation m (e.g., in units of Hz/s) is applied to a CW laser, then the round-trip time T may be related to the frequency difference Δf between the received scattered light and the LO light by the expression T=Δf/m. Additionally, the distance D from the target 130 to the lidar system 100 may be expressed as D=(Δf/m)·c/2, where c is the speed of light. For example, for a light source 110 with a linear frequency modulation of 10¹⁴ Hz/s, a frequency difference (between the received scattered light and the LO light) of 33 MHz may be measured. This 33-MHz frequency difference corresponds to a round-trip time of approximately 330 ns and a distance to the target of approximately 50 meters. As another example, a frequency difference of 133 MHz corresponds to a round-trip time of approximately 1.33 μs and a distance to the target of approximately 200 meters.

In particular embodiments, a receiver or processor of a FMCW lidar system may determine a frequency difference between received scattered light and LO light, and a distance to a target 130 may be determined based on the frequency difference. The frequency difference Δf between received scattered light and LO light corresponds to the round-trip time T (e.g., through the relationship T=Δf/m), and determining the frequency difference may correspond to or may be referred to as determining the round-trip time. For example, a receiver of a FMCW lidar system may determine a frequency difference between received scattered light and LO light, and based on the determined frequency difference, a processor may determine a distance to the target.

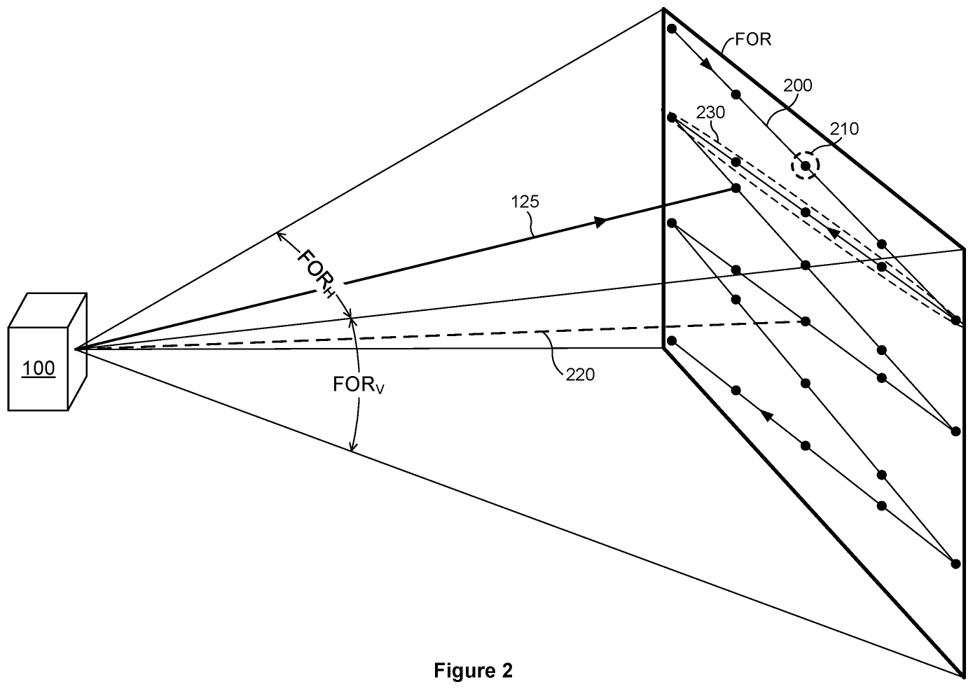

FIG. 2 illustrates an example scan pattern 200 produced by a lidar system 100. A scanner 120 of the lidar system 100 may scan the output beam 125 (which may include multiple emitted optical signals) along a scan pattern 200 that is contained within a FOR of the lidar system 100. A scan pattern 200 (which may be referred to as an optical scan pattern, optical scan path, scan path, or scan) may represent a path or course followed by output beam 125 as it is scanned across all or part of a FOR. Each traversal of a scan pattern 200 may correspond to the capture of a single frame or a single point cloud. In particular embodiments, a lidar system 100 may be configured to scan output optical beam 125 along one or more particular scan patterns 200. In particular embodiments, a scan pattern 200 may scan across any suitable field of regard (FOR) having any suitable horizontal FOR (FOR_{H}) and any suitable vertical FOR (FOR_{V}). For example, a scan pattern 200 may have a field of regard represented by angular dimensions (e.g., FOR_{H}×FOR_{V}) 40°×30°, 90°×40°, or 60°×15°. As another example, a scan pattern 200 may have a FOR_{H} greater than or equal to 10°, 25°, 30°, 40°, 60°, 90°, or 120°. As another example, a scan pattern 200 may have a FOR_{V} greater than or equal to 2°, 5°, 10°, 15°, 20°, 30°, or 45°.

In the example of FIG. 2, reference line 220 represents a center of the field of regard of scan pattern 200. In particular embodiments, reference line 220 may have any suitable orientation, such as for example, a horizontal angle of 0° (e.g., reference line 220 may be oriented straight ahead) and a vertical angle of 0° (e.g., reference line 220 may have an inclination of 0°), or reference line 220 may have a nonzero horizontal angle or a nonzero inclination (e.g., a vertical angle of +10° or −10°). In FIG. 2, if the scan pattern 200 has a 60°×15° field of regard, then scan pattern 200 covers a ±30° horizontal range with respect to reference line 220 and a ±7.5° vertical range with respect to reference line 220. Additionally, optical beam 125 in FIG. 2 has an orientation of approximately −15° horizontal and +3° vertical with respect to reference line 220. Optical beam 125 may be referred to as having an azimuth of −15° and an altitude of +3° relative to reference line 220. In particular embodiments, an azimuth (which may be referred to as an azimuth angle) may represent a horizontal angle with respect to reference line 220, and an altitude (which may be referred to as an altitude angle, elevation, or elevation angle) may represent a vertical angle with respect to reference line 220.

In particular embodiments, a scan pattern 200 may include multiple pixels 210, and each pixel 210 may be associated with one or more laser pulses or one or more distance measurements. Additionally, a scan pattern 200 may include multiple scan lines 230, where each scan line represents one scan across at least part of a field of regard, and each scan line 230 may include multiple pixels 210. In FIG. 2, scan line 230 includes five pixels 210 and corresponds to an approximately horizontal scan across the FOR from right to left, as viewed from the lidar system 100. In particular embodiments, a cycle of scan pattern 200 may include a total of Pₓ×P_{y} pixels 210 (e.g., a two-dimensional distribution of Pₓ by P_{y} pixels). As an example, scan pattern 200 may include a distribution with dimensions of approximately 100-2,000 pixels 210 along a horizontal direction and approximately 4-400 pixels 210 along a vertical direction. As another example, scan pattern 200 may include a distribution of 1,000 pixels 210 along the horizontal direction by 64 pixels 210 along the vertical direction (e.g., the frame size is 1000×64 pixels) for a total of 64,000 pixels per cycle of scan pattern 200. In particular embodiments, the number of pixels 210 along a horizontal direction may be referred to as a horizontal resolution of scan pattern 200, and the number of pixels 210 along a vertical direction may be referred to as a vertical resolution. As an example, scan pattern 200 may have a horizontal resolution of greater than or equal to 100 pixels 210 and a vertical resolution of greater than or equal to 4 pixels 210. As another example, scan pattern 200 may have a horizontal resolution of 100-2,000 pixels 210 and a vertical resolution of 4-400 pixels 210.

In particular embodiments, each pixel 210 may be associated with a distance (e.g., a distance to a portion of a target 130 from which an associated laser pulse was scattered) or one or more angular values. As an example, a pixel 210 may be associated with a distance value and two angular values (e.g., an azimuth and altitude) that represent the angular location of the pixel 210 with respect to the lidar system 100. A distance to a portion of target 130 may be determined based at least in part on a time-of-flight measurement for a corresponding pulse. An angular value (e.g., an azimuth or altitude) may correspond to an angle (e.g., relative to reference line 220) of output beam 125 (e.g., when a corresponding pulse is emitted from lidar system 100) or an angle of input beam 135 (e.g., when an input signal is received by lidar system 100). In particular embodiments, an angular value may be determined based at least in part on a position of a component of scanner 120. As an example, an azimuth or altitude value associated with a pixel 210 may be determined from an angular position of one or more corresponding scanning mirrors of scanner 120.

FIG. 3 illustrates an example lidar system 100 with an example rotating polygon mirror 301. In particular embodiments, a scanner 120 may include a polygon mirror 301 configured to scan output beam 125 along a particular direction. In the example of FIG. 3, scanner 120 includes two scanning mirrors: (1) a polygon mirror 301 that rotates along the Θₓ direction and (2) a scanning mirror 302 that oscillates back and forth along the Θ_{y} direction. The output beam 125 from light source 110, which passes alongside mirror 115, is reflected by reflecting surface 320 of scan mirror 302 and is then reflected by a reflecting surface (e.g., surface 320A, 320B, 320C, or 320D) of polygon mirror 301. Scattered light from a target 130 returns to the lidar system 100 as input beam 135. The input beam 135 reflects from polygon mirror 301, scan mirror 302, and mirror 115, which directs input beam 135 through focusing lens 330 and to the detector 340 of receiver 140. The detector 340 may be a PN photodiode, a PIN photodiode, an APD, a SPAD, or any other suitable detector. A reflecting surface 320 (which may be referred to as a reflective surface) may include a reflective metallic coating (e.g., gold, silver, or aluminum) or a reflective dielectric coating, and the reflecting surface 320 may have any suitable reflectivity R at an operating wavelength of the light source 110 (e.g., R greater than or equal to 70%, 80%, 90%, 95%, 98%, or 99%).

In particular embodiments, a polygon mirror 301 may be configured to rotate along a Θₓ or Θ_{y} direction and scan output beam 125 along a substantially horizontal or vertical direction, respectively. A rotation along a Θₓ direction may refer to a rotational motion of mirror 301 that results in output beam 125 scanning along a substantially horizontal direction. Similarly, a rotation along a Θ_{y} direction may refer to a rotational motion that results in output beam 125 scanning along a substantially vertical direction. In FIG. 3, mirror 301 is a polygon mirror that rotates along the Θₓ direction and scans output beam 125 along a substantially horizontal direction, and mirror 302 pivots along the Θ_{y} direction and scans output beam 125 along a substantially vertical direction. In particular embodiments, a polygon mirror 301 may be configured to scan output beam 125 along any suitable direction. As an example, a polygon mirror 301 may scan output beam 125 at any suitable angle with respect to a horizontal or vertical direction, such as for example, at an angle of approximately 0°, 10°, 20°, 30°, 45°, 60°, 70°, 80°, or 90° with respect to a horizontal or vertical direction. Additionally, scan mirror 302 may scan the output beam 125 along any suitable direction that is different from the scan direction of the polygon mirror 301. For example, scan mirror 302 may scan the output beam 125 along a direction that is approximately orthogonal to the scan direction of the polygon mirror 301.

In particular embodiments, a polygon mirror 301 may refer to a multi-sided object having reflective surfaces 320 on two or more of its sides or faces. As an example, a polygon mirror may include any suitable number of reflective faces (e.g., 2, 3, 4, 5, 6, 7, 8, or 10 faces), where each face includes a reflective surface 320. A polygon mirror 301 may have a cross-sectional shape of any suitable polygon, such as for example, a triangle (with three reflecting surfaces 320), square (with four reflecting surfaces 320), pentagon (with five reflecting surfaces 320), hexagon (with six reflecting surfaces 320), heptagon (with seven reflecting surfaces 320), or octagon (with eight reflecting surfaces 320). In FIG. 3, the polygon mirror 301 has a substantially square cross-sectional shape and four reflecting surfaces (320A, 320B, 320C, and 320D). The polygon mirror 301 in FIG. 3 may be referred to as a square mirror, a cube mirror, or a four-sided polygon mirror. In FIG. 3, the polygon mirror 301 may have a shape similar to a cube, cuboid, or rectangular prism. Additionally, the polygon mirror 301 may have a total of six sides, where four of the sides include faces with reflective surfaces (320A, 320B, 320C, and 320D).

In particular embodiments, a polygon mirror 301 may be continuously rotated in a clockwise or counter-clockwise rotation direction about a rotation axis of the polygon mirror 301. The rotation axis may correspond to a line that is perpendicular to the plane of rotation of the polygon mirror 301 and that passes through the center of mass of the polygon mirror 301. In FIG. 3, the polygon mirror 301 rotates in the plane of the drawing, and the rotation axis of the polygon mirror 301 is perpendicular to the plane of the drawing. An electric motor may be configured to rotate a polygon mirror 301 at a substantially fixed frequency (e.g., a rotational frequency of approximately 1 Hz (or 1 revolution per second), 10 Hz, 50 Hz, 100 Hz, 500 Hz, or 1,000 Hz). As an example, a polygon mirror 301 may be mechanically coupled to an electric motor (e.g., a synchronous electric motor) which is configured to spin the polygon mirror 301 at a rotational speed of approximately 160 Hz (or, 9600 revolutions per minute (RPM)).

In particular embodiments, output beam 125 may be reflected sequentially from the reflective surfaces 320A, 320B, 320C, and 320D as the polygon mirror 301 is rotated. This results in the output beam 125 being scanned along a particular scan axis (e.g., a horizontal or vertical scan axis) to produce a sequence of scan lines, where each scan line corresponds to a reflection of the output beam 125 from one of the reflective surfaces of the polygon mirror 301. In FIG. 3, the output beam 125 reflects off of reflective surface 320A to produce one scan line. Then, as the polygon mirror 301 rotates, the output beam 125 reflects off of reflective surfaces 320B, 320C, and 320D to produce a second, third, and fourth respective scan line. In particular embodiments, a lidar system 100 may be configured so that the output beam 125 is first reflected from polygon mirror 301 and then from scan mirror 302 (or vice versa). As an example, an output beam 125 from light source 110 may first be directed to polygon mirror 301, where it is reflected by a reflective surface of the polygon mirror 301, and then the output beam 125 may be directed to scan mirror 302, where it is reflected by reflective surface 320 of the scan mirror 302. In the example of FIG. 3, the output beam 125 is reflected from the polygon mirror 301 and the scan mirror 302 in the reverse order. In FIG. 3, the output beam 125 from light source 110 is first directed to the scan mirror 302, where it is reflected by reflective surface 320, and then the output beam 125 is directed to the polygon mirror 301, where it is reflected by reflective surface 320A.

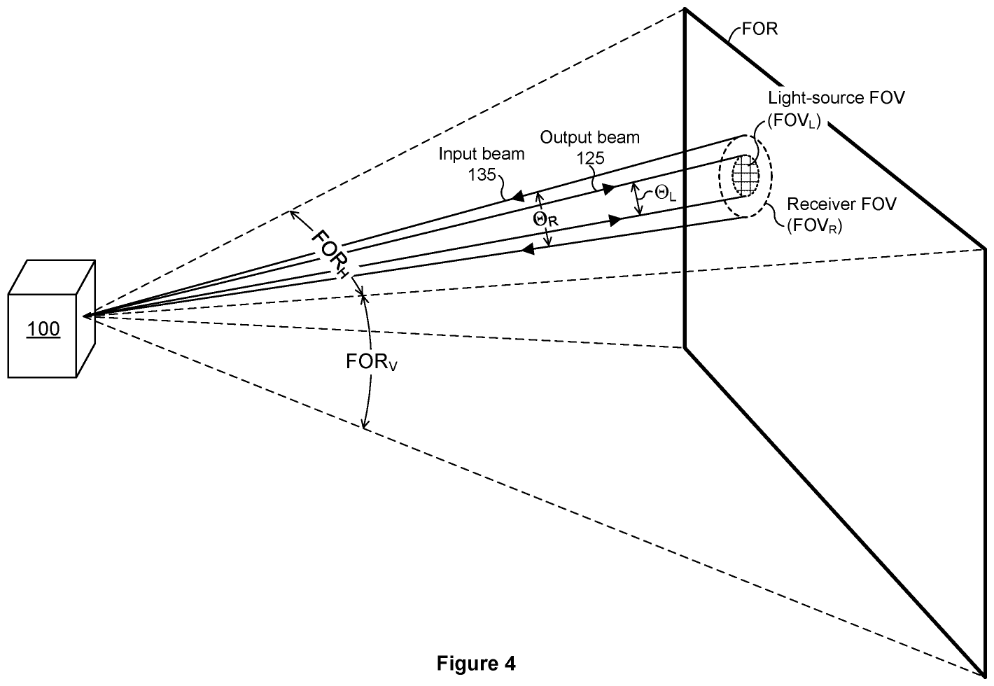

FIG. 4 illustrates an example light-source field of view (FOV_{L}) and receiver field of view (FOV_{R}) for a lidar system 100. A light source 110 of lidar system 100 may emit pulses of light as the FOV_{L} and FOV_{R} are scanned by scanner 120 across a field of regard (FOR). In particular embodiments, a light-source field of view may refer to an angular cone illuminated by the light source 110 at a particular instant of time. Similarly, a receiver field of view may refer to an angular cone over which the receiver 140 may receive or detect light at a particular instant of time, and any light outside the receiver field of view may not be received or detected. As an example, as the light-source field of view is scanned across a field of regard, a portion of a pulse of light emitted by the light source 110 may be sent downrange from lidar system 100, and the pulse of light may be sent in the direction that the FOV_{L} is pointing at the time the pulse is emitted. The pulse of light may scatter off a target 130, and the receiver 140 may receive and detect a portion of the scattered light that is directed along or contained within the FOV_{R}.

In particular embodiments, scanner 120 may be configured to scan both a light-source field of view and a receiver field of view across a field of regard of the lidar system 100. Multiple pulses of light may be emitted and detected as the scanner 120 scans the FOV_{L} and FOV_{R} across the field of regard of the lidar system 100 while tracing out a scan pattern 200. In particular embodiments, the light-source field of view and the receiver field of view may be scanned synchronously with respect to one another, so that as the FOV_{L} is scanned across a scan pattern 200, the FOV_{R} follows substantially the same path at the same scanning speed. Additionally, the FOV_{L} and FOV_{R} may maintain the same relative position to one another as they are scanned across the field of regard. As an example, the FOV_{L} may be substantially overlapped with or centered inside the FOV_{R} (as illustrated in FIG. 4), and this relative positioning between FOV_{L} and FOV_{R} may be maintained throughout a scan. As another example, the FOV_{R} may lag behind the FOV_{L} by a particular, fixed amount throughout a scan (e.g., the FOV_{R} may be offset from the FOV_{L} in a direction opposite the scan direction).

In particular embodiments, the FOV_{L} may have an angular size or extent Θ_{L} that is substantially the same as or that corresponds to the divergence of the output beam 125, and the FOV_{R} may have an angular size or extent Θ_{R} that corresponds to an angle over which the receiver 140 may receive and detect light. In particular embodiments, the receiver field of view may be any suitable size relative to the light-source field of view. As an example, the receiver field of view may be smaller than, substantially the same size as, or larger than the angular extent of the light-source field of view. In particular embodiments, the light-source field of view may have an angular extent of less than or equal to 50 milliradians, and the receiver field of view may have an angular extent of less than or equal to 50 milliradians. The FOV_{L} may have any suitable angular extent Θ_{L}, such as for example, approximately 0.1 mrad, 0.2 mrad, 0.5 mrad, 1 mrad, 1.5 mrad, 2 mrad, 3 mrad, 5 mrad, 10 mrad, 20 mrad, 40 mrad, or 50 mrad. Similarly, the FOV_{R} may have any suitable angular extent Θ_{R}, such as for example, approximately 0.1 mrad, 0.2 mrad, 0.5 mrad, 1 mrad, 1.5 mrad, 2 mrad, 3 mrad, 5 mrad, 10 mrad, 20 mrad, 40 mrad, or 50 mrad. In particular embodiments, the light-source field of view and the receiver field of view may have approximately equal angular extents. As an example, Θ_{L} and Θ_{R} may both be approximately equal to 1 mrad, 2 mrad, or 4 mrad. In particular embodiments, the receiver field of view may be larger than the light-source field of view, or the light-source field of view may be larger than the receiver field of view. As an example, Θ_{L} may be approximately equal to 3 mrad, and Θ_{R} may be approximately equal to 4 mrad. As another example, Θ_{R} may be approximately K times larger than Θ_{L}, where K is any suitable factor, such as for example, 1.1, 1.2, 1.5, 2, 3, 5, or 10.

In particular embodiments, a pixel 210 may represent or may correspond to a light-source field of view or a receiver field of view. As the output beam 125 propagates from the light source 110, the diameter of the output beam 125 (as well as the size of the corresponding pixel 210) may increase according to the beam divergence Θ_{L}. As an example, if the output beam 125 has a Θ_{L} of 2 mrad, then at a distance of 100 m from the lidar system 100, the output beam 125 may have a size or diameter of approximately 20 cm, and a corresponding pixel 210 may also have a corresponding size or diameter of approximately 20 cm. At a distance of 200 m from the lidar system 100, the output beam 125 and the corresponding pixel 210 may each have a diameter of approximately 40 cm.

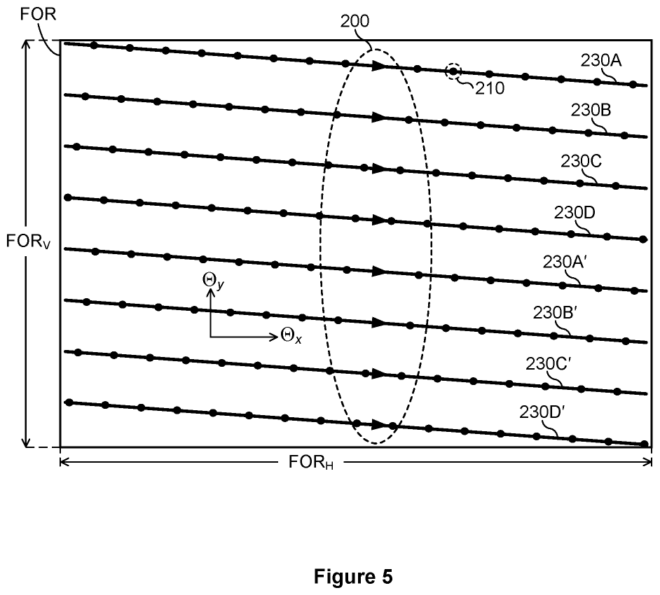

FIG. 5 illustrates an example unidirectional scan pattern 200 that includes multiple pixels 210 and multiple scan lines 230. In particular embodiments, scan pattern 200 may include any suitable number of scan lines 230 (e.g., approximately 1, 2, 5, 10, 20, 50, 100, 500, or 1,000 scan lines), and each scan line 230 of a scan pattern 200 may include any suitable number of pixels 210 (e.g., 1, 2, 5, 10, 20, 50, 100, 200, 500, 1,000, 2,000, or 5,000 pixels). The scan pattern 200 illustrated in FIG. 5 includes eight scan lines 230, and each scan line 230 includes approximately 16 pixels 210. In particular embodiments, a scan pattern 200 where the scan lines 230 are scanned in two directions (e.g., alternately scanning from right to left and then from left to right) may be referred to as a bidirectional scan pattern 200, and a scan pattern 200 where the scan lines 230 are scanned in the same direction may be referred to as a unidirectional scan pattern 200. The scan pattern 200 in FIG. 2 may be referred to as a bidirectional scan pattern, and the scan pattern 200 in FIG. 5 may be referred to as a unidirectional scan pattern 200 where each scan line 230 travels across the FOR in substantially the same direction (e.g., approximately from left to right as viewed from the lidar system 100). In particular embodiments, scan lines 230 of a unidirectional scan pattern 200 may be directed across a FOR in any suitable direction, such as for example, from left to right, from right to left, from top to bottom, from bottom to top, or at any suitable angle (e.g., at a 0°, 5°, 10°, 30°, or 45° angle) with respect to a horizontal or vertical axis. In particular embodiments, each scan line 230 in a unidirectional scan pattern 200 may be a separate line that is not directly connected to a previous or subsequent scan line 230.

In particular embodiments, a unidirectional scan pattern 200 may be produced by a scanner 120 that includes a polygon mirror (e.g., polygon mirror 301 of FIG. 3), where each scan line 230 is associated with a particular reflective surface 320 of the polygon mirror. As an example, reflective surface 320A of polygon mirror 301 in FIG. 3 may produce scan line 230A in FIG. 5. Similarly, as the polygon mirror 301 rotates, reflective surfaces 320B, 320C, and 320D may successively produce scan lines 230B, 230C, and 230D, respectively. Additionally, for a subsequent revolution of the polygon mirror 301, the scan lines 230A′, 230B′, 230C′, and 230D′ may be successively produced by reflections of the output beam 125 from reflective surfaces 320A, 320B, 320C, and 320D, respectively. In particular embodiments, N successive scan lines 230 of a unidirectional scan pattern 200 may correspond to one full revolution of a N-sided polygon mirror. As an example, the four scan lines 230A, 230B, 230C, and 230D in FIG. 5 may correspond to one full revolution of the four-sided polygon mirror 301 in FIG. 3. Additionally, a subsequent revolution of the polygon mirror 301 may produce the next four scan lines 230A′, 230B′, 230C′, and 230D′ in FIG. 5.

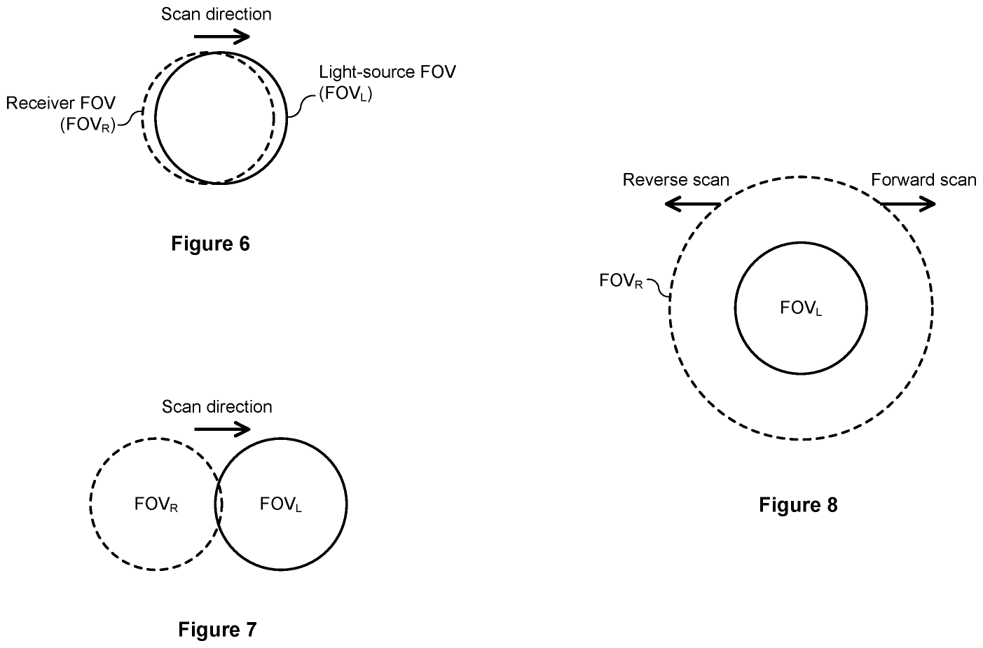

FIG. 6 illustrates an example light-source field of view and receiver field of view with a corresponding scan direction. In particular embodiments, scanner 120 may scan the FOV_{L} and FOV_{R} along any suitable scan direction or combination of scan directions, such as for example, left to right, right to left, upward, downward, or any suitable combination thereof. As an example, the FOV_{L} and FOV_{R} may follow a left-to-right scan direction (as illustrated in FIG. 6) across a field of regard. In particular embodiments, a light-source field of view and a receiver field of view may be non-overlapped during scanning or may be at least partially overlapped during scanning. As an example, the FOV_{L} and FOV_{R} may have any suitable amount of angular overlap, such as for example, approximately 0%, 1%, 2%, 5%, 10%, 25%, 50%, 75%, 90%, or 100% of angular overlap. As another example, if Θ_{L} and Θ_{R} are 2 mrad, and FOV_{L} and FOV_{R} are offset from one another by 1 mrad, then FOV_{L} and FOV_{R} may be referred to as having a 50% angular overlap. As another example, if Θ_{L} and Θ_{R} are 2 mrad, and FOV_{L} and FOV_{R} are offset from one another by 2 mrad, then FOV_{L} and FOV_{R} may be referred to as having a 0% angular overlap. As another example, the FOV_{L} and FOV_{R} may be substantially coincident with one another and may have an angular overlap of approximately 100%. In the example of FIG. 6, the FOV_{L} and FOV_{R} are approximately the same size and have an angular overlap of approximately 90%. In particular embodiments, the FOV_{L} and FOV_{R} may be scanned synchronously with respect to one another so that the two FOV_{S} follow approximately the same scan pattern 200 and are scanned at approximately the same scanning speed. Additionally, the FOV_{L} and FOV_{R} may maintain the same relative position to one another as they are scanned (e.g., the angular overlap between the FOV_{L} and FOV_{R} may remain approximately fixed as they are scanned).

FIG. 7 illustrates an example receiver field of view that is offset from a light-source field of view. In particular embodiments, a FOV_{L} and FOV_{R} may be scanned along a particular scan direction, and the FOV_{R} may be offset from the FOV_{L} in a direction opposite the scan direction so that the FOV_{R} lags behind the FOV_{L}. A lidar system with a polygon mirror (e.g., similar to that illustrated in FIG. 3) may have its FOV_{L} and FOV_{R} arranged as illustrated in FIG. 7 where the FOV_{R} lags behind the FOV_{L}, and the FOV_{L} and FOV_{R} may follow a scan pattern 200 similar to that illustrated in FIG. 5. Each reflection of the output beam 125 from a reflective surface of polygon mirror 301 may correspond to a single scan line 230, and each scan line may scan across a FOR in the same direction (e.g., from left to right). The FOV_{L} and FOV_{R} in FIG. 7 may be referred to as having an angular overlap of approximately 5%, and the FOV_{L} and FOV_{R} may be scanned synchronously so that the angular overlap remains approximately fixed as the FOV_{L} and FOV_{R} are scanned along a scan direction at approximately the same scanning speed.

In the example of FIG. 7, the FOV_{L} and FOV_{R} are approximately the same size, and the FOV_{R} lags behind the FOV_{L} so that the FOV_{L} and FOV_{R} have an angular overlap of approximately 5%. In particular embodiments, the FOV_{R} may be configured to lag behind the FOV_{L} to produce any suitable angular overlap, such as for example, an angular overlap of less than or equal to 90%, 75%, 50%, 25%, 5%, 1%, or 0%. Additionally, the FOV_{L} and FOV_{R} may have approximately the same sizes or may have different sizes (e.g., the FOV_{R} may have a diameter or angular extent Θ_{R}, that is approximately 1.5×, 2×, 3×, 4×, 5×, or 10×larger than the diameter or angular extent Θ_{L} of the FOV_{L}). After a pulse of light is emitted by light source 110, the pulse may scatter from a target 130, and some of the scattered light may propagate back to the lidar system 100 along a path that corresponds to the orientation of the light-source field of view at the time the pulse was emitted. As the pulse of light propagates to and from the target 130, the receiver field of view moves in the scan direction and increases its overlap with the previous location of the light-source field of view (e.g., the location of the light-source field of view when the pulse was emitted). For a close-range target (e.g., a target 130 located within 20% of the operating range of the lidar system), when the receiver 140 detects scattered light from the emitted pulse, the receiver field of view may overlap less than or equal to 20% of the previous location of the light-source field of view. The receiver 140 may receive less than or equal to 20% of the scattered light that propagates back to the lidar system 100 along the path that corresponds to the orientation of the light-source field of view at the time the pulse was emitted. However, since the target 130 is located relatively close to the lidar system 100, the receiver 140 may still receive a sufficient amount of light to produce a signal indicating that a pulse has been detected. For a midrange target (e.g., a target 130 located between 20% and 80% of the operating range of the lidar system 100), when the receiver 140 detects the scattered light, the receiver field of view may overlap between 20% and 80% of the previous location of the light-source field of view. For a target 130 located a distance greater than or equal to 80% of the operating range of the lidar system 100, when the receiver 140 detects the scattered light, the receiver field of view may overlap greater than or equal to 80% of the previous location of the light-source field of view. For a target 130 located at the operating range from the lidar system 100, when the receiver 140 detects the scattered light, the receiver field of view may be substantially overlapped with the previous location of the light-source field of view. In this case, the receiver 140 may receive substantially all of the scattered light that propagates back to the lidar system 100 along a path that corresponds to the orientation of the light-source field of view at the time the pulse was emitted.

FIG. 8 illustrates an example forward-scan direction and reverse-scan direction for a light-source field of view and a receiver field of view. In particular embodiments, a lidar system 100 may be configured so that the FOV_{R} is larger than the FOV_{L}, and the receiver and light-source FOV_{S} may be substantially coincident, overlapped, or centered with respect to one another. As an example, the FOV_{R} may have a diameter or angular extent Θ_{R}, that is approximately 1.5×, 2×, 3×, 4×, 5×, or 10× larger than the diameter or angular extent Θ_{L} of the FOV_{L}. In the example of FIG. 8, the diameter of the receiver field of view is approximately 2 times larger than the diameter of the light-source field of view, and the two FOV_{S} are overlapped and centered with respect to one another. The receiver field of view being larger than the light-source field of view may allow the receiver 140 to receive scattered light from emitted pulses in both scan directions (forward scan or reverse scan). In the forward-scan direction illustrated in FIG. 8, scattered light may be received primarily by the left side of the FOV_{R}, and in the reverse-scan direction, scattered light may be received primarily by the right side of the FOV_{R}. For example, as a pulse of light propagates to and from a target 130 during a forward scan, the FOV_{R} scans to the right, and scattered light that returns to the lidar system 100 may be received primarily by the left portion of the FOV_{R.}

In particular embodiments, a lidar system 100 may perform a series of forward and reverse scans. As an example, a forward scan may include the FOV_{L} and the FOV_{R} being scanned horizontally from left to right, and a reverse scan may include the two fields of view being scanned from right to left. As another example, a forward scan may include the FOV_{L} and the FOV_{R} being scanned along any suitable direction (e.g., along a 45-degree angle), and a reverse scan may include the two fields of view being scanned along a substantially opposite direction. In particular embodiments, the forward and reverse scans may trace paths that are adjacent to or displaced with respect to one another. As an example, a reverse scan may follow a line in the field of regard that is displaced above, below, to the left of, or to the right of a previous forward scan. As another example, a reverse scan may scan a row in the field of regard that is displaced below a previous forward scan, and the next forward scan may be displaced below the reverse scan. The forward and reverse scans may continue in an alternating manner with each scan being displaced with respect to the previous scan until a complete field of regard has been covered. Scans may be displaced with respect to one another by any suitable angular amount, such as for example, by approximately 0.05°, 0.1°, 0.2°, 0.5°, 1°, or 2°.

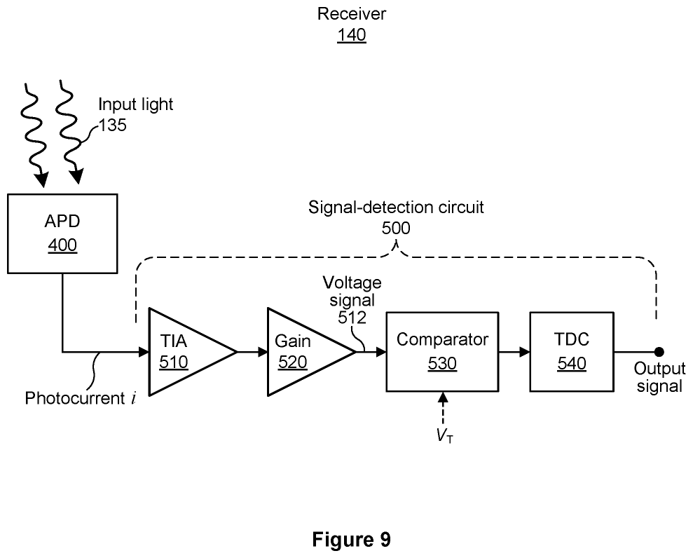

FIG. 9 illustrates an example receiver 140 that includes an avalanche photodiode (APD) 400 coupled to a signal-detection circuit 500. In particular embodiments, a signal-detection circuit 500 may include circuitry that receives an electrical-current signal (e.g., photocurrent i) from an APD 400 and performs current-to-voltage conversion, signal amplification, sampling, filtering, signal conditioning, analog-to-digital conversion, time-to-digital conversion, pulse detection, threshold detection, rising-edge detection, or falling-edge detection. A signal-detection circuit 500 may be used to determine (i) whether an optical signal (e.g., an optical pulse) has been received by an APD 400 or (ii) a time associated with receipt of an optical signal by an APD 400. A signal-detection circuit 500 may include a transimpedance amplifier (TIA) 510, a voltage-gain circuit 520, a comparator 530, or a time-to-digital converter (TDC) 540. In particular embodiments, a signal-detection circuit 500 may be included in a receiver 140 or a controller 150, or parts of a signal-detection circuit 500 may be included in a receiver 140 and other parts may be included in a controller 150. As an example, a TIA 510 and a voltage-gain circuit 520 may be part of a receiver 140, and a comparator 530 and a TDC 540 may be part of a controller 150 that is coupled to the receiver 140. As another example, a TIA 510, gain circuit 520, comparator 530, and TDC 540 may be part of a receiver 140, and an output signal from the TDC 540 may be supplied to a controller 150.

In particular embodiments, a signal-detection circuit 500 may include a TIA 510 configured to receive a photocurrent signal i from an APD 400 and produce a voltage signal that corresponds to the received photocurrent. As an example, in response to a received optical pulse (e.g., light from an emitted optical pulse that is scattered by a remote target 130), an APD 400 may produce photocurrent i that includes a pulse of electrical current corresponding to the received optical pulse. A TIA 510 may receive the electrical-current pulse from the APD 400 and amplify the pulse of electrical current to produce a voltage pulse that corresponds to the received current pulse. In particular embodiments, a TIA 510 may also act as an electronic filter. As an example, a TIA 510 may be configured as a low-pass filter that removes or attenuates high-frequency electrical noise by attenuating signals above a particular frequency (e.g., above 1 MHz, 10 MHz, 20 MHz, 50 MHz, 100 MHz, 200 MHz, 300 MHz, 1 GHz, or any other suitable frequency). In particular embodiments, a signal-detection circuit 500 may include a voltage-gain circuit 520 (which may be referred to as a gain circuit or a voltage amplifier) configured to amplify a voltage signal. As an example, a gain circuit 520 may include one or more voltage-amplification stages that amplify a voltage signal received from a TIA 510. For example, the gain circuit 520 may receive a voltage pulse from a TIA 510, and the gain circuit 520 may amplify the voltage pulse by any suitable amount, such as for example, by a gain of approximately 3 dB, 10 dB, 20 dB, 30 dB, 40 dB, or 50 dB. Additionally, the gain circuit 520 may be configured to also act as an electronic filter to remove or attenuate electrical noise. In particular embodiments, a signal-detection circuit 500 may not include a separate gain circuit 520 (e.g., a TIA 510 may produce a voltage signal 512 that is directly coupled to a comparator 530 without an intervening voltage-gain circuit).

In particular embodiments, a signal-detection circuit 500 may include a comparator 530 configured to receive a voltage signal 512 from TIA 510 or gain circuit 520 and produce an electrical-edge signal (e.g., a rising edge or a falling edge) when the received voltage signal rises above or falls below a particular threshold voltage V_{T}. As an example, when a received voltage signal 512 rises above V_{T}, a comparator 530 may produce a rising-edge digital-voltage signal (e.g., a signal that steps from approximately 0 V to approximately 2.5 V, 3.3 V, 5 V, or any other suitable digital-high level). Additionally or alternatively, when a received voltage signal 512 falls below V_{T}, a comparator 530 may produce a falling-edge digital-voltage signal (e.g., a signal that steps down from approximately 2.5 V, 3.3 V, 5 V, or any other suitable digital-high level to approximately 0 V). The voltage signal 512 received by the comparator 530 may be received from a TIA 510 or gain circuit 520 and may correspond to a photocurrent signal i produced by an APD 400. As an example, the voltage signal 512 received by the comparator 530 may include a voltage pulse that corresponds to an electrical-current pulse produced by the APD 400 in response to a received optical pulse. The voltage signal 512 received by the comparator 530 may be an analog signal, and an electrical-edge signal produced by the comparator 530 may be a digital signal.

In particular embodiments, a signal-detection circuit 500 may include a time-to-digital converter (TDC) 540 configured to receive an electrical-edge signal from a comparator 530 and determine an interval of time between emission of a pulse of light by the light source 110 and receipt of the electrical-edge signal. The interval of time may correspond to a round-trip time of flight for an emitted pulse of light to travel from the lidar system 100 to a target 130 and back to the lidar system 100. The portion of the emitted pulse of light that is received by the lidar system 100 (e.g., scattered light from target 130) may be referred to as a received pulse of light. The output of the TDC 540 may include one or more numerical values, where each numerical value (which may be referred to as a numerical time value, a time value, a digital value, or a digital time value) corresponds to a time interval determined by the TDC 540. In particular embodiments, a TDC 540 may have an internal counter or clock with any suitable period, such as for example, 5 ps, 10 ps, 15 ps, 20 ps, 30 ps, 50 ps, 100 ps, 0.5 ns, 1 ns, 2 ns, 5 ns, or 10 ns. As an example, the TDC 540 may have an internal counter or clock with a 20-ps period, and the TDC 540 may determine that an interval of time between emission and receipt of an optical pulse is equal to 25,000 time periods, which corresponds to a time interval of approximately 0.5 microseconds. The TDC 540 may send an output signal that includes the numerical value “25000” to a processor or controller 150 of the lidar system 100. In particular embodiments, a lidar system 100 may include a processor configured to determine a distance from the lidar system 100 to a target 130 based at least in part on an interval of time determined by a TDC 540. As an example, the processor may be an ASIC or FPGA and may be a part of a receiver 140 or controller 150. The processor may receive a numerical value (e.g., “25000”) from the TDC 540, and based on the received value, the processor may determine the distance from the lidar system 100 to a target 130.

In particular embodiments, determining an interval of time between emission and receipt of a pulse of light may include (1) determining a time associated with the emission of the pulse by light source 110 or lidar system 100 or (2) determining a time when scattered light from the pulse is detected by receiver 140. As an example, a TDC 540 may count the number of time periods or clock cycles between an electrical edge associated with emission of a pulse of light and an electrical edge associated with detection of scattered light from the pulse. Determining when scattered light from the pulse is detected by receiver 140 may be based on determining a time for a rising or falling edge (e.g., a rising or falling edge produced by comparator 530) associated with the detected pulse. In particular embodiments, determining a time associated with emission of a pulse of light may be based on an electrical trigger signal. As an example, light source 110 may produce an electrical trigger signal for each pulse of light that is emitted, or an electrical device (e.g., controller 150) may provide a trigger signal to the light source 110 to initiate the emission of each pulse of light. A trigger signal associated with emission of an optical pulse may be provided to TDC 540, and a rising edge or falling edge of the trigger signal may correspond to a time when the optical pulse is emitted. In particular embodiments, a time associated with emission of an optical pulse may be determined based on an optical trigger signal. As an example, a time associated with the emission of a pulse of light may be determined based at least in part on detection of a portion of light from the emitted pulse of light prior to the emitted pulse of light exiting the lidar system 100 and propagating to target 130. The portion of the emitted pulse of light (which may be referred to as an optical trigger pulse) may be detected by a separate detector (e.g., a PIN photodiode or an APD) or by an APD 400 of the receiver 140. A portion of light from an emitted pulse of light may be scattered or reflected from a surface (e.g., a surface of a beam splitter or window, or a surface of light source 110, mirror 115, or scanner 120) located within lidar system 100 to produce the optical trigger pulse, or the lidar system 100 may include an optical splitter that splits off a portion of the emitted pulse of light to produce the optical trigger pulse. At least part of the optical trigger pulse may be received by a separate detector or by an APD 400 of receiver 140, and a separate detection circuit or a signal-detection circuit 500 coupled to the APD 400 may determine that an optical trigger pulse has been received. The time at which the optical trigger pulse was received may be associated with the emission time of the pulse.

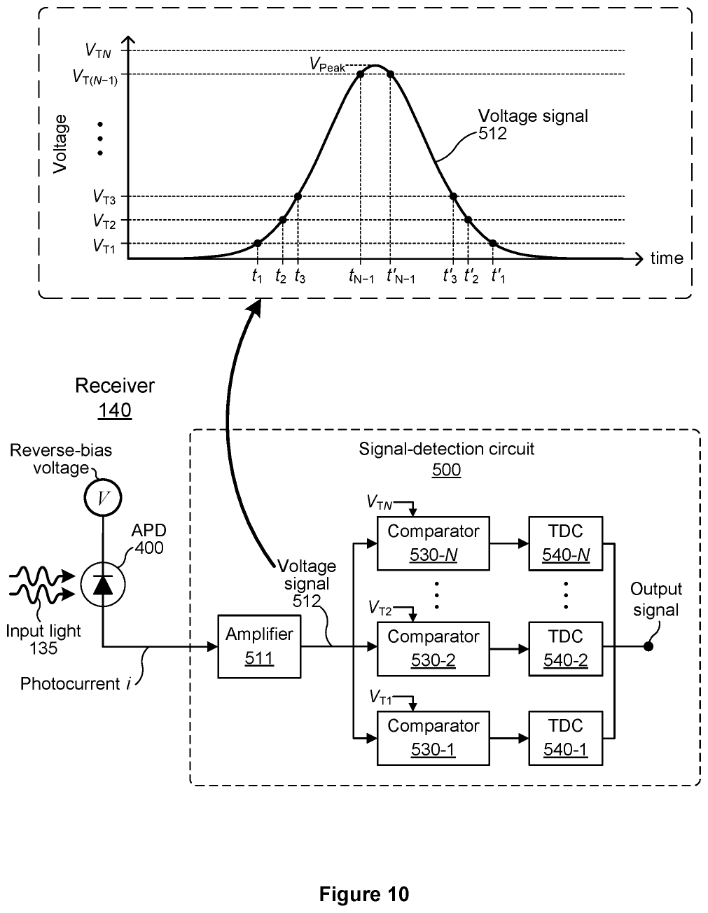

FIG. 10 illustrates an example receiver 140 and an example voltage signal 512 corresponding to a received pulse of light. A light source 110 of a lidar system 100 may emit a pulse of light, and a receiver 140 may be configured to detect input light 135. The input light 135 in FIG. 10 may include a received pulse of light. In particular embodiments, a receiver 140 of a lidar system 100 may include one or more APDs 400, one or more electronic amplifiers 511, one or more comparators 530, or one or more time-to-digital converters (TDCs) 540. The receiver 140 illustrated in FIG. 10 includes an APD 400 configured to receive input light 135 and produce a photocurrent i that corresponds to a received pulse of light (which is part of the input light 135). The photocurrent i produced by the APD 400 may be referred to as a photocurrent signal, electrical-current signal, electrical current, or current. The APD 400 may be configured to detect light at a 1200-1600 nm operating wavelength of a lidar system 100. The APDs 400 in FIGS. 9-10 may correspond to the detector 340 in FIG. 3.

In FIG. 10, the APD 400 is electrically coupled to a signal-detection circuit 500 (which may be referred to as a pulse-detection circuit). The APD 400 is also electrically coupled to a voltage source that supplies a reverse-bias voltage V to the APD 400. The signal-detection circuit 500 includes an electronic amplifier 511 configured to receive the photocurrent i and produce a voltage signal 512 that corresponds to the received photocurrent. For example, the APD 400 may produce a pulse of photocurrent in response to a received pulse of light, and the voltage signal 512 may be an analog voltage pulse that corresponds to the pulse of photocurrent. The amplifier 511 may include a TIA 510 configured to receive the photocurrent i and amplify the photocurrent to produce a voltage signal 512 (e.g., a voltage pulse) that corresponds to the photocurrent signal. Alternatively, the amplifier 511 may include a TIA 510 followed by a voltage-gain circuit 520. The TIA 510 may amplify the photocurrent i to produce an intermediate voltage signal (e.g., a voltage pulse), and the voltage-gain circuit 520 may amplify the intermediate voltage signal to produce a voltage signal 512 (e.g., an amplified voltage pulse). An amplifier 511 or a TIA 510 may include an electronic filter (e.g., a low-pass, high-pass, or band-pass filter) that filters the photocurrent i or the voltage signal 512. The transimpedance gain or amplification of a TIA 510 may be expressed in units of ohms (Ω), or equivalently volts per ampere (V/A). For example, if a TIA 510 has a gain of 100 V/A, then for a photocurrent i with a peak current of 10 μA, the TIA 510 may produce a voltage signal 512 with a corresponding peak voltage of approximately 1 mV.

In FIG. 10, the voltage signal 512 produced by the amplifier 511 is coupled to N comparators (comparators 530-1, 530-2, . . . , 530-N), and each comparator is supplied with a particular threshold or reference voltage (V_{T1}, V_{T2}, . . . , V_{TN}). A signal-detection circuit 500 may include 1, 2, 5, 10, 50, 100, 500, 1000, or any other suitable number of comparators 530. The signal-detection circuit 500 in FIG. 9 includes one comparator 530. In FIG. 10, the signal-detection circuit 500 may include N=10 comparators, and the threshold voltages may be set to 10 values between 0 volts and 1 volt (e.g., V_{T1}=0.1 V, V_{T2}=0.2 V, and V_{T10}=1.0 V). Each comparator may produce an electrical-edge signal (e.g., a rising or falling electrical edge) when the voltage signal 512 rises above or falls below a particular threshold voltage. For example, comparator 530-2 may produce a rising edge when the voltage signal 512 rises above the threshold voltage V_{T2}. Additionally or alternatively, comparator 530-2 may produce a falling edge when the voltage signal 512 falls below the threshold voltage V_{T2}.

The signal-detection circuit 500 in FIG. 10 includes N time-to-digital converters (TDCs 540-1, 540-2, . . . , 540-N), and each comparator is coupled to one TDC 540. Each comparator-TDC pair in FIG. 10 (e.g., comparator 530-1 and TDC 540-1) may be referred to as a threshold detector. A comparator may provide an electrical-edge signal to a corresponding TDC, and the TDC may act as a timer that produces an electrical output signal (e.g., a digital signal, a digital word, or a digital value) that represents a time when the edge signal is received from the comparator. For example, if the voltage signal 512 rises above the threshold voltage V_{T1}, then the comparator 530-1 may produce a rising-edge signal that is supplied to the input of TDC 540-1, and the TDC 540-1 may produce a digital time value corresponding to a time when the edge signal was received by TDC 540-1. The digital time value may be referenced to the time when a pulse of light is emitted by a light source 110, and the digital time value may correspond to or may be used to determine a round-trip time for the pulse of light to travel from a lidar system 100, to a target 130, and back to the lidar system 100. Additionally, if the voltage signal 512 subsequently falls below the threshold voltage V_{T1}, then the comparator 530-1 may produce a falling-edge signal that is supplied to the input of TDC 540-1, and the TDC 540-1 may produce a digital time value corresponding to a time when the edge signal was received by TDC 540-1.

In particular embodiments, an output signal of a signal-detection circuit 500 may include an electrical signal that corresponds to a received pulse of light. For example, the signal-detection output signal in FIG. 10 may be a digital signal that corresponds to the analog voltage signal 512, which in turn corresponds to the photocurrent signal i, which in turn corresponds to a received pulse of light. If an input light signal 135 includes a received pulse of light, the signal-detection circuit 500 may receive a photocurrent i (e.g., a pulse of current) and produce an output signal that corresponds to the received pulse of light. The output signal may include one or more digital time values from each of the TDCs 540 that received one or more edge signals from a comparator 530, and the digital time values may represent the analog voltage signal 512. The output signal from a signal-detection circuit 500 may be sent to a controller 150, and a time of arrival for the received pulse of light (which may be referred to as a time of receipt) may be determined based at least in part on the one or more time values produced by the TDCs. For example, the time of arrival may be determined from a time associated with a peak (e.g., Vₚₑₐₖ) of the voltage signal 512, a time associated with a temporal center (e.g., a centroid or weighted average) of the voltage signal 512, or a time associated with a rising edge of the voltage signal 512. The output signal in FIG. 10 may correspond to the electrical output signal 145 in FIG. 1.

In particular embodiments, a signal-detection output signal may include one or more digital values that correspond to (1) a time when a pulse of light is emitted or (2) a time when a received pulse of light is detected by a receiver 140. The output signal in FIG. 10 may include digital values from each of the TDCs that receive an edge signal from a comparator, and each digital value may represent a time interval between the emission of an optical pulse by a light source 110 and the receipt of an edge signal from a comparator. For example, a light source 110 may emit a pulse of light that is scattered by a target 130, and a receiver 140 may receive a portion of the scattered pulse of light as an input pulse of light. When the light source emits the pulse of light, a count value of the TDCs may be reset to zero counts. Alternatively, the TDCs in receiver 140 may accumulate counts continuously over multiple pulse periods (e.g., for 10, 100, 1,000, 10,000, or 100,000 pulse periods), and when a pulse of light is emitted, a TDC count associated with the pulse emission may be stored in memory. After the pulse of light is emitted, the TDCs may continue to accumulate counts that correspond to elapsed time (e.g., the TDCs may count in terms of clock cycles or some fraction of clock cycles).

In FIG. 10, when TDC 540-1 receives an edge signal from comparator 530-1, the TDC 540-1 may produce a digital signal that represents the time interval between emission of the pulse of light and receipt of the edge signal. For example, the digital signal may include a digital value that corresponds to the number of clock cycles that elapsed between emission of the pulse of light and receipt of the edge signal. Alternatively, if the TDC 540-1 accumulates counts over multiple pulse periods, then the digital signal may include a digital value that corresponds to the TDC count at the time of receipt of the edge signal. The signal-detection output signal may include digital values corresponding to one or more times when a pulse of light was emitted and one or more times when a TDC received an edge signal. An output signal from a signal-detection circuit 500 may correspond to a received pulse of light and may include digital values from each of the TDCs that receive an edge signal from a comparator. The output signal may be sent to a controller 150, and the controller may determine a distance D to the target 130 based at least in part on the output signal. Additionally or alternatively, the controller 150 may determine an optical characteristic of a received pulse of light based at least in part on the output signal received from the TDCs of a signal-detection circuit 500.

In particular embodiments, a receiver 140 of a lidar system 100 may include one or more analog-to-digital converters (ADCs). As an example, instead of including multiple comparators and TDCs, a receiver 140 may include an ADC that receives a voltage signal 512 from amplifier 511 and produces a digital representation of the voltage signal 512. Although this disclosure describes or illustrates example receivers 140 that include one or more comparators 530 and one or more TDCs 540, a receiver 140 may additionally or alternatively include one or more ADCs. As an example, in FIG. 10, instead of the N comparators 530 and N TDCs 540, the receiver 140 may include an ADC configured to receive the voltage signal 512 and produce a digital output signal that includes digitized values that correspond to the voltage signal 512.

The example voltage signal 512 illustrated in FIG. 10 corresponds to a received pulse of light. The voltage signal 512 may be an analog signal produced by an electronic amplifier 511 and may correspond to a pulse of light detected by the receiver 140 in FIG. 10. The voltage levels on the y-axis correspond to the threshold voltages V_{T1}, V_{T2}, . . . , V_{TN} of the respective comparators 530-1, 530-2, . . . , 530-N. The time values t₁, t₂, t₃, . . . , t_{N-1} correspond to times when the voltage signal 512 exceeds the corresponding threshold voltages, and the time values t′₁, t′₂, t′₃, . . . , t′_{N-1} correspond to times when the voltage signal 512 falls below the corresponding threshold voltages. For example, at time t′₁ when the voltage signal 512 exceeds the threshold voltage V_{T1}, comparator 530-1 may produce an edge signal, and TDC 540-1 may output a digital value corresponding to the time t₁. Additionally, the TDC 540-1 may output a digital value corresponding to the time t′₁ when the voltage signal 512 falls below the threshold voltage V_{T1}. Alternatively, the receiver 140 may include an additional TDC (not illustrated in FIG. 10) configured to produce a digital value corresponding to time t′₁ when the voltage signal 512 falls below the threshold voltage V_{T1}. The output signal from signal-detection circuit 500 may include one or more digital values that correspond to one or more of the time values t₁, t₂, t₃, . . . , t_{N-1} and t′₁, t′₂, t′₃, . . . , t′_{N-1}. Additionally, the output signal may also include one or more values corresponding to the threshold voltages associated with the time values. Since the voltage signal 512 in FIG. 10 does not exceed the threshold voltage V_{TN}, the corresponding comparator 530-N may not produce an edge signal. As a result, TDC 540-N may not produce a time value, or TDC 540-N may produce a signal indicating that no edge signal was received.

In particular embodiments, an output signal produced by a signal-detection circuit 500 of a receiver 140 may correspond to or may be used to determine an optical characteristic of a received pulse of light detected by the receiver 140. An optical characteristic of a received pulse of light may include a peak optical intensity, a peak optical power, an average optical power, an optical energy, a shape or amplitude, a time of receipt, a temporal center, a rising or falling edge, a round-trip time of flight, or a temporal duration or width of the received pulse of light. One or more of the approaches for determining an optical characteristic of a received pulse of light as described herein may be implemented using a receiver 140 that includes one or more comparators 530 and TDCs 540 or using a receiver 140 that includes one or more ADCs. For example, an optical characteristic of a received pulse of light may be determined from an output signal provided by multiple TDCs 540 of a signal-detection circuit 500 (as illustrated in FIG. 10), or an optical characteristic may be determined from an output signal provided by one or more ADCs of a signal-detection circuit.

A round-trip time of flight (e.g., a time for an emitted pulse of light to travel from the lidar system 100 to a target 130 and back to the lidar system 100) may be determined based on a difference between a time of receipt and a time of emission for a pulse of light, and the distance D to the target 130 may be determined based on the round-trip time of flight. A time of receipt for a received pulse of light may correspond to (i) a time associated with a peak of voltage signal 512, (ii) a time associated with a temporal center of voltage signal 512, or (iii) a time associated with a rising edge of voltage signal 512. For example, in FIG. 10 a time associated with the peak voltage (Vₚₑₐₖ) may be determined based on the threshold voltage V_{T(N-1)} (e.g., an average of the times t_{N-1} and t′_{N-1} may correspond to the peak-voltage time). As another example, a curve-fit or interpolation operation may be applied to the values of a signal-detection output signal to determine a time associated with the peak voltage. A curve may be fit to the values of a signal-detection output signal to produce a curve that approximates the shape of a received optical pulse, and a time associated with the peak of the curve may correspond to the peak-voltage time. As another example, a curve that is fit to the values of a signal-detection output signal may be used to determine a time associated with a rising edge or a temporal center of voltage signal 512 (e.g., the temporal center may be determined by calculating a centroid or weighted average of the curve).

A duration of a received pulse of light may be determined from a duration or width of a corresponding voltage signal 512. For example, the difference between two time values of a signal-detection output signal may be used to determine a duration of a received pulse of light. In the example of FIG. 10, the duration of the pulse of light corresponding to voltage signal 512 may be determined from the difference (t′₃−t₃), which may correspond to a received pulse of light with a pulse duration of 4 nanoseconds. As another example, a controller 150 may apply a curve-fit or interpolation operation to the values of the signal-detection output signal, and the duration of the pulse of light may be determined based on a width of the curve (e.g., a full width at half maximum of the curve).

In particular embodiments, a temporal correction or offset may be applied to a determined time of emission or time of receipt to account for signal delay within a lidar system 100. For example, there may be a time delay of 2 ns between an electrical trigger signal that initiates emission of a pulse of light and a time when the emitted pulse of light exits the lidar system 100. To account for the 2-ns time delay, a 2-ns offset may be added to an initial time of emission determined by a receiver 140 or a processor of the lidar system 100. For example, a receiver 140 may receive an electrical trigger signal at time t_{TRIG} indicating emission of a pulse of light by light source 110. To compensate for the 2-ns delay between the trigger signal and the pulse of light exiting the lidar system 100, the emission time of the pulse of light may be indicated as (t_{TRIG}+2 ns). Similarly, there may be a 1-ns time delay between a received pulse of light entering the lidar system 100 and a time when electrical edge signals corresponding to the received pulse of light are received by one or more TDCs 540 of a receiver 140. To account for the 1-ns time delay, a 1-ns offset may be subtracted from a determined time of receipt.

In particular embodiments, a processor or a receiver 140 may determine, based on a photocurrent signal i produced by an APD 400, a round-trip time T for a portion of an emitted optical signal to travel to a target 130 and back to a lidar system 100. Determining the round-trip time may include (i) determining a time of emission for the optical signal or (ii) determining a time of receipt of the portion of the emitted optical signal. Additionally, a processor or a receiver 140 may determine a distance D from the lidar system 100 to the target 130 based on the round-trip time T For example, an APD 400 may produce a pulse of photocurrent i in response to a received pulse of light, and a receiver 140 may produce a voltage pulse (e.g., voltage signal 512) corresponding to the pulse of photocurrent. Based on the voltage signal 512, the receiver 140 or a processor may determine a time of receipt for the received pulse of light. Additionally, the receiver 140 or processor may determine a time of emission for a pulse of light (e.g., a time at which the pulse of light was emitted by a light source 110), where the received pulse of light includes scattered light from the emitted pulse of light. Based on the time of receipt and the time of emission, the receiver 140 or processor may determine the round-trip time T and the distance D. For example, based on the time of receipt (T_{R}) and the time of emission (T_{E}), the receiver 140 or processor may determine the round-trip time T (e.g., T=T_{R}−T_{E}), and the distance D may be determined from the expression D=c·T/2.

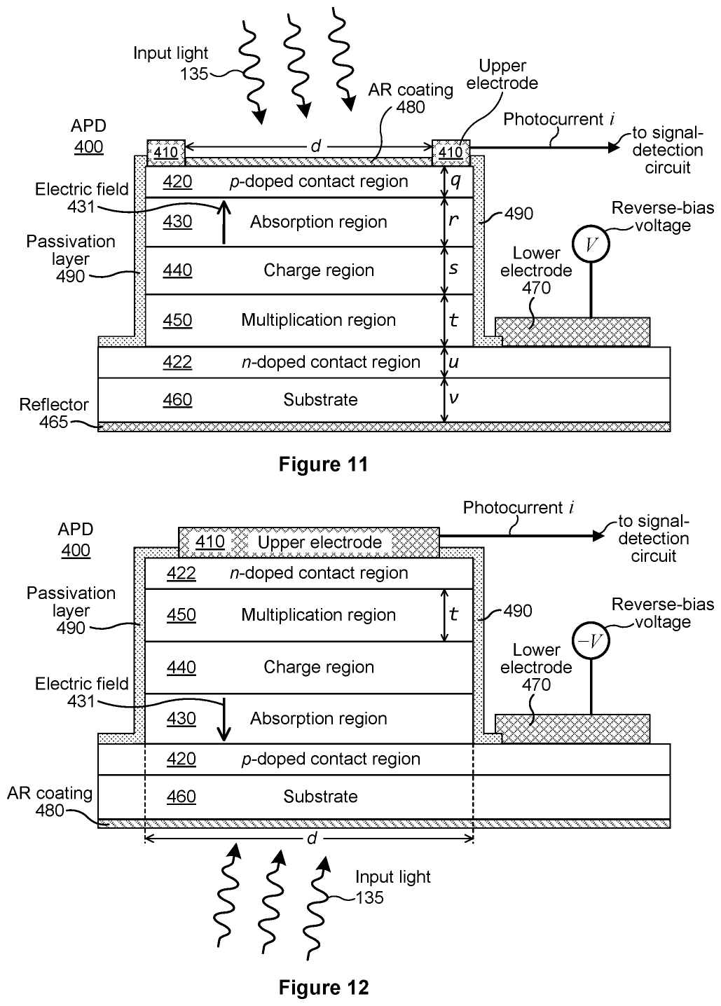

FIGS. 11 and 12 each illustrates an example avalanche photodiode 400. In particular embodiments, a lidar system 100 may include a light source 110 that emits an optical signal (e.g., output beam 125 in FIGS. 1-4) and a receiver 140 that detects an input optical signal (e.g., input light 135) that includes a portion of the emitted optical signal scattered by a target 130 located a distance D from the lidar system 100. The receiver 140 may include one or more avalanche photodiodes (APDs) 400 configured to receive the input optical signal and produce a photocurrent signal i corresponding to the input optical signal. The photocurrent signal i corresponding to the input optical signal may refer to the photocurrent signal having one or more temporal or frequency-domain characteristics that are approximately equal to that of the input optical signal. For example, the emitted optical signal may include a pulse of light that scatters from a target 130, and the input optical signal may include a portion of the scattered pulse of light. The receiver 140 may include an APD 400 that receives the portion of the scattered pulse of light and produces a photocurrent signal i that includes a pulse of electrical current that corresponds to the received pulse of light. The pulse of electrical current corresponding to the received pulse of light may refer to the pulse of electrical current having a rise-time, fall-time, or duration that is (i) greater than or equal to a corresponding rise-time, fall-time, or duration of the received pulse of light and (ii) less than or equal to three times the corresponding rise-time, fall-time, or duration of the received pulse of light. For example, the received pulse of light may have a 2-ns rise time and the corresponding pulse of electrical current produced by the APD 400 may have a 3-ns rise time. As another example, the received pulse of light may have a 6-ns duration, and the corresponding pulse of electrical current may have a 12-ns duration.

In particular embodiments, an APD 400 may include one or more electrodes, one or more contact regions, one or more intrinsic regions, one or more absorption regions, one or more charge regions, one or more multiplication regions, one or more substrates, one or more anti-reflection (AR) coatings, one or more reflectors, one or more passivation layers, one or more graded band-gap regions, one or more buffer regions, or one or more guard rings. Each of the APDs 400 in FIGS. 11-12 includes two electrodes 410 and 470, two contact regions 420 and 422, an absorption region 430, a charge region 440, a multiplication region 450, a substrate 460, an anti-reflection (AR) coating 480, and a passivation layer 490. Additionally, the APD 400 in FIG. 11 includes a reflector 465. Each of the contact regions 420 and 422, absorption region 430, charge region 440, multiplication region 450, and substrate 460 may include a semiconductor material having a particular composition and a particular density of dopants (e.g., n-doped, p-doped, or undoped).

In particular embodiments, an APD 400 may have a mesa structure. An APD 400 with a mesa structure may include one or more regions or layers that extend above a plane of the substrate 460 and may be formed by etching away surrounding material to leave the mesa structure formed by the APD. The sides of the mesa structure (which may be referred to as sidewalls) may be formed by etching away the surrounding material and may be coated with a passivation layer 490. The passivation layer 490 may be an electrically insulating material configured to protect the regions or layers of the APD 400 from damage from the environment (e.g., from air or water vapor) or to electrically isolate the regions or layers from each other or from materials external to the APD 400. A passivation layer 490 may include one or more of silicon dioxide (SiO₂), indium phosphide (InP), polyimide, benzocyclobutene (BCB) polymer, aluminum oxide (Al₂O₃), titanium dioxide (TiO₂), aluminum nitride (AlN), zinc oxide (ZnO), and zinc sulfide (ZnS).

Each of the APDs 400 in FIGS. 11-12 has a mesa structure in which the contact region 420, absorption region 430, charge region 440, and multiplication region 450 extend above a plane of the substrate 460. The mesa structure in each of FIGS. 11-12 has a rectangular cross-sectional shape with vertical sidewalls that are not sloped. In other embodiments, a mesa structure may have an approximately trapezoidal cross-sectional shape with the narrower side of the trapezoid located away from the substrate 460 and the wider side located near the substrate 460. A mesa structure with a trapezoidal cross section may have sidewalls that are sloped. In each of FIGS. 11-12, the upper electrode 410 and the lower electrode 470 are located at different heights with respect to a plane of the substrate 460. In other embodiments, an APD 400 with a mesa structure may have two electrodes located at approximately the same height. For example, the upper electrode 410 may extend down a sidewall and above a portion of a passivation layer 490 to provide an electrical contact that is adjacent to and at approximately the same height as the lower electrode 470. Upper and lower electrodes may be referred to as first and second electrodes, anode and cathode contacts, or p-side and n-side contacts.

In each of FIGS. 11 and 12, the APD 400 receives input light 135 and detects the input light 135 by producing a photocurrent signal i that corresponds to the received input light 135. The photocurrent signal i produced by the APD 400 may be directed to a signal-detection circuit 500, such as that illustrated in FIG. 9 or 10. For example, an APD 400 may be electrically coupled to a TIA 510, and the photocurrent signal i may be sent to the TIA 510 which produces a voltage signal that corresponds to the photocurrent signal. An APD 400 may be directly coupled to a TIA 510 or may be AC-coupled to a TIA 510, for example, by a series capacitor located between the APD 400 and the TIA 510. The photocurrent signal i may be supplied to a signal-detection circuit 500 from the anode or cathode of the APD 400. In FIG. 11, the photocurrent i is supplied from the anode (or, p-side) of the APD 400, and in FIG. 12, the photocurrent i is supplied from the cathode (or, n-side) of the APD 400. The p-side of the APD 400 refers to the p-doped end and includes the p-doped contact region 420 in FIGS. 11 and 12. The n-side of the APD 400 refers to the n-doped end and includes the n-doped contact region 422.

In particular embodiments, an APD 400 may be configured to operate in a reverse-biased mode, and a receiver 140 may include a voltage source that applies a reverse-bias voltage V to the APD 400. In FIG. 11, a positive voltage V is applied to the lower electrode 470 with respect to the upper electrode 410, where the lower electrode 470 is electrically coupled to the n-doped end of the APD 400. In FIG. 12, a negative voltage −V is applied to the lower electrode 470 with respect to the upper electrode 410, where the lower electrode 470 is electrically coupled to the p-doped end of the APD 400. The configuration and reverse biasing of the APD 400 in FIG. 12 is inverted with respect to the APD 400 in FIG. 11, but in both FIGS. 11 and 12, the APD 400 is reverse biased so that the electric potential of the n-side of the APD 400 is V volts above the potential of the p-side. A reverse-bias voltage of ±V may be applied to an upper electrode 410 or a lower electrode 470, and V may have any suitable value, such as for example approximately 10 V, 20 V, 30 V, 50 V, 75 V, 100 V, or 200 V. As an example, a reverse-bias voltage of greater than 20 volts may be applied to an APD 400. As another example, a 40-V to 50-V reverse-bias voltage may be applied to an APD 400. In FIG. 11, a reverse-bias voltage of +40 V may be applied to the lower electrode 470 (which is in ohmic contact with the n-doped contact region 422) with respect to the upper electrode 410 (which is in ohmic contact with the p-doped contact region 420). In FIG. 12, a reverse-bias voltage of −40 V may be applied to the lower electrode 470 (which is in ohmic contact with the p-doped contact region 420) with respect to the upper electrode 410 (which is in ohmic contact with the n-doped contact region 422).

An upper electrode 410 or lower electrode 470 of an APD 400 may include any suitable electrically conductive material, such as for example a metal (e.g., gold, palladium, titanium, platinum, aluminum, nickel, or indium), a transparent conductive oxide (e.g., indium tin oxide), a carbon-nanotube material, or a highly doped semiconductor material. For example, an upper electrode 410 and a lower electrode 470 may each include one or more metals that are deposited as a thin film onto a surface of the APD 400. Each of the metal electrodes may make a low resistance ohmic contact with one of the contact regions 420 and 422. The contact regions 420 and 422 may each include a semiconductor material that is heavily doped to provide low electrical resistance and an ohmic contact with the corresponding electrodes 410 and 470. In the example of FIG. 11, the p-doped contact region 420 may be heavily doped with an acceptor-type dopant (e.g., dopant density >10¹⁸ atoms/cm³), and the n-doped contact region 422 may be heavily doped with a donor-type dopant.

In particular embodiments, an upper electrode 410 or a lower electrode 470 may be at least partially transparent or may have an opening to allow input light 135 to pass through to the absorption region 430 of the APD 400. In FIG. 11, the upper electrode 410 may have a ring shape with a circular opening of diameter d or a square opening with side length d. The upper electrode 410 may at least partially surround the active region of the APD, where the active region refers to an area over which the APD 400 may receive and detect input light 135. The active region of an APD 400 may have any suitable diameter or length d, such as for example, a diameter or length of approximately 25 μm, 50 μm, 80 μm, 100 μm, 200 μm, 500 μm, 1 mm, 2 mm, or 5 mm.

In particular embodiments, an APD 400 may include an absorption region 430 configured to (i) absorb at least a portion of input light 135 and (ii) produce electronic carriers corresponding to the absorbed portion of the input light 135. The electronic carriers produced in the absorption region 430 may include electrons and holes and may be referred to as carriers or photogenerated carriers. Each photon from input light 135 that is absorbed in the absorption region 430 may produce one electron and one hole (which may be referred to as an electron-hole pair). For example, if the input light 135 includes a pulse of light with 1,000 photons, the absorption region may absorb approximately 800 of the photons (corresponding 80% absorption of the input light 135) and produce 800 electrons and 800 holes corresponding to the 800 absorbed photons. The absorption region 430 of an APD 400 may be configured to absorb greater than or equal to 50%, 70%, 80%, 90%, 95%, or 99% of the received input light 135. For example, the band gap of the semiconductor material that makes up the absorption region 430 may be configured so that the semiconductor material substantially absorbs light at one or more operating wavelengths of a lidar system 100.

The absorption region 430 may have a band gap that is less than an energy of the photons of input light 135. The band gap may refer to an energy difference between the top of the valence band and the bottom of the conduction band of the semiconductor material that makes up the absorption region 430. For example, a lidar system 100 may have an operating wavelength of 1550 nm, which corresponds to an energy of approximately 0.8 electron-volts (eV) per photon, and the absorption region 430 may have a band gap of approximately 0.7 eV. Since the photon energy of 0.8 eV is greater than the 0.7-eV band gap of the absorption region 430, most of the photons of the input beam 135 (which may have a wavelength of approximately 1550 nm) may be absorbed in the absorption region 430. Each photon that is absorbed may promote an electron from the valence band to the conduction band, which results in the production of an electron-hole pair. In FIG. 11, the input light 135 may pass through the p-doped contact region 420 and then may be substantially absorbed in the absorption region 430. In this case, the p-doped contact region 420 may have a band gap that is greater than the energy of the photons of input light 135 so that the p-doped contact region 420 is substantially transparent to the input light 135. In FIG. 12, the input light 135 may pass through the substrate 460 and the p-doped contact region 420 to reach the absorption region 430. In this case, the substrate 460 and the p-doped contact region 420 may each have a band gap that is greater than the photon energy of input light 135.

In a reverse-biased APD 400, the electric field in the APD that results from the applied reverse-bias voltage points from the n-side to the p-side. Holes, which are positively charged, will drift in the direction of an electric field, while electrons, which are negatively charged, will drift in the opposite direction. In FIG. 11, the electric field 431 in the absorption region 430 is directed toward the p-doped contact region 420. This direction of the electric field 431 indicates that (i) the holes generated in the absorption region 430 through photo-absorption of the input light 135 may drift away from the multiplication region 450 and toward the p-doped contact region 420 and (ii) the electrons generated in the absorption region 430 may drift toward the multiplication region 450 via the charge region 440. In other APD configurations, the holes generated in the absorption region may drift toward the multiplication region, and the electrons generated in the absorption region may drift away from the multiplication region. For example, in FIG. 11, the locations of the absorption region 430 and the multiplication region 450 may be interchanged. In this case, the holes generated in the absorption region 430 may drift toward the multiplication region 450 via the charge region 440, and the electrons generated in the absorption region 430 may drift toward the n-doped contact region 422. In particular embodiments, an APD 400 may include a charge region 440 located between the absorption region 430 and the multiplication region 450. The charge region 440 may be a layer of semiconductor material that separates the absorption region 430 and the multiplication region 450. Additionally, the charge region 440 may have a particular composition or dopant density that is configured to minimize band-gap discontinuities between the absorption region 430 and the multiplication region 450 and provide appropriate electric-field distribution.

In particular embodiments, a multiplication region 450 of an APD 400 may receive a portion of photogenerated carriers from an absorption region 430, and the multiplication region 450 may produce additional electronic carriers by impact ionization. Depending on the configuration of the APD 400, the portion of photogenerated carriers that are received from the absorption region 430 and that initiate impact-ionization events in the multiplication region 450 may be made up of primarily electrons or primarily holes. For example, in FIG. 11, greater than 90% of the impact-ionization events may be initiated by electrons. In the multiplication region 450 (which may be referred to as a multiplication layer, avalanche region, avalanche layer, gain layer, or gain region), an avalanche-multiplication process may occur where photogenerated carriers (e.g., electrons or holes) produced in the absorption region 430 collide with the semiconductor lattice of the multiplication region 450 and produce additional carriers through impact ionization. In addition to the original carrier that collided with the semiconductor lattice, each impact-ionization event (e.g., one electron colliding with the semiconductor lattice) may produce an electron and a hole. Some of the carriers generated through impact ionization may in turn produce additional carriers through additional impact-ionization events. In this manner, an avalanche process may repeat numerous times so that one photogenerated carrier may result in the generation of multiple carriers. As an example, a single photon absorbed in the absorption region 430 may lead to the generation of approximately 4, 5, 10, 20, 30, 40, 50, 100, 200, 500, or any other suitable number of carriers in the multiplication region 450 through an avalanche-multiplication process. The number of carriers generated from a single photogenerated carrier may be referred to as the gain of the APD 400. For example, the gain of an APD 400 may be greater than or equal to 4, 5, 10, 20, 30, 40, 50, 100, 200, or 500.

The impact-ionization events in the multiplication region 450 may be initiated primarily by photogenerated electrons or primarily by photogenerated holes. In FIG. 11, most of the impact-ionization events may be initiated by photogenerated electrons produced in the absorption region 430, while the photogenerated holes produced in the absorption region 430 may initiate few to none of the impact-ionization events (since most of the photogenerated holes may be directed by the electric field 431 away from the multiplication region 450 and toward the p-doped contact region 420). In other APD configurations, impact ionization may be initiated primarily by holes instead of electrons. For example, in FIG. 11, the locations of the absorption region 430 and the multiplication region 450 may be interchanged, and impact ionization may be initiated primarily by photogenerated holes produced in the absorption region 430 (since most of the photogenerated electrons may be directed away from the multiplication region 450).

In particular embodiments, the gain of an APD 400 (e.g., the number of carriers generated from a single photogenerated carrier) may increase as the applied reverse bias V is increased. If the applied reverse bias V is increased above a particular value referred to as the APD breakdown voltage, then a single carrier may trigger a self-sustaining avalanche process in which the output of the APD 400 is saturated regardless of the input light level. An APD 400 that is operated at or above a breakdown voltage may be referred to as a single-photon avalanche diode (SPAD) and may be referred to as operating in a Geiger mode or a photon-counting mode. An APD 400 operated below a breakdown voltage may be referred to as a linear APD 400 or a linear-mode APD 400, and the output current produced by the APD may be sent to an analog amplifier circuit (e.g., a TIA 510 or amplifier 511).

The carriers generated in an APD 400 may produce an electrical current which may be referred to as a photocurrent (i), a photocurrent signal, an output photocurrent, or an output current. The photocurrent i may include (i) an initial photocurrent (iₚ) that includes photogenerated carriers produced through absorption of the input light 135 in the absorption region 430 and (ii) a multiplied photocurrent (iₘ) that includes additional carriers produced by impact ionization in the multiplication region 450. The photocurrent i may be approximately equal to the sum of iₚ and iₘ so that the photocurrent i includes at least a portion of the photogenerated carriers and at least a portion of the additional electronic carriers produced by impact ionization. Since a single photogenerated carrier may produce multiple additional carriers through impact ionization, most of the electronic carriers in the photocurrent i may result from impact ionization. For example, greater than 80% of the carriers in a photocurrent i may result from impact ionization, while less than 20% of the carriers in the photocurrent may result from photogeneration (e.g., iₘ may be greater than four times iₚ). The photocurrent i may represent an electrical current produced by an APD 400 in response to detection of input light 135. In addition to the photocurrent i, the APD 400 may also produce other electrical currents, such as for example, current resulting from other received optical signals, dark current, thermally generated current, leakage current, or other types of unwanted electrical current.

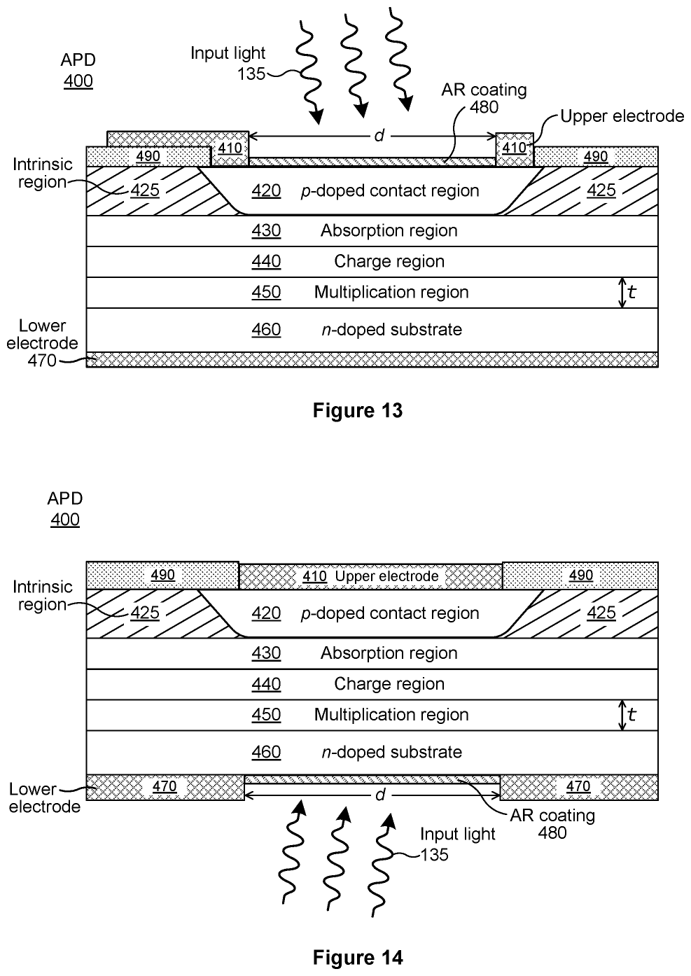

FIGS. 13 and 14 each illustrates an example planar avalanche photodiode 400. Each of the APDs 400 in FIGS. 13-14 includes two electrodes 410 and 470, a contact region 420, an intrinsic region 425, an absorption region 430, a charge region 440, a multiplication region 450, a substrate 460, an anti-reflection (AR) coating 480, and a passivation layer 490. The APDs 400 in FIGS. 13-14 may operate in a manner similar to the APDs 400 in FIGS. 11-12. For example, a reverse bias voltage may be applied between the upper electrode 410 and lower electrode 470, and photogenerated carriers may be produced in the absorption region 430 by optical absorption of at least a portion of the photons of input light 135. Some of the photogenerated carriers (e.g., primarily electrons or holes) may drift into the multiplication region 450 and produce additional carriers through impact ionization. The APD 400 may produce a photocurrent that includes at least a portion of the photogenerated carriers and at least a portion of the additional electronic carriers produced through impact ionization. The intrinsic region 425 may include an undoped semiconductor material that provides a region of low electrical conductivity that surrounds the p-doped contact region 420. The intrinsic region 425 may reduce the amount of unwanted leakage current or help to confine the photocurrent to the central portion of the APD 400.

In particular embodiments, an APD 400 may have a planar structure. An APD 400 with a planar structure may have a planarized configuration in which one or more regions or layers of the APD 400 do not form a mesa-like structure that projects above the substrate 460. Each of the APDs 400 in FIGS. 13-14 has a planar structure, while each of the APDs 400 in FIGS. 11-12 has a mesa structure.

An APD 400 may include any suitable combination of regions or layers that are positioned in any suitable configuration. For example, an APD 400 may be configured as a separate absorption and multiplication (SAM) device that includes an absorption region 430 and a multiplication region 450 (and may not include a separate or distinct charge region 440 or graded band-gap region). As another example, an APD 400 may be configured as a separate absorption, grading, charge, and multiplication (SAGCM) device that includes an absorption region 430, a graded band-gap region, a charge region 440, and a multiplication region 450. The APD 400 in each of FIGS. 11-14 is configured as a separate absorption, charge, and multiplication (SACM) device that includes an absorption region 430, a charge region 440, and a multiplication region 450. The regions or layers of an APD 400 may be located in any suitable position with respect to one another. For the three regions (absorption region 430, charge region 440, and multiplication region 450) in each of FIGS. 11-14, the APD 400 is configured with the absorption region 430 located closest to the p-doped contact region 420 and the multiplication region 450 located closest to the n-doped contact region 422 or n-doped substrate 460. In other APD configurations, the locations of the absorption region 430 and the multiplication region 450 may be interchanged so that the absorption region 430 is located closest to the n-side of the APD 400, and the multiplication region 450 is located closest to the p-side of the APD 400.

The regions or layers of an APD 400 may include any suitable semiconductor material having any suitable doping (e.g., n-doped, p-doped, or intrinsic undoped material). For example, the multiplication region 450 in FIG. 11 may include a semiconductor material that is undoped or n-doped, and the absorption region 430 may include a semiconductor material that is undoped or p-doped. Regions that are doped may be heavily doped (e.g., dopant density >10¹⁸ atoms/cm³) or lightly doped (e.g., dopant density <10¹⁶ atoms/cm³), or may have any other suitable dopant density. For example, the p-doped contact region 420 in FIG. 11 may be heavily doped with an acceptor-type dopant, and the n-doped contact region 422 may be heavily doped with a donor-type dopant. Dopants may include any suitable material, such as for example, one or more of tellurium, selenium, sulfur, tin, silicon, germanium, beryllium, zinc, chromium, magnesium, and carbon.

The regions or layers of an APD 400 may include any suitable semiconductor material having any suitable composition. For example, one or more regions or layers of an APD 400 may include one or more of the following semiconductor materials: indium phosphide (InP), indium arsenide (InAs), aluminum arsenide (AlAs), gallium arsenide (GaAs), indium antimonide (InSb), aluminum antimonide (AlSb), gallium antimonide (GaSb), antimony (Sb), aluminum gallium antimonide (AlₓGa₁₋ₓSb), gallium arsenide antimonide (GaAsₓSb₁₋ₓ), indium aluminum arsenide (InₓAl₁₋ₓAs), indium gallium arsenide (InₓGa₁₋ₓAs), aluminum arsenide antimonide (AlAsₓSb₁₋ₓ), indium gallium aluminum arsenide (InₓGa_{y}Al_{1-x-y}As), aluminum gallium arsenide antimonide (AlₓGa₁₋ₓAs_{y}Sb_{1-y}), aluminum indium arsenide antimonide (AlₓIn₁₋ₓAs_{y}Sb_{1-y}), where the parameters x and y provide the specific composition of a material and each parameter has any suitable value from 0 to 1.

Semiconductor materials that include combinations of two or more different elements may be referred to as alloys, semiconductor alloys, or semiconductor alloy materials. For example, GaAs may be referred to as a semiconductor alloy that includes the element gallium (Ga) and the element arsenic (As). A semiconductor alloy that includes two different elements may be referred to as a binary semiconductor alloy. For example, InP, InAs, AlAs, and GaAs may each be referred to as a binary semiconductor alloy. A semiconductor alloy that includes three different elements may be referred to as a ternary semiconductor alloy. For example, AlGaSb, GaAsSb, and InAlAs may each be referred to as a ternary semiconductor alloy. A semiconductor alloy that includes four different elements may be referred to as a quaternary semiconductor alloy. For example, InGaAlAs, AlGaAsSb, and AlInAsSb may each be referred to as a quaternary semiconductor alloy. Herein, the parameters x and y for a ternary or quaternary alloy may occasionally be omitted for ease of reading (e.g., InₓGa_{y}Al_{1-x-y}As may be written as InGaAlAs).

The regions or layers of an APD 400 may have any suitable thickness. In FIG. 11, the p-doped contact region 420 has a thickness q, the absorption region 430 has a thickness r, the charge region 440 has a thickness s, the multiplication region 450 has a thickness t, the n-doped contact region 422 has a thickness u, and the substrate 460 has a thickness v. The thickness v of the substrate 460 may be significantly larger than the combined thicknesses of the other regions of an APD 400. For example, the substrate thickness v may be approximately 100-1,000 μm, and the sum of the other thicknesses (q+r+s+t+u) may be approximately 1-20 μm. As another example, the substrate thickness v may be approximately 300 μm, and the sum of the other thicknesses (q+r+s+t+u) may be less than approximately 5 μm. As another example, the multiplication region 450 of an APD 400 may have a thickness t of approximately 100 nm to approximately 2,000 nm.

An APD 400 may be configured as a front-side illuminated device, a back-side illuminated device, a two-sided device that is illuminated from both sides, or an edge-illuminated device. The front side of an APD 400 may refer to the side opposite or away from the substrate 460, and the back-side of an APD 400 may refer to the side that includes or is closer to the substrate 460. The APD 400 in each of FIGS. 11 and 13 is a front-illuminated APD 400 in which the input light 135 enters the APD 400 through the side opposite the substrate 460. The APD 400 in each of FIGS. 12 and 14 is a back-illuminated APD 400 in which the input light 135 enters the APD 400 through the substrate 460. For a back-illuminated APD 400, the substrate 460 may be transparent to light at a wavelength of the input light 135 (e.g., the substrate may have a band gap that is greater than the photon energy of input light 135). The substrate 460 may receive the input light 135 and convey the input light 135 toward the absorption region 430. A two-sided APD 400 may be configured to receive two input beams of light, one through the front side (the side opposite the substrate 460) and another through the back side (through the substrate 460).

An APD 400 may include an anti-reflection (AR) coating 480 on an exterior surface of the APD 400, and the AR coating 480 may reduce a reflectivity of the exterior surface at a wavelength of the input light 135. Due to the relatively high refractive index of semiconductor materials, a surface of a semiconductor material that does not have an AR coating may have a fairly high reflectivity at a lidar-system operating wavelength, such as for example a reflectivity of greater than approximately 10%, 20%, or 30%. An AR coating 480 may be applied to an input surface (e.g., an exterior surface on the front side or back side of the APD 400) through which the input light 135 enters the APD 400. By applying the AR coating 480 to an input surface of an APD 400, a greater amount of the input light 135 may be transmitted into the APD 400, and less of the input light 135 may be lost due to reflection by the input surface. An AR coating 480 may provide a surface with any suitable reflectivity at an operating wavelength of a lidar system 100, such as for example a reflectivity of less than or equal to 5%, 2%, 1%, 0.5%, or 0.1%. For example, output beam 125 and input light 135 may each have a wavelength of approximately 1550 nm, and an AR coating 480 may provide a reflectivity of less than 1% at 1550 nm. In FIG. 11, the input light 135 enters the APD 400 through the exterior surface of the p-doped contact region 420. The exterior surface of the p-doped contact region 420 has an AR coating 480 that reduces the reflectivity of the surface at a wavelength of the input light 135. In FIG. 12, the input light 135 enters the APD 400 through the exterior surface of the substrate 460. The exterior surface of the substrate 460 has an AR coating 480 that reduces the reflectivity of the surface at a wavelength of the input light 135. A two-sided APD 400 may have an AR coating 480 on each of its two input surfaces (one surface on the front side and another surface on the back side).

An APD 400 may include a reflective material 465 located on a surface opposite the input surface through which input light 135 enters the APD 400. The reflective material 465 may include a reflective metal or a reflective dielectric coating. In FIG. 11, the input light 135 enters the APD 400 through the top surface (which may be referred to as the input surface), and the exterior surface of the substrate 460 includes a reflector 465 (which may be referred to as a reflective material). In FIG. 12, the upper electrode 410 may include one or more metals, and the upper electrode 410 may act as a reflective material that reflects a portion of the input light 135 back toward the absorption region 430. A reflector 465 may receive a portion of the input light 135 that propagates from the input surface, through the APD 400, and to the reflector 465. The reflector 465 may reflect the received portion of the input light 135 back through the APD 400 toward the absorption region 430. The reflector 465 may provide a second pass of the input light 135 through the APD 400 to increase the efficiency of the APD 400 by increasing the amount of input light 135 that is absorbed by the absorption region 430. For example, the absorption region 430 may absorb approximately 80% of the input light 135 on its first pass through the absorption region 430. The reflector 465 may reflect the approximately 20% of the input light 135 that is not absorbed on the first pass, and the absorption region 430 may absorb approximately 80% of the 20% portion of the input light 135 on its second pass through the absorption region 430. The double-pass configuration provided by the reflector 465 may result in approximately 96% absorption of the input light 135, rather than the approximately 80% absorption from a single-pass configuration.

An APD 400 may be configured to detect light having one or more wavelengths between approximately 900 nm and approximately 2000 nm. A lidar system 100 may have a single operating wavelength (e.g., 1550 nm), multiple operating wavelengths (e.g., 1530 nm and 1550 nm), or may operate over one or more wavelength ranges (e.g., 1500-1560 nm). An APD 400 may be configured to detect input light 135 at the one or more operating wavelengths of the lidar system 100. For example, an APD 400 may be configured to detect input light 135 having a wavelength of approximately 905 nm, 1100 nm, 1400 nm, 1500 nm, 1550 nm, 1600 nm, 1700 nm, or 2000 nm, or any other suitable wavelength, combination of wavelengths, or wavelength ranges. The wavelength range over which an APD 400 may detect light may correspond to the wavelength range over which the absorption region 430 absorbs light. The absorption region 430 may be configured to absorb photons corresponding to the operating wavelength of the lidar system 100, and the composition of the absorption region 430 may be selected so that the semiconductor material of the absorption region 430 has a maximum optical absorption at the one or more operating wavelengths of a lidar system 100. For example, the composition of the absorption region 430 may be selected so that the band gap of the absorption region 430 is less than the photon energy of the input light 135. Additionally, the composition of other regions that the input light 135 passes through may be selected to have a minimum optical absorption (e.g., the composition of the p-doped contact region 420 in FIG. 11 may be selected so that its band gap is larger than the photon energy of the input light 135).

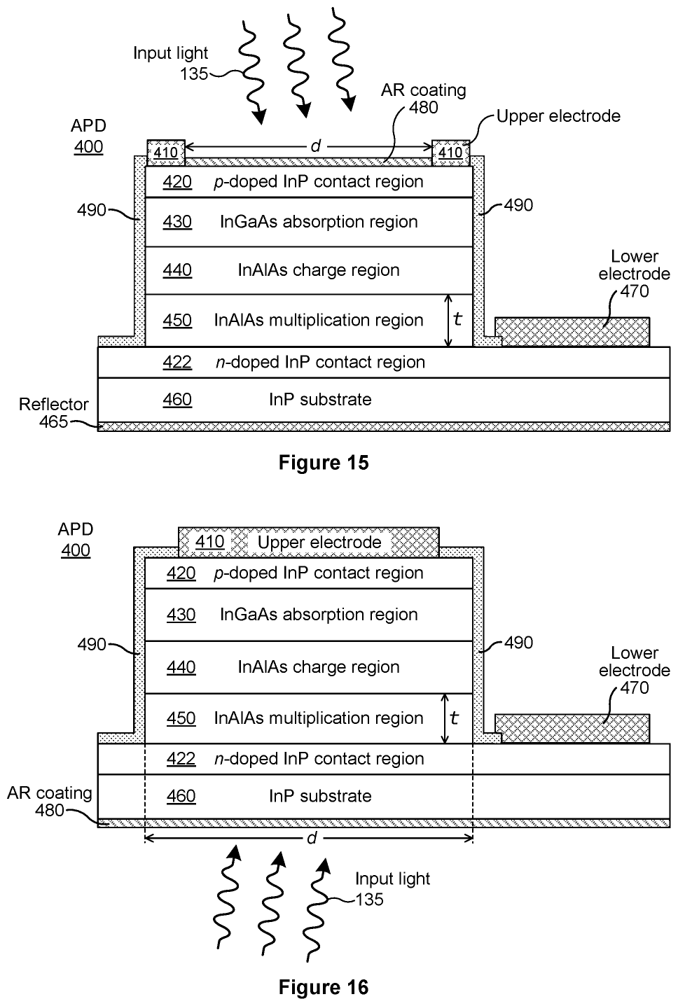

FIGS. 15 and 16 each illustrates an example avalanche photodiode 400 with an indium-aluminum-arsenide (InAlAs) multiplication region 450. The APD 400 in each of FIGS. 15-16 may be referred to as an InGaAs APD, an InAlAs APD, or an InGaAlAs APD. The APD 400 in FIG. 15 is front-side illuminated, and the APD 400 in FIG. 16 is back-side illuminated. In each of FIGS. 15-16, the absorption region 430 includes InₓGa₁₋ₓAs, the charge region 440 includes InₓAl₁₋ₓAs, and the multiplication region 450 includes InₓAl₁₋ₓAs, where the parameter x may have any suitable value from 0 to 1 in each of the regions. For example, the absorption region 430 may have a composition of In_{0.53}Ga_{0.47}As, where the parameter x is 0.53, and the multiplication region 450 may have a composition of In_{0.52}Al_{0.48}As, where the parameter x is 0.52. The values for x in two or more of the regions may be approximately the same, or the values for x in each of the regions may be different.

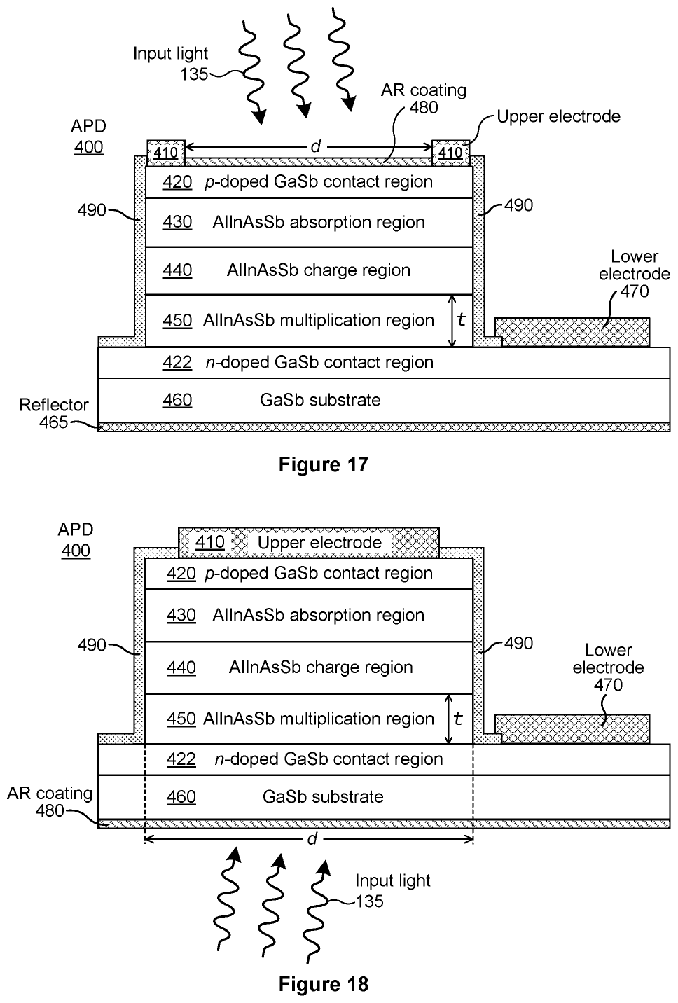

FIGS. 17 and 18 each illustrates an example avalanche photodiode 400 with an aluminum-indium-arsenide-antimonide (AlInAsSb) multiplication region 450. The APD in each of FIGS. 17-18 may be referred to as an AlInAsSb APD. The APD 400 in FIG. 17 is front-side illuminated, and the APD 400 in FIG. 18 is back-side illuminated. In each of FIGS. 17-18, the absorption region 430 includes AlₓIn₁₋ₓAs_{y}Sb_{1-y}, the charge region 440 includes AlₓIn₁₋ₓAs_{y}Sb_{1-y}, and the multiplication region 450 includes AlₓIn₁₋ₓAs_{y}Sb_{1-y}, where each of the parameters x and y may have any suitable value from 0 to 1 in each of the regions. For example, the absorption region 430 may have a composition of Al_{0.4}In_{0.6}As_{0.3}Sb_{0.7}, where the parameter x is 0.4 and the parameter y is 0.3, and the multiplication region 450 may have a composition of Al_{0.7}In_{0.3}As_{0.3}Sb_{0.7}, where the parameter x is 0.7 and the parameter y is 0.3. The values for x in two or more of the regions may be approximately the same, or the values for x in each of the regions may be different. Similarly, the values for y in two or more of the regions may be approximately the same, or the values for y in each of the regions may be different. The APD 400 in each of FIGS. 17-18 is grown on a GaSb substrate 460 and includes a GaSb contact region 420.

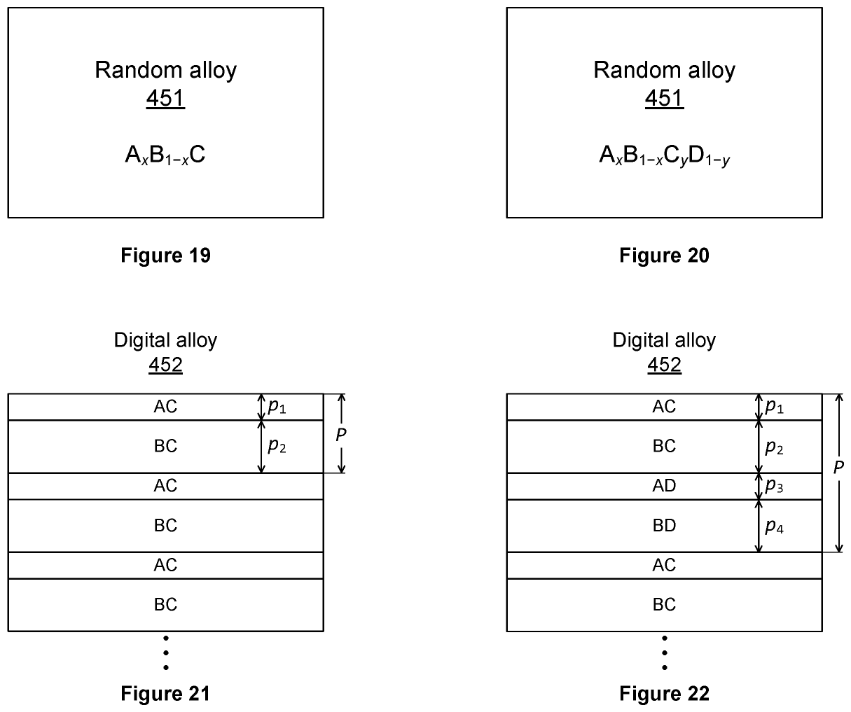

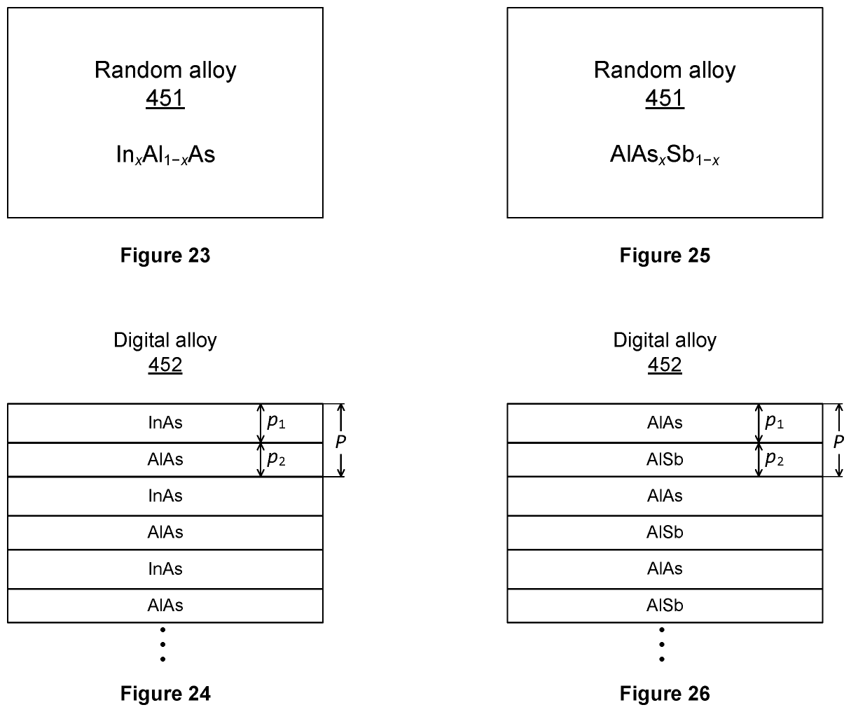

FIG. 19 illustrates an example ternary random alloy 451. The symbols A, B, and C may each represent a particular element that is part of a ternary semiconductor alloy with the composition AₓB₁₋ₓC. For example, A may represent indium (In), B may represent aluminum (Al), and C may represent arsenic (As) so that AₓB₁₋ₓC corresponds to the random semiconductor alloy InₓAl₁₋ₓAs illustrated in FIG. 23. The random alloy 451 in FIG. 19 may be part of a particular region (e.g., contact region 420 or 422, absorption region 430, charge region 440, or multiplication region 450) of an APD 400. The semiconductor alloy 451 in FIG. 19, which has three components (A, B, and C), may be referred to as a ternary semiconductor alloy. Additionally, the ternary semiconductor alloy may be a ternary random alloy 451 where at least some of the components of the alloy are distributed randomly throughout particular atomic sites of the crystal structure of the alloy. The random alloy AₓB₁₋ₓC may have a crystal structure with two distinct sets of atomic sites: each site of the first set may accommodate either component A or B, and each site of the second set may accommodate component C. In a ternary random alloy 451 with the composition AₓB₁₋ₓC, the components A and B may be distributed randomly throughout the first set of sites, while component C substantially occupies the second set of sites. For example, if the parameter x is 0.25, then approximately 25% of the first set of sites may be occupied by component A, and approximately 75% of the first set of sites may be occupied by component B, where the distribution of components A and B is substantially random throughout the first set of sites.

FIG. 20 illustrates an example quaternary random alloy 451. The symbols A, B, C, and D may each represent a particular element that is part of a quaternary semiconductor alloy with the composition AₓB₁₋ₓC_{y}D_{1-y}. For example, A may represent aluminum (Al), B may represent indium (In), C may represent arsenic (As), and D may represent antimony (Sb) so that AₓB₁₋ₓC_{y}D_{1-y} corresponds to the random semiconductor alloy AlₓIn₁₋ₓAs_{y}Sb_{1-y} illustrated in FIG. 29. The random alloy 451 in FIG. 20 may be part a of particular region (e.g., contact region 420 or 422, absorption region 430, charge region 440, or multiplication region 450) of an APD 400. The semiconductor alloy 451 in FIG. 20, which has four components (A, B, C, and D), may be referred to as a quaternary semiconductor alloy. Additionally, the quaternary semiconductor alloy may be a quaternary random alloy 451 that has a crystal structure with two distinct sets of atomic sites: each site of the first set may accommodate either component A or B, and each site of the second set may accommodate either component C or D. In a quaternary semiconductor random alloy 451, the components A and B may be distributed randomly throughout the first set of sites, and the components C and D may be distributed randomly throughout the second set of sites. For example, if a quaternary random alloy 451 has the composition A_{0.5}B_{0.5}C_{0.1}D_{0.9}, then approximately 50% of the first set of sites may be occupied by component A, and the other 50% of the first set of sites may be occupied by component B. Additionally, approximately 10% of the second set of sites may be occupied by component C, and approximately 90% of the second set of sites may be occupied by component D.

A random alloy 451 (which may be referred to as an analog alloy) may be fabricated using any suitable semiconductor growth technique, such as for example, molecular-beam epitaxy (MBE), vapor-phase epitaxy (VPE), or chemical vapor deposition (CVD). During growth of a random alloy 451, each of the components of the random alloy 451 may be flowed at a substantially constant rate, and the composition of the random alloy 451 may be determined by the particular flow rates for each of the components. The random ternary alloy AₓB₁₋ₓC from FIG. 19 may be grown on a substrate material, and the flux or flow rate of each of the components A, B, and C during the growth process may be controlled according to their relative concentration in the alloy. For example, if a random ternary alloy 451 has a composition A_{0.3}B_{0.7}C, then the flux of component A may be approximately 30% the flux of component C, and the flux of component B may be approximately 70% that of component C. Similarly, the random quaternary alloy AₓB₁₋ₓC_{y}D_{1-y} from FIG. 20 may be grown with a flux or flow rate of each of the components A, B, C, and D determined according to their relative concentration in the alloy. For example, if a random quaternary alloy 451 has a composition of A_{0.2}B_{0.8}C_{0.4}D_{0.6}, then the flux of component A may be approximately 25% the flux of component B, the flux of component C may be approximately 50% that of component B, and the flux of component D may be approximately 75% that of component B.

FIG. 21 illustrates an example ternary digital alloy 452. In contrast with a random alloy 451 in which the components of the alloy may be distributed substantially uniformly throughout the material, a digital alloy 452 may include two or more semiconductor alloy materials arranged in successive layers. The layers of a digital alloy 452 may be arranged in a repeating pattern, or the layers may be arranged in a non-repeating pattern. The digital alloy 452 in FIG. 21, which includes three components (A, B, and C), may be referred to as a ternary digital alloy 452. The three components are arranged in a repeating pattern of successive layers (AC, BC, AC, BC, etc.) that repeats after every two layers. Each layer of the digital alloy 452 in FIG. 21 includes a particular binary semiconductor alloy (AC or BC). For example, A may represent indium (In), B may represent aluminum (Al), and C may represent arsenic (As), which indicates that the ternary digital alloy 452 includes successive layers of the binary alloys InAs and AlAs (as illustrated in FIG. 24). The ellipsis located below the digital alloy 452 in FIG. 21 (as well as in FIGS. 22, 24, 26, 28, 30, and 32) indicates that the digital alloy 452 may include additional layers. For example, in addition to the three periods of the two-layer repeating pattern illustrated in FIG. 21 (where each period includes one layer of AC and one layer of BC), the ellipsis indicates that the digital alloy 452 may include additional layers based on the same repeating pattern.

FIG. 22 illustrates an example quaternary digital alloy 452. The digital alloy 452 in FIG. 22, which includes four components (A, B, C, and D), may be referred to as a quaternary digital alloy 452. Instead of distributing the four components substantially uniformly (as in the random alloy 451 of FIG. 21), the four components in the digital alloy 452 of FIG. 22 are arranged in a repeating pattern of successive layers (AC, BC, AD, BD, AC, BC, AD, BD, etc.) that repeats after every four layers. Each layer of the digital alloy includes a particular binary semiconductor alloy (AC, BC, AD, or BD). The digital alloys 452 in each of FIGS. 21-22 may be part of an APD 400. For example, each of the digital alloys 452 may be part of an absorption region 430, charge region 440, or multiplication region 450.

In particular embodiments, a digital alloy 452 may include any suitable repeating or non-repeating arrangement of layers of any suitable semiconductor material having any suitable composition. The material making up each layer may include a single element (e.g., Sb), a binary semiconductor alloy (e.g., InAs), a ternary semiconductor alloy (e.g., InAlAs), or a quaternary semiconductor alloy (e.g., AlInAsSb). The digital alloys 452 in each of FIGS. 21-22 include a repeating pattern of layers of binary semiconductor alloys. In other embodiments, each of the layers of a digital alloy 452 may include a single element, a binary semiconductor alloy, a ternary semiconductor alloy, or a quaternary semiconductor alloy. As an example, each layer of a digital alloy 452 may include a binary semiconductor alloy or a ternary semiconductor alloy. As another example, a quaternary digital alloy 452 may include four components (A, B, C, and D) arranged in the following repeating five-layer pattern: D, BC, BD, AD, AC, etc., where the layer with D corresponds to a single-element layer. As another example, a quaternary digital alloy 452 may include the following repeating three-layer pattern: ABD, BD, BCD, etc., where the layers ABD and BCD each corresponds to a ternary semiconductor alloy. Within each layer that includes a ternary or quaternary semiconductor alloy, the layer may be a random alloy having a particular composition (e.g., AₓB₁₋ₓC or AₓB₁₋ₓC_{y}D_{1-y}).

A digital alloy 452 may be fabricated using a digital-alloy growth technique, where the successive layers of the digital alloy 452 are grown using molecular-beam epitaxy (MBE). In a digital-alloy growth technique, the flux or flow rate of each of the components in a digital alloy 452 may be controlled according to the composition of each of the layers. Instead of allowing each of the components to be deposited at a constant rate (e.g., as with a random-alloy growth process), in a digital-alloy growth process, the flux of one or more of the components may be turned on or off throughout the growth process to produce the various layers of the digital alloy 452. The digital alloy 452 in FIG. 21 may be grown on a substrate material, and the flux or flow rate of each of the components A, B, C during the growth process may be controlled according to the composition of the layers AC and BC. For example, component C may be deposited with a constant flux during the growth process (e.g., a valve or shutter for component C may be open throughout the growth process), and valves or shutters for each of the components A and B may be alternately opened and closed to produce the layer AC (e.g., valve or shutter for component A open; valve or shutter for component B closed) and the layer BC (e.g., valve or shutter for component A closed; valve or shutter for component B open). For the digital alloy 452 in FIG. 22, the flux or flow rate of each of the components A, B, C, D during the growth process may be controlled to produce the layers AC, BC, AD, and BD. For example, to produce the layers AC and BC, the valve or shutter for component C may be open, the valve or shutter for component D may be closed, and the valves or shutters for components A and B may be alternately opened and closed. Similarly, to produce the layers AD and BD, the valve or shutter for component C may be closed, the valve or shutter for component D may be open, and the valves or shutters for components A and B may be alternately opened and closed.

In particular embodiments, the layers of a digital alloy 452 may have a period (P) from 2 to 30 monolayers. The period of a digital alloy 452 corresponds to a thickness of the minimum repeating pattern formed by the layers of the digital alloy 452. For example, the minimum repeating pattern of the digital alloy 452 in FIG. 21 includes two layers: layer AC and layer BC. The period P of a digital alloy 452 is the sum of the thicknesses of the layers that make up one period (e.g., P=p₁+p₂). In FIG. 22, the minimum repeating pattern includes the four layers AC, BC, AD, and BD, and the period P of the digital alloy 452 is p₁+p₂+p₃+p₄. The period P and the thickness p of a layer may be expressed in units of distance (e.g., angstroms or nanometers) or in units of monolayers. A monolayer corresponds to a single atomic layer of the crystal structure that makes up a particular layer of a digital alloy 452, and the dimension or thickness of a monolayer corresponds the thickness of the single atomic layer. For example, the layer AC in FIG. 21 may have a crystal structure with a monolayer thickness of 0.3 nm, and the layer may have a thickness p₁ of 5 monolayers, which may be expressed as a thickness p₁ of approximately 1.5 nm. As another example, each of the layers AC and BC in FIG. 21 may have a thickness of 1 monolayer, which corresponds to a period P of 2 monolayers (which may be approximately equal to 0.6 nm). As another example, the thicknesses p₁, p₂, p₃, and p₄ of the layers in FIG. 22 may be 3 monolayers, 6 monolayers, 3 monolayers, and 6 monolayers, respectively, which corresponds to a period P of 18 monolayers.

A digital alloy 452 may include any suitable number S of periods of layers (such as for example 1, 2, 5, 10, 20, 50, 100, or 200 periods), each period having a thickness P from 2 to 30 monolayers, and the overall thickness of a digital alloy 452 may be expressed as S×P. For example, layer AC in FIG. 21 may have a thickness p₁ of 2 monolayers, and layer BC may have a thickness p₂ of 4 monolayers, which corresponds to a period P of 6 monolayers. If the digital alloy 452 in FIG. 21 includes 20 periods of the two-layer pattern AC-BC, then the digital alloy 452 may have an overall thickness of 120 monolayers (e.g., S×P=20×6=120). If each monolayer has an approximate thickness of 0.5 nm, then the overall thickness of the digital alloy 452 may be expressed as 60 nm. As another example, a digital alloy 452 with 50 periods of layers, where each period has a thickness of 8 nm, may have an overall thickness of approximately 400 nm. A digital alloy 452 may have any suitable thickness, such as for example a thickness of approximately 10 nm, 50 nm, 100 nm, 200 nm, 300 nm, 500 nm, or 1,000 nm.

In particular embodiments, a digital alloy 452 may have an average composition that corresponds to an average of the compositions of the layers that make up the digital alloy 452. The average composition of a digital alloy 452 may be determined based on the composition of each layer weighted by its thickness. For example, the value of the average composition x for a particular component A of a digital alloy 452 may be expressed as x=[Σᵢ₌₁^{N}xᵢpᵢ]/P, where: N is the number of layers in one period of the digital alloy 452; P is the thickness of one period; pᵢ is the thickness of the i-th layer of the period; and xᵢ is 0 if the i-th layer does not include the component A, and xᵢ is 1 if the i-th layer includes the component A.

In the example of FIG. 21, layer AC has a thickness of p₁, and layer BC has a thickness of p₂. The total thickness of one period of the digital alloy 452 is represented by P, where P is the sum of the thicknesses of the layers that make up one period (e.g., P=p₁+p₂). The average composition of the digital alloy 452 in FIG. 21 may be expressed as AₓB₁₋ₓC, where the composition parameter x is determined based on the composition and thicknesses of each of the layers. In FIG. 21, x (the relative concentration of component A) may be expressed as p₁/P, and 1−x (the relative concentration of component B) may be expressed as p₂/P. For example, if p₁, the thickness of layer AC, is 3 nm, and p₂, the thickness of layer BC, is 6 nm, then the period P of the digital alloy 452 is 9 nm, and the average composition of the digital alloy 452 may be expressed as A_{0.33}B_{0.67}C. In the example of FIG. 22, layers AC, BC, AD, and BD have thicknesses of p₁, p₂, p₃, and p₄, respectively, and the period P of the digital alloy 452 is p₁+p₂+p₃+p₄. The average composition of the digital alloy 452 in FIG. 22 may be expressed as AₓB₁₋ₓC_{y}D_{1-y}. The value for x (the relative concentration of component A) may be expressed as (p₁+p₃)/P, and the value for 1−x (the relative concentration of component B) may be expressed as (p₂+p₄)/P. Similarly, the value for y (the relative concentration of component C) may be expressed as (p₁+p₂)/P, and the value for 1−y (the relative concentration of component D) may be expressed as (p₃+p₄)/P. For example, if the thicknesses p₁, p₂, p₃, and p₄ are 2 nm, 4 nm, 2 nm, and 4 nm, respectively (which corresponds to a period P for the digital alloy of 12 nm), then the average composition of the digital alloy 452 in FIG. 22 may be expressed as A_{0.33}B_{0.67}C_{0.5}D_{0.5}.

FIG. 23 illustrates an example InAlAs random alloy 451. The InAlAs random alloy 451, which is similar to that illustrated in FIG. 19, is a ternary random alloy that includes three components: indium (In), aluminum (Al), and arsenic (As). The InAlAs random alloy 451 may have a crystal structure with two sets of atomic sites: each site of the first set may accommodate either an In or an Al atom, and each site of the second set may accommodate an As atom. The composition of the InAlAs random alloy 451 may be expressed as InₓAl₁₋ₓAs, where the parameter x has any suitable value from 0 to 1. For example, the parameter x may have a value of 0.52 so that the composition of the random alloy 451 is In_{0.52}Al_{0.48}As. In this case, approximately 52% of the first set of atomic sites may be occupied by In atoms, and approximately 48% of the first set of atomic sites may be occupied by Al atoms. Additionally, the In and Al atoms may be distributed substantially randomly and uniformly throughout the first set of sites.

FIG. 24 illustrates an example InAlAs digital alloy 452. The InAlAs digital alloy 452, which is similar to that illustrated in FIG. 21, is a ternary digital alloy that includes three components: indium (In), aluminum (Al), and arsenic (As). The InAlAs digital alloy 452 includes a two-layer repeating pattern with alternating layers of the binary semiconductor alloys indium arsenide (InAs) and aluminum arsenide (AlAs). For example, the InAlAs digital alloy 452 may include a repeating pattern of three monolayers of InAs (p₁=3 monolayers) and three monolayers of AlAs (p₂=3 monolayers), which gives a period P of 6 monolayers. The average composition of an InAlAs digital alloy 452 may be expressed as InₓAl₁₋ₓAs, where the parameter x has any suitable value from 0 to 1. For example, an InAlAs digital alloy 452 with a repeating pattern of three monolayers of InAs and three monolayers of AlAs may be referred to as having an average composition of In_{0.5}Al_{0.5}As, where the parameter x is 0.5. An InAlAs digital alloy 452 may be fabricated using a digital-alloy growth technique in which As atoms are deposited with a constant flux during the growth process (e.g., a valve that supplies As₂ gas may be open throughout the growth process), and valves or shutters that supply In and Al are alternately opened and closed to produce the InAs and AlAs layers.

An InAlAs digital alloy 452 with an average composition of In_{0.52}Al_{0.48}As (e.g., the parameter x is 0.52) may be grown on an indium phosphide (InP) substrate. An In_{0.52}Al_{0.48}As digital alloy 452 may be approximately lattice matched to InP, which may allow the digital alloy 452 to be grown on an InP substrate without the digital alloy 452 experiencing excessive stress or strain due to lattice mismatch. For example, an APD 400 that includes a digital alloy 452 with an average composition of In_{0.52}Al_{0.48}As may include an InP substrate 460 that the APD 400 is grown on. An In_{0.52}Al_{0.48}As digital alloy 452 may be grown by providing the InAs layers with a thickness p₁ of 13 monolayers and the AlAs layers with a thickness p₂ of 12 monolayers, with equal numbers of the InAs and AlAs layers. Alternatively, to achieve an average composition of approximately In_{0.52}Al_{0.48}As, the digital alloy 452 may include (i) unequal numbers of the InAs and AlAs layers (e.g., N+1 layers of InAs and N layers of AlAs, where N is any suitable integer), (ii) one or more InAs layers with a thickness p₁ that is different from other InAs layers, (iii) one or more AlAs layers with a thickness p₂ that is different from other AlAs layers, or (iv) one or more InAs or AlAs layers with a non-integer monolayer thickness (e.g., thickness p₁ of 3.25 monolayers). For example, a digital alloy 452 with an average composition In_{0.52}Al_{0.48}As may include four layers of AlAs, each layer having a thickness of three monolayers, and four layers of InAs, three InAs layers having a thickness of three monolayers and one InAs layer having a thickness of four monolayers. As another example, a digital alloy 452 with an average composition In_{0.52}Al_{0.48}As may include InAs layers having a thickness p₁ of approximately 3.25 monolayers and AlAs layers having a thickness p₂ of approximately 3 monolayers.

FIG. 25 illustrates an example AlAsSb random alloy 451. The AlAsSb random alloy 451 is a ternary random alloy that includes three components: aluminum (Al), arsenic (As), and antimony (Sb). The AlAsSb random alloy 451 may have a crystal structure with two sets of atomic sites: each site of the first set may accommodate an Al atom, and each site of the second set may accommodate either an As or an Sb atom. The composition of the AlAsSb random alloy 451 may be expressed as AlAsₓSb₁₋ₓ, where the parameter x has any suitable value from 0 to 1. For example, the parameter x may have a value of 0.56 so that the composition of the random alloy 451 is AlAs_{0.56}Sb_{0.44}. In this case, approximately 56% of the second set of atomic sites may be occupied by As atoms, and approximately 44% of the second set of atomic sites may be occupied by Sb atoms. Additionally, the As and Sb atoms may be distributed substantially randomly and uniformly throughout the second set of sites.

FIG. 26 illustrates an example AlAsSb digital alloy 452. The AlAsSb digital alloy 452 is a ternary digital alloy that includes three components: aluminum (Al), arsenic (As), and antimony (Sb). The AlAsSb digital alloy 452 includes a two-layer repeating pattern with alternating layers of the binary semiconductor alloys aluminum arsenide (AlAs) and aluminum antimonide (AlSb). The average composition of an AlAsSb digital alloy 452 may be expressed as AlAsₓSb₁₋ₓ, where the parameter x has any suitable value from 0 to 1. For example, an AlAsSb digital alloy 452 with an average composition of AlAs_{0.56}Sb_{0.44} (e.g., the parameter x is 0.56) may be grown on an indium phosphide (InP) substrate. An AlAs_{0.56}Sb_{0.44} digital alloy 452 may be approximately lattice matched to InP, which may allow the digital alloy 452 to be grown on an InP substrate without the digital alloy 452 experiencing excessive stress or strain due to lattice mismatch. For example, an APD 400 that includes a digital alloy 452 with an average composition of AlAs_{0.56}Sb_{0.44} may include an InP substrate 460 that the APD 400 is grown on. An AlAsSb digital alloy 452 may be fabricated using a digital-alloy growth technique in which Al atoms are deposited with a constant flux during the growth process, and valves or shutters that supply As and Sb are alternately opened and closed to produce the AlAs and AlSb layers. An AlAs_{0.56}Sb_{0.44} digital alloy 452 may be grown by providing (i) unequal numbers of the AlAs and AlSb layers (e.g., N+1 layers of AlAs and N layers of AlSb, where N is any suitable integer), (ii) one or more AlAs layers with a thickness p₁ that is different from other AlAs layers, (iii) one or more AlSb layers with a thickness p₂ that is different from other AlSb layers, (iv) one or more AlAs or AlSb layers with a non-integer monolayer thickness (e.g., thickness p₁ of 7 monolayers and thickness p₂ of 5.5 monolayers), or (v) AlAs and AlSb layers each having a particular respective thickness p₁ and p₂ (e.g., thickness p₁ of 14 monolayers and thickness p₂ of 11 monolayers).

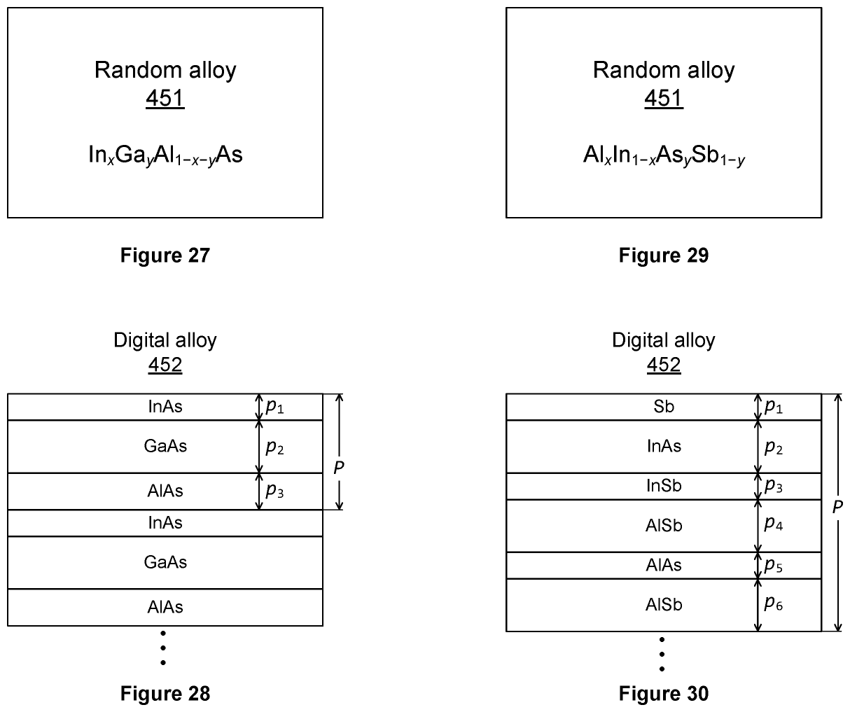

FIG. 27 illustrates an example InGaAlAs random alloy 451. The InGaAlAs random alloy 451 is a quaternary random alloy that includes four components: indium (In), gallium (Ga), aluminum (Al), and arsenic (As). The InGaAlAs random alloy 451 may have a crystal structure with two sets of atomic sites: each site of the first set may accommodate an In atom, Ga atom, or Al atom, and each site of the second set may accommodate an As atom. The composition of the InGaAlAs random alloy 451 may be expressed as InₓGa_{y}Al_{1-x-y}As, where each of the parameters x and y has a value from 0 to 1 with the constraint that x+y is less than 1. For example, the parameters x and y may have respective values 0.52 and 0.24 so that the composition of the random alloy 451 is In_{0.52}Ga_{0.24}Al_{0.24}As. In this case, the In, Ga, and Al atoms may be distributed substantially randomly throughout the first set of atomic sites, with approximately 52% of the first set of sites occupied by In atoms, approximately 24% of the first set of sites occupied by Ga atoms, and approximately 24% of the first set of sites occupied by Al atoms.

FIG. 28 illustrates an example InGaAlAs digital alloy 452. The InGaAlAs digital alloy 452 is a quaternary digital alloy that includes four components: indium (In), gallium (Ga), aluminum (Al), and arsenic (As). The InGaAlAs digital alloy 452 has a three-layer repeating pattern that includes layers of the binary semiconductor alloys indium arsenide (InAs), gallium arsenide (GaAs), and aluminum arsenide (AlAs). The average composition of an InGaAlAs digital alloy 452 may be expressed as InₓGa_{y}Al_{1-x-y}As, where each of the parameters x and y has a value from 0 to 1 with the constraint that x+y is less than 1. For example, the parameters x and y may have respective values 0.52 and 0.24 so that the average composition of the digital alloy 452 is In_{0.52}Ga_{0.24}Al_{0.24}As. An InGaAlAs digital alloy 452 may be fabricated using a digital-alloy growth technique in which As atoms are deposited with a constant flux during the growth process, and valves or shutters that supply In, Ga, and Al are alternately opened and closed to produce the InAs, GaAs, and AlAs layers.

FIG. 29 illustrates an example AlInAsSb random alloy 451. The AlInAsSb random alloy 451, which is similar to that illustrated in FIG. 20, is a quaternary random alloy that includes four components: aluminum (Al), indium (In), arsenic (As), and antimony (Sb). The AlInAsSb random alloy 451 may have a crystal structure with two sets of atomic sites: each site of the first set may accommodate an Al atom or In atom, and each site of the second set may accommodate an As atom or Sb atom. The composition of the AlInAsSb random alloy 451 may be expressed as AlₓIn₁₋ₓAs_{y}Sb_{1-y}, where each of the parameters x and y has a value from 0 to 1. For example, the parameters x and y may have respective values 0.8 and 0.3 so that the composition of the random alloy 451 is Al_{0.8}In_{0.2}As_{0.3}Sb_{0.7}. In this case, the Al and In atoms may be distributed substantially randomly throughout the first set of atomic sites with approximately 80% of the first set of sites occupied by Al atoms and approximately 20% of the first set of sites occupied by In atoms. Additionally, the As and Sb atoms may be distributed substantially randomly throughout the second set of atomic sites with approximately 30% of the second set of sites occupied by As atoms and approximately 70% of the second set of sites occupied by Sb atoms.

FIG. 30 illustrates an example AlInAsSb digital alloy 452. The AlInAsSb digital alloy 452 is a quaternary digital alloy that includes four components: aluminum (Al), indium (In), arsenic (As), and antimony (Sb). The AlInAsSb digital alloy 452 has a six-layer repeating pattern that includes layers of the binary semiconductor alloys aluminum arsenide (AlAs), aluminum antimonide (AlSb), indium arsenide (InAs), and indium antimonide (InSb) along with one layer of antimony (Sb). An AlInAsSb digital alloy 452 may include any suitable combination of layers arranged in any suitable sequence. The six-layer sequence of layers that make up one period of the digital alloy 452 in FIG. 30 is AlSb, AlAs, AlSb, InSb, InAs, Sb. The average composition of an AlInAsSb digital alloy 452 may be expressed as AlₓIn₁₋ₓAs_{y}Sb_{1-y}, where each of the parameters x and y has a value from 0 to 1. In particular embodiments, the parameter x may have a value from 0.7 to 1.0. For example, the parameters x and y may have respective values 0.73 and 0.2 so that the average composition of the digital alloy 452 is Al_{0.73}In_{0.27}As_{0.2}Sb_{0.8}. As another example, the parameters x and y may have respective values 0.8 and 0.23 so that the average composition of the digital alloy 452 is Al_{0.8}In_{0.2}As_{0.23}Sb_{0.77}. An AlInAsSb digital alloy 452 may be fabricated using a digital-alloy growth technique in which valves or shutters that supply each of the four components, Al, In, As, and Sb, are alternately opened and closed to produce layers that include one or more of AlAs, AlSb, InAs, InSb, and Sb. For example, to grow the three-layer sequence AlSb, AlAs, AlSb in FIG. 30, a valve or shutter that supplies In may be closed, a valve or shutter that supplies Al may be open, and valves or shutters that supply Sb and As may be alternately opened and closed. In particular embodiments, an AlInAsSb digital alloy 452 may be grown on a GaSb substrate. For example, an APD 400 that includes an AlInAsSb digital alloy 452 may include a GaSb substrate 460 that the APD 400 is grown on.

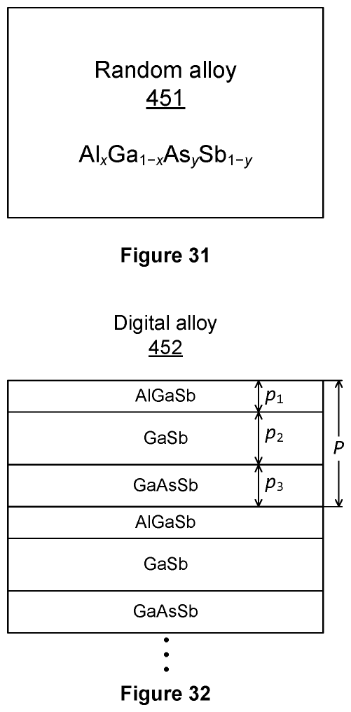

FIG. 31 illustrates an example AlGaAsSb random alloy 451. The AlGaAsSb random alloy 451, which is similar to that illustrated in FIG. 20, is a quaternary random alloy that includes four components: aluminum (Al), gallium (Ga), arsenic (As), and antimony (Sb). The AlGaAsSb random alloy 451 may have a crystal structure with two sets of atomic sites: each site of the first set may accommodate an Al atom or Ga atom, and each site of the second set may accommodate an As atom or Sb atom. The composition of the AlInAsSb random alloy 451 may be expressed as AlₓGa₁₋ₓAs_{y}Sb_{1-y}, where each of the parameters x and y has a value from 0 to 1. For example, the parameters x and y may have respective values 0.85 and 0.56 so that the composition of the random alloy 451 is Al_{0.85}Ga_{0.15}As_{0.56}Sb_{0.44}. In this case, the Al and Ga atoms may be distributed substantially randomly throughout the first set of atomic sites with approximately 85% of the first set of atomic sites occupied by Al atoms and approximately 15% of the first set of atomic sites occupied by Ga atoms. Additionally, the As and Sb atoms may be distributed substantially randomly throughout the second set of atomic sites with approximately 56% of the second set of sites occupied by As atoms and approximately 44% of the second set of sites occupied by Sb atoms.

FIG. 32 illustrates an example AlGaAsSb digital alloy 452. The AlGaAsSb digital alloy 452 is a quaternary digital alloy that includes four components: aluminum (Al), gallium (Ga), arsenic (As), and antimony (Sb). The AlGaAsSb digital alloy 452 has a three-layer repeating pattern that includes one layer of the binary semiconductor alloy gallium antimonide (GaSb) and one layer of each of the ternary semiconductor alloys aluminum gallium antimonide (AlₓGa₁₋ₓSb) and gallium arsenide antimonide (GaAsₓSb₁₋ₓ). The AlGaAsSb digital alloy 452 is a digital alloy where each layer of the digital alloy includes either a binary semiconductor alloy or a ternary semiconductor alloy. In other embodiments, an AlGaAsSb digital alloy 452 may include layers with two or more of the following binary semiconductor alloys (and no ternary semiconductor alloys): AlAs, AlSb, GaAs, and GaSb. The average composition of an AlGaAsSb digital alloy 452 may be expressed as AlₓGa₁₋ₓAs_{y}Sb_{1-y}, where each of the parameters x and y has a value from 0 to 1. For example, the parameters x and y may have respective values 0.85 and 0.56 so that the average composition of the digital alloy 452 is Al_{0.85}Ga_{0.15}As_{0.56}Sb_{0.44}. An AlAsSb digital alloy 452 with an average composition of Al_{0.85}Ga_{0.15}As_{0.56}Sb_{0.44} may be grown on an indium phosphide (InP) substrate. An Al_{0.85}Ga_{0.15}As_{0.56}Sb_{0.44} digital alloy 452 may be approximately lattice matched to InP. The AlGaAsSb digital alloy 452 in FIG. 32 may be fabricated using a digital-alloy growth technique in which Ga and Sb atoms are both deposited throughout the growth process, and valves or shutters that supply Al and As are alternately opened and closed to produce the AlGaSb, GaSb, and GaAsSb layers.

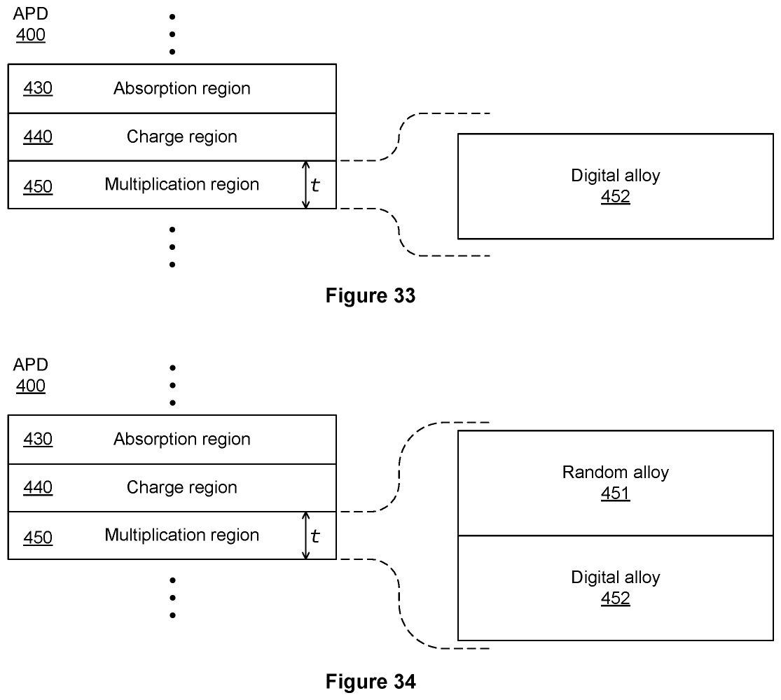

FIG. 33 illustrates an example avalanche photodiode 400 with a multiplication region 450 that includes a digital alloy 452. In particular embodiments, an APD 400 may include a multiplication region 450 that includes a digital alloy 452. In the example APD 400 of FIG. 33, the multiplication region 450 includes a digital alloy 452, and the APD 400 also includes an absorption region 430 and a charge region 440. The ellipses located above and below the APD 400 in FIG. 33 (as well as in FIGS. 34-40) indicate that, in addition to the absorption region 430, charge region 440, and multiplication region 450, the APD 400 may include additional layers or regions that are omitted for clarity. For example, the APD 400 in FIG. 33 (or any of FIGS. 34-40) may include a p-doped contact region 420, an n-doped contact region 422, an upper electrode 410, a lower electrode 470, a substrate 460, a passivation layer 490, an intrinsic region 425, a reflector 465, an AR coating 480, or any other suitable layer or region.

In particular embodiments, a multiplication region 450 of an APD 400 may include (i) one or more digital alloys 452 or (ii) any suitable combination of one or more random alloys 451 and one or more digital alloys 452. For example, the multiplication region 450 of an APD 400 illustrated in FIGS. 11-18 and described herein may include one or more digital alloys 452 or any suitable combination of one or more random alloys 451 and one or more digital alloys 452. A digital alloy 452 that is part of a multiplication region 450 of an APD 400 may (i) receive at least a portion of photogenerated electronic carriers produced in an absorption region 430 and (ii) produce at least a portion of a photocurrent signal i, where the portion of the photocurrent signal i is produced by impact ionization that is initiated by the electronic carriers received from the absorption region 430. A multiplication region 450 may include any suitable digital alloy 452, such as for example: an InAlAs digital alloy 452 (e.g., as illustrated in FIG. 24), an AlAsSb digital alloy 452 (e.g., as illustrated in FIG. 26), an InGaAlAs digital alloy 452 (e.g., as illustrated in FIG. 28), an AlInAsSb digital alloy 452 (e.g., as illustrated in FIG. 30), an AlGaAsSb digital alloy 452 (e.g., as illustrated in FIG. 32), or any other suitable digital alloy 452. As used herein, a digital-alloy region may refer to a region of an APD 400 that includes a digital alloy 452, and the terms digital-alloy region and digital alloy may be used interchangeably. For example, the multiplication region 450 in FIG. 33 may be referred to as including a digital-alloy region or a digital alloy 452. As used herein, a random-alloy region may refer to a region of an APD 400 that includes a random alloy 451, and the terms random-alloy region and random alloy may be used interchangeably.

FIG. 34 illustrates an example avalanche photodiode 400 with a multiplication region 450 that includes a random alloy 451 and a digital alloy 452. The APD 400 in FIG. 34 includes an absorption region 430, a charge region 440, and a multiplication region 450 that includes a random alloy 451 and a digital alloy 452, and the APD is configured so that the random alloy 451 is located closer to the absorption region 430 than the digital alloy 452. Additionally, the multiplication region 450 may be configured so that the band gap of the random alloy 451 is greater than the band gap of the digital alloy 452.

For a multiplication region 450 that includes two or more materials having two or more different band gaps, most of the impact-ionization events associated with the multiplication region 450 may occur within the material having the lowest band gap. A material with the lowest band gap (of two or more materials) has the lowest energy gap between its valance and conduction bands, which may correspond to that material having the lowest impact-ionization threshold energy required to produce carriers through impact ionization. For example, in FIG. 34, a greater energy or electric field may be required to initiate impact ionization in the higher-band-gap random alloy 451 than in the lower-band-gap digital alloy 452. As a result, most of the electrons or holes produced in the absorption region 430 that drift toward the multiplication region 450 may move through the random alloy 451 without initiating significant impact ionization (e.g., due to the higher band gap of the random alloy 451), and the impact-ionization events may occur mostly in the lower-band-gap digital alloy region 452 of the multiplication region 450. The lower-band-gap digital alloy 452 in FIG. 34 may be referred to as a high-ionization-rate material relative to the higher-band-gap random alloy 451, and most of the carriers (e.g., greater than 80% of the carriers) produced through impact ionization in the multiplication region 450 of the APD 400 may be produced in the digital alloy 452. The lower-band-gap digital alloy 452 in FIG. 34 may be referred to as an impact-ionization region that (i) receives a portion of the photogenerated electronic carriers produced in the absorption region 430 (e.g., electrons or holes that drift toward the multiplication region 450) and (ii) produces additional electronic carriers by impact ionization, where the impact ionization is initiated by the photogenerated carriers received from the absorption region 430. The additional electronic carriers produced in the digital alloy 452 by impact ionization may be part of a photocurrent signal i produced by the APD 400 in response to a received input optical signal 135. For example, the photocurrent i may include (i) at least a portion of the photogenerated carriers produced in the absorption region 430 and (ii) at least a portion of the additional electronic carriers produced by impact ionization in the digital alloy 452 of the multiplication region 450.

The random alloy 451 and the digital alloy 452 in FIG. 34 may be made from different materials (e.g., InGaAs and InAlAs) or may be made from the same material having different compositions (e.g., InAl₁₋ₓAs with different values for the x parameter). The materials or compositions may be selected so that the band gap of the random alloy 451 is greater than the band gap of the digital alloy 452. For example, the random alloy 451 may have a composition of In_{0.4}Al_{0.6}As (with a band gap of approximately 1.7 eV), and the digital alloy 452 may have an average composition of In_{0.52}Al_{0.48}As (with a band gap of less than 1.55 eV). Alternatively, the random alloy 451 and the digital alloy 452 in FIG. 34 may have compositions that are approximately equal. In general, a random alloy 451 with a particular composition may have a greater band gap than a digital alloy 452 having an average composition that is approximately the same as the particular composition of the random alloy 451. For example, the random alloy 451 in FIG. 34 may have a composition of In_{0.52}Al_{0.48}As (with a band gap of approximately 1.55 eV), and the digital alloy 452 may have an average composition of In_{0.52}Al_{0.48}As (with a band gap of less than 1.55 eV).

Two materials may be referred to as having approximately equal compositions if they include the same materials (e.g., In, Al, and As) and their respective x values (and y values, if applicable) are within 5% of each other. For example, two InₓAl₁₋ₓAs random alloys 451 with x-parameter values of 0.53 and 0.51 may be referred to as having approximately the same composition. The two x-parameter values are within 5% of each other since they differ by approximately 4%. Similarly, two InₓAl₁₋ₓAs digital alloys 452 with x-parameter values of 0.53 and 0.51 may be referred to as having approximately the same average composition. Additionally, an InₓAl₁₋ₓAs random alloy 451 and an InₓAl₁₋ₓAs digital alloy 452 with respective x-parameter values of 0.53 and 0.51 may be referred to as having approximately the same composition.

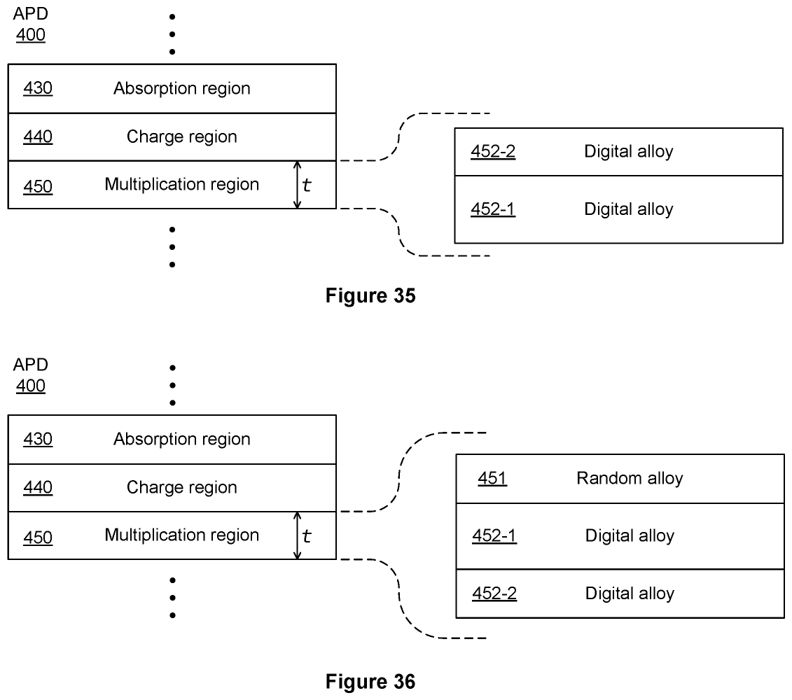

FIG. 35 illustrates an example avalanche photodiode 400 with a multiplication region 450 that includes two digital alloys (452-1, 452-2). The APD 400 in FIG. 35 includes an absorption region 430, a charge region 440, and a multiplication region 450 that includes a first digital alloy 452-1 and a second digital alloy 452-2, and the APD 400 is configured so that the second digital alloy 452-2 is located closer to the absorption region 430 than the first digital alloy 452-1. Additionally, the multiplication region 450 may be configured so that the band gap of the second digital alloy 452-2 is greater than the band gap of the first digital alloy 452-1. Since the first digital alloy 452-1 has a lower band gap than the second digital alloy 452-2, most of the impact-ionization events associated with the multiplication region 450 may occur within the first digital alloy 452-1. Most of the electrons or holes produced in the absorption region 430 that drift toward the multiplication region 450 may move through the second digital alloy 452-2 without initiating significant impact ionization (e.g., due to the higher band gap of the second digital alloy 452-2), and the impact-ionization events may occur mostly in the lower-band-gap first digital alloy 452-1 of the multiplication region 450. The first digital alloy 452-1 in FIG. 35 may be referred to as an impact-ionization region that (i) receives a portion of the photogenerated electronic carriers produced in the absorption region 430 and (ii) produces additional electronic carriers by impact ionization. The additional electronic carriers produced in the first digital alloy 452-1 by impact ionization may be part of a photocurrent signal i produced by the APD 400 in response to a received input optical signal 135.

The first digital alloy 452-1 and the second digital alloy 452-2 in FIG. 35 may be made from different materials or may be made from the same material having different compositions. The materials or compositions may be selected so that the band gap of the first digital alloy 452-1 is less than the band gap of the second digital alloy 452-2. Alternatively, the first digital alloy 452-1 and the second digital alloy 452-2 may have average compositions that are approximately equal, and the period P₁ of the layers of the first digital-alloy region 452-1 may be greater than the period P₂ of the layers of the second digital-alloy region 452-2 (e.g., P₁>P₂). In general, the band gap of a digital alloy 452 may depend, at least in part, on the period P of the digital alloy 452, and a larger period may correspond to a smaller band gap. In the embodiment where (i) the two digital alloys have approximately the same average composition and (ii) P₁>P₂, the band gap of the first digital alloy 452-1 may be less than the band gap of the second digital alloy 452-2. For example, the two digital alloys may each include an InAlAs digital alloy 452 similar to that of FIG. 24, where the period of the first digital alloy 452-1 is 10 monolayers, and the period of the second digital alloy 452-2 is six monolayers. Providing a digital alloy 452 with a larger period may include increasing a thickness of one or more of the layers of the digital alloy 452. For example, the first digital alloy 452-1 (with a 10-monolayer period) may have InAs and AlAs layers each with a thickness of five monolayers, and the second digital alloy 452-2 (with a six-monolayer period) may have InAs and AlAs layers each with a thickness of three monolayers.

FIG. 36 illustrates an example avalanche photodiode 400 with a multiplication region 450 that includes a random alloy 451 and two digital alloys (452-1, 452-2). The APD 400 in FIG. 36 includes an absorption region 430, a charge region 440, and a multiplication region 450 that includes a first digital alloy 452-1, a second digital alloy 452-2, and a random alloy 451. The multiplication region 450 is configured so that the first digital alloy 452-1 is disposed between the random alloy 451 and the second digital alloy 452-2. Additionally, the multiplication region 450 may be configured so that the band gap of the first digital alloy 452-1 is less than the band gaps of the random alloy 451 and the second digital alloy 452-2. The multiplication region 450 in FIG. 36 forms a three-region sandwich structure in which the middle region (digital alloy 452-1) has a band gap that is less than the band gap of each of the two outer regions (random alloy 451 and digital alloy 452-2). The lower band gap of the first digital alloy 452-1 may provide a lower-energy potential well with the higher-band-gap materials on either side forming an energy barrier. The first digital alloy 452-1 may (i) receive at least a portion of photogenerated carriers produced in the absorption region 430 and (ii) produce additional carriers by impact ionization that is initiated by the electronic carriers received from the absorption region 430. Most of the electrons or holes produced in the absorption region 430 that drift toward the multiplication region 450 may move through the random alloy 451 without initiating significant impact ionization (e.g., due to the higher band gap of the random alloy 451), and the impact-ionization events that produce additional carriers may occur mostly in the low-band-gap first digital alloy 452-1 of the multiplication region 450. In FIG. 36, the random alloy 451 is located closer to the absorption region 430 than the second digital alloy 452-2. In other embodiments, the locations of the random alloy 451 and the second digital alloy 452-2 may be reversed so that the second digital alloy 452-2 is located closer to the absorption region 430 than the random alloy 451.

The first digital alloy 452-1, second digital alloy 452-2, and random alloy 451 in FIG. 36 may be made from different materials or may be made from the same material having different compositions. The materials or compositions may be selected so that the band gap of the first digital alloy 452-1 is less than the band gaps of the random alloy 451 and the second digital alloy 452-2. Alternatively, the first digital alloy 452-1 and the second digital alloy 452-2 may have average compositions that are approximately equal, and the period P₁ of the layers of the first digital-alloy region 452-1 may be greater than the period P₂ of the layers of the second digital-alloy region 452-2 (e.g., P₁>P₂). With this configuration, the band gap of the first digital alloy 452-1 may be less than the band gap of the second digital alloy 452-2. Additionally, the random alloy 451 may have a composition that is approximately the same as the average composition of the first and second digital alloys so that the band gap of the first digital alloy 452-1 is less than the band gap of the random alloy 451.

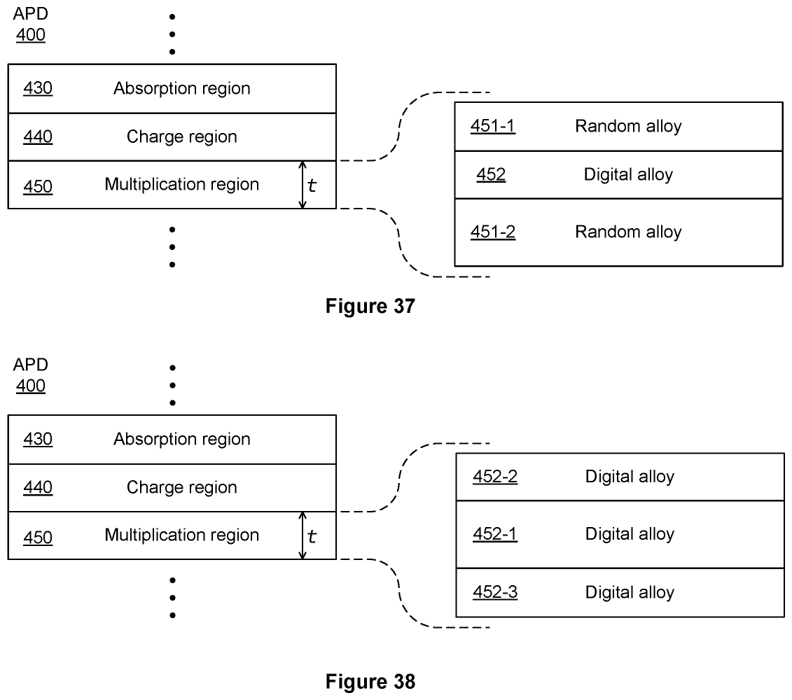

FIG. 37 illustrates an example avalanche photodiode 400 with a multiplication region 450 that includes a digital alloy 452 and two random alloys (451-1, 451-2). The APD 400 in FIG. 37 includes an absorption region 430, a charge region 440, and a multiplication region 450 that includes a digital alloy 452, a first random alloy 451-1, and a second random alloy 451-2. The multiplication region 450 is configured so that the digital alloy 452 is disposed between the two random alloys 451-1 and 451-2. Additionally, the multiplication region 450 may be configured so that the band gap of the digital alloy 452 is less than the band gaps of the first random alloy 451-1 and the second random alloy 451-2. The multiplication region 450 in FIG. 37 forms a three-region sandwich structure in which the middle region (digital alloy 452) has a band gap that is less than the band gap of each of the two outer regions (random alloys 451-1 and 451-2). The lower band gap of the digital alloy 452 may provide a lower-energy potential well with the higher-band-gap materials on either side forming an energy barrier. The digital alloy 452 may (i) receive at least a portion of photogenerated carriers produced in the absorption region 430 and (ii) produce additional carriers by impact ionization that is initiated by the electronic carriers received from the absorption region 430. Most of the electrons or holes produced in the absorption region 430 that drift toward the multiplication region 450 may move through the random alloy 451-1 without initiating significant impact ionization (e.g., due to the higher band gap of the random alloy 451-1), and the impact-ionization events that produce additional carriers may occur mostly in the low-band-gap digital alloy 452 of the multiplication region 450.

The digital alloy 452, first random alloy 451-1, and second random alloy 451-2 in FIG. 37 may be made from different materials or may be made from the same material having different compositions. The materials or compositions may be selected so that the band gap of the digital alloy 452 is less than the band gaps of the two random alloys 451-1 and 451-2. Alternatively, the digital alloy 452 may have an average composition that is approximately equal to the composition of the two random alloys 451-2 and 451-2. With this equal-composition configuration, the band gap of the digital alloy 452 may be less than the band gaps of the two random alloys 451-1 and 451-2. For example, the digital alloy 452 may be an AlAsSb digital alloy (e.g., similar to that illustrated in FIG. 26) with an average composition of AlAs_{0.56}Sb_{0.44}. Additionally, the random alloys 451-1 and 451-2 may each include an AlAsSb random alloy (e.g., similar to that illustrated in FIG. 25) with approximately the same composition AlAs_{0.56}Sb_{0.44}. As another example, the digital alloy 452 and the random alloys 451-1 and 451-2 may each include an InAlAs alloy (e.g., similar to that illustrated in FIGS. 23 and 24) with a composition of In_{0.52}Al_{0.48}As.

FIG. 38 illustrates an example avalanche photodiode 400 with a multiplication region 450 that includes three digital alloys (452-1, 452-2, 452-3). The APD 400 in FIG. 38 includes an absorption region 430, a charge region 440, and a multiplication region 450 that includes a first digital alloy 452-1, a second digital alloy 452-2, and a third digital alloy 452-3. The multiplication region 450 is configured so that the first digital alloy 452-1 is disposed between the two digital alloys 452-2 and 452-3. Additionally, the multiplication region 450 may be configured so that the band gap of the first digital alloy 452-1 is less than the band gaps of the other two digital alloys 452-2 and 452-3. The multiplication region 450 in FIG. 38 forms a three-region sandwich structure in which the middle region (digital alloy 452-1) has a band gap that is less than the band gap of each of the two outer regions (digital alloys 452-2 and 452-3). The lower band gap of the first digital alloy 452-1 may provide a lower-energy potential well with the higher-band-gap digital alloys on either side forming an energy barrier. The first digital alloy 452-1 may (i) receive at least a portion of photogenerated carriers produced in the absorption region 430 and (ii) produce additional carriers by impact ionization that is initiated by the electronic carriers received from the absorption region 430. Most of the electrons or holes produced in the absorption region 430 that drift toward the multiplication region 450 may move through the digital alloy 452-2 without initiating significant impact ionization (e.g., due to the higher band gap of the digital alloy 452-2), and the impact-ionization events that produce additional carriers may occur mostly in the low-band-gap first digital alloy 452-1 of the multiplication region 450.

The digital alloys 452-1, 452-2, and 452-3 in FIG. 38 may be made from different materials or may be made from the same material having different compositions. The materials or compositions may be selected so that the band gap of the first digital alloy 452-1 is less than the band gaps of the other two digital alloys 452-2 and 452-3. Alternatively, the digital alloys 452-1, 452-2, and 452-3 may have average compositions that are approximately equal, and the period Pi of the layers of the first digital-alloy region 452-1 may be greater than the respective periods P₂ and P₃ of the layers of the other two digital alloys 452-2 and 452-3 (e.g., P₁>P₂ and P₁>P₃). With this equal-composition configuration where P₁ is greater than P₂ and P₃, the band gap of the first digital alloy 452-1 may be less than the band gaps of the other two digital alloys 452-2 and 452-3. For example, the digital alloys 452-1, 452-2, and 452-3 may be AlAsSb digital alloys with an average composition of AlAs_{0.56}Sb_{0.44}, where the period of the first digital alloy 452-1 is greater than the period of the other two digital alloys 452-2 and 452-3. As another example, the digital alloys 452-1, 452-2, and 452-3 may be InAlAs digital alloys with an average composition of In_{0.52}Al_{0.48}As, and the first digital alloy 452-1 may have an 8-monolayer period, while each of the digital alloys 452-2 and 452-3 may have a 4-monolayer period.

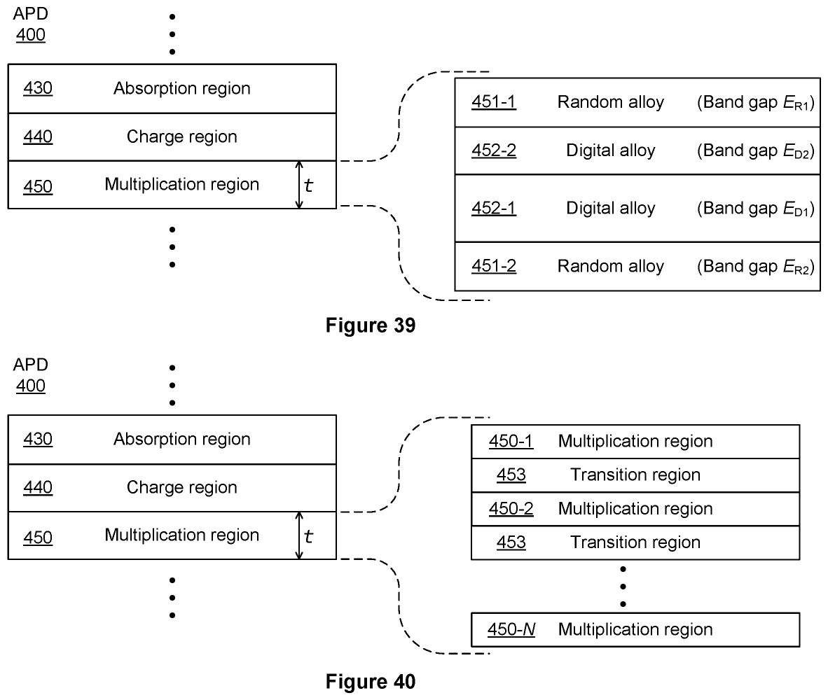

FIG. 39 illustrates an example avalanche photodiode 400 with a multiplication region 450 that includes two random alloys (451-1, 451-2) and two digital alloys (452-1, 452-2). The APD 400 in FIG. 39 includes an absorption region 430, a charge region 440, and a multiplication region 450 that includes a first digital alloy 452-1, a second digital alloy 452-2, a first random alloy 451-1, and a second random alloy 451-2. The multiplication region 450 is configured as a four-region structure with (i) digital alloy 452-2 disposed between random alloy 451-1 and digital alloy 452-1 and (ii) digital alloy 452-1 disposed between digital alloy 452-2 and random alloy 451-2. The regions are arranged with the random alloy 451-2 located farthest from the absorption region 430 and the random alloy 451-1 located closest to the absorption region 430 and with the regions disposed in the following order: second random alloy 451-2, first digital alloy 452-1, second digital alloy 452-2, and first random alloy 451-1. Additionally, the multiplication region 450 may be configured so that: the band gap (E_{D2}) of the second digital alloy 452-2 is less than the band gap (E_{R1}) of the first random alloy 451-1, the band gap (E_{D1}) of the first digital alloy 452-1 is less than the band gap (E_{D2}) of the second digital alloy 452-2, and the band gap (E_{R2}) of the second random alloy 451-2 is greater than the band gap (E_{D1}) of the first digital alloy 452-1. This configuration of the band gaps may be expressed by the inequalities E_{D1}<E_{D2}<E_{R1} and E_{D1}<E_{R2}. The first digital alloy 452-1, which has the lowest band gap of the four regions, provides a low-energy potential well with the regions on either side forming an energy barrier. Additionally, the three regions 451-1, 452-2, and 452-1 form a graded well with the random alloy 451-1 having the highest band gap, the digital alloy 452-2 having a lower band gap, and the digital alloy 452-1 forming a well with the lowest band gap. The first digital alloy 452-1 may (i) receive at least a portion of photogenerated carriers produced in the absorption region 430 and (ii) produce additional carriers by impact ionization that is initiated by the electronic carriers received from the absorption region 430. Most of the electrons or holes produced in the absorption region 430 that drift toward the multiplication region 450 may move through the random alloy 451-1 and the digital alloy 452-2 without initiating significant impact ionization (e.g., due to the higher band gaps of those regions), and the impact-ionization events that produce additional carriers may occur mostly in the low-band-gap first digital alloy 452-1 of the multiplication region 450.

The digital alloys 452-1 and 452-2 and random alloys 451-1 and 451-2 in FIG. 39 may be made from different materials or may be made from the same material having different compositions. The materials or compositions may be selected so that the band gaps of the four regions satisfy the inequalities E_{D1}<E_{D2}<E_{R1} and E_{D1}<E_{R2}. Alternatively, the digital alloys 452-1 and 452-2 may have average compositions that are approximately equal, and the period P₁ of the layers of the first digital-alloy region 452-1 may be greater than the period P₂ of the layers of the second digital-alloy region 452-2 (e.g., P₁>P₂). With this configuration, the band gap (E_{D1}) of the first digital alloy 452-1 may be less than the band gap (E_{D2}) of the second digital alloy 452-2. Additionally, the composition of the random alloys 451-1 and 451-2 may be approximately the same as the average composition of the two digital alloys 452-1 and 452-2. With this configuration, the band gap (E_{D2}) of the second digital alloy 452-2 may be less than the band gap (E_{R1}) of the first random alloy 451-1, and the band gap (E_{R2}) of the second random alloy 451-2 may be greater than the band gap (E_{D1}) of the first digital alloy 452-1. For example, the digital alloys 452-1 and 452-2 and random alloys 451-1 and 451-2 may each have of a composition of In_{0.52}Al_{0.48}As. Additionally, the first digital alloy 452-1 may have a 10-monolayer period (e.g., InAs and AlAs layers each with a thickness of five monolayers), and the second digital alloy 452-2 may have a 6-monolayer period (e.g., InAs and AlAs layers each with a thickness of three monolayers).

FIG. 40 illustrates an example avalanche photodiode 400 with multiple cascaded multiplication regions (450-1, 450-2, . . . , 450-N). In particular embodiments, an APD 400 may include a multiplication region 450 that includes two or more sub-multiplication regions (450-1, 450-2, etc.) that are disposed in series. The APD 400 in FIG. 40 includes an absorption region 430, a charge region 440, and a multiplication region 450 that includes N sub-multiplication regions. Each of the multiplication regions 450-1, 450-2, and 450-N in FIG. 40 may be referred to as a sub-multiplication region to distinguish it from the multiplication region 450. The multiplication region 450 in FIG. 40 includes multiple sub-multiplication regions with a transition region 453 located between each pair of adjacent sub-multiplication regions. The multiplication region 450 includes N sub-multiplication regions (and N−1 transition regions 453), where N is any suitable integer greater than or equal to 2. For example, an APD 400 may include a multiplication region 450 with 2, 3, 4, 5, 10, or any other suitable number of sub-multiplication regions. A multiplication region 450 that includes multiple sub-multiplication regions may be referred to as a cascaded multiplication region or a cascaded gain stage.

Each of the sub-multiplication regions (450-1, 450-2, etc.) of a multiplication region 450 may include a digital alloy 452. For example, one or more of the sub-multiplication regions 450-1, 450-2, and 450-N in FIG. 40 may include (i) one or more digital alloys 452 or (ii) any suitable combination of one or more random alloys 451 and one or more digital alloys 452. As another example, one of more of the sub-multiplication regions 450-1, 450-2, and 450-N may be configured similar to a multiplication region 450 illustrated in any of FIGS. 33-39. As another example, each of the sub-multiplication regions 450-1, 450-2, and 450-N may have a three-region sandwich structure similar to the multiplication region 450 illustrated in FIG. 36, 37, or 38.

The APD 400 in FIG. 40 may produce a photocurrent signal i in response to a received input optical signal 135. Each of the sub-multiplication regions in a cascaded multiplication region 450 may produce a portion of the photocurrent signal i by impact ionization. For example, sub-multiplication region 450-1 may include a digital alloy 452 that (i) receives a portion of photogenerated electronic carriers produced in the absorption region 430 (e.g., electrons or holes that drift toward the multiplication region 450) and (ii) produces additional electronic carriers by impact ionization, where the impact ionization is initiated by the photogenerated carriers received from the absorption region 430. Additionally, sub-multiplication region 450-2 may include a digital alloy 452 that (i) receives a portion of the photogenerated electronic carriers produced in the absorption region 430 or a portion of the additional electronic carriers produced in sub-multiplication region 450-1 and (ii) produces additional electronic carriers by impact ionization. This process of cascaded impact-ionization events may continue in each of the N sub-multiplication regions, with a digital alloy 452 of each sub-multiplication region producing a portion of the photocurrent signal i by impact ionization.

The transition regions 453 of a cascaded multiplication region 450 may provide a buffer or a separation between each pair of adjacent sub-multiplication regions. For example, in an APD 400 where impact-ionization events in the multiplication region 450 are primarily initiated by electrons, a transition region 453 located between a pair of adjacent sub-multiplication regions may include a hole-relaxation layer that reduces the kinetic energy of secondary holes that move into the transition region 453. Alternatively, in an APD 400 where impact-ionization events are primarily initiated by holes, a transition region 453 may include an electron-relaxation layer that reduces the kinetic energy of secondary electrons that move into the transition region 453.

The multiplication region 450 of an APD 400 may have any suitable thickness t, such as for example, a thickness t between approximately 100 nm and approximately 2,000 nm. For example, in FIG. 38, the multiplication region 450 may have a thickness t of approximately 1,000 nm (e.g., the first digital alloy 452-1 may have a thickness of approximately 300 nm, and each of the digital alloys 452-2 and 452-3 may have a thickness of approximately 350 nm). As another example, the multiplication region 450 may have a thickness t of approximately 300 nm (e.g., each of the digital alloys 452-1, 452-2, and 452-3 may have a thickness of approximately 100 nm).

An APD 400 as described or illustrated herein (e.g., an APD that includes a multiplication region 450 with (i) one or more digital alloys 452 or (ii) one or more random alloys 451 and one or more digital alloys 452) may be referred to as a low-noise APD, a digital-alloy APD, an APD with a digital-alloy multiplication region 450, or an APD utilizing impact ionization in a digital alloy 452. A digital-alloy APD 400 may include a multiplication region 450 with a digital alloy 452, where the digital alloy 452 (i) receives a portion of photogenerated electronic carriers produced in the absorption region 430 (e.g., electrons or holes that drift toward the multiplication region 450) and (ii) produces additional electronic carriers by impact ionization. In particular embodiments, a lidar system 100 with a receiver 140 that includes an APD 400 with a digital-alloy multiplication region 450 may exhibit improved performance compared to a lidar system that uses another type of APD (e.g., an APD with a multiplication layer that does not include a digital alloy). As an example, a digital-alloy APD 400 may operate with a lower excess noise factor or with a higher gain than another type of APD.

A digital-alloy APD 400 as described or illustrated herein may operate with an excess noise factor (ENF) of less than three. Excess noise (which may be referred to as gain noise or multiplication noise) may refer to electrical noise associated with the avalanche-multiplication process that includes impact ionization in the multiplication region 450 of the APD 400. The ENF represents an amount of increase in the statistical noise (e.g., shot noise) associated with the avalanche-multiplication process in an APD 400. The ENF may depend, at least in part, on the ratio of the rates at which electrons and holes initiate impact ionization in the multiplication region 450 of the APD. The ratio of the rates, which may be referred to as an impact-ionization ratio (represented by k), may be expressed as a ratio of hole-ionization rate (Rₕ) over the electron-ionization rate (Rₑ), or vice versa. In an APD 400 in which electrons are the primary electronic carrier (and electrons are the primary initiator of impact ionization), the impact-ionization ratio may be expressed as k=Rₕ/Rₑ. Conversely, in an APD 400 in which holes are the primary electronic carrier (and holes are the primary initiator of impact ionization), the impact-ionization ratio may be expressed as k=Rₑ/Rₕ. In either case, the impact-ionization ratio k is a value from 0 to 1, and the lower the value of k, the lower the ENF of an APD 400. For example, an APD 400 with an ENF of less than three may have a value of k that is less than 0.1. In general, a multiplication region 450 with a digital alloy 452 that produces carriers by impact ionization exhibits a lower value of k than a multiplication region that does not include a digital alloy (e.g., a multiplication region that includes one or more random alloys). As a result, a digital-alloy APD 400 may have a relatively low ENF as compared to an APD with a multiplication region that does not include a digital alloy. For example, a digital-alloy APD 400 (that includes a multiplication region 450 with (i) one or more digital alloys 452 or (ii) one or more random alloys 451 and one or more digital alloys 452) may have an ENF of less than three, while an APD with a multiplication region that includes one or more random alloys (and no digital alloys) may have an ENF of greater than five.

A digital-alloy APD 400 as described or illustrated herein may operate with a gain of greater than four. The gain of an APD 400 may correspond to the average number of carriers generated by impact ionization from a single photogenerated carrier. For example, a digital-alloy APD 400 may operate with a gain of between approximately 4 and 30. As another example, a digital-alloy APD 400 with a cascaded multiplication region 450 (e.g., as illustrated in FIG. 40) may operate with a gain of between approximately 10 and 60. As another example, a digital-alloy APD 400 may operate with a gain of between approximately 4 and 30 and an ENF of less than three. The reduced ENF provided by a digital-alloy APD 400 may alloy the APD to operate with higher gain as compared to an APD with a multiplication region that does not include a digital alloy. Additionally, this increased front-end gain provided by the digital-alloy APD 400 may reduce the gain required in a TIA 510 or electronic amplifier 511 that follows the APD 400 or may allow the TIA 510 or electronic amplifier 511 to be operated at a higher bandwidth.

In particular embodiments, an APD 400 may include an absorption region 430 that includes a first region and a second region, where the band gap of the first region is greater than the band gap of the second region. Having an absorption region 430 that includes two or more regions with two or more respective band gaps may produce a graded band gap throughout the absorption region 430 that may assist in the transport of photogenerated carriers. The first region (with the greater band gap) may be a random alloy 451, and the second region (with the smaller band gap) may be a digital alloy 452. Alternatively, the first and second regions may both be digital alloys 452 with average compositions that are approximately equal, and the period of the layers of the second region may be greater than the period of the layers of the first region.

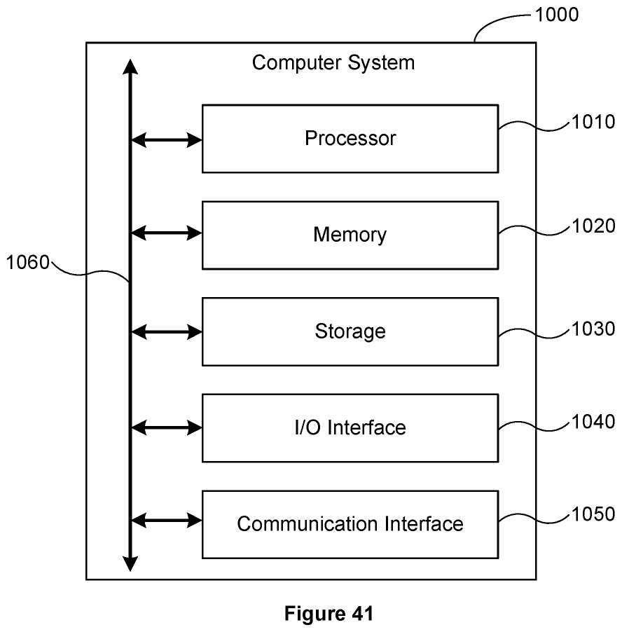

FIG. 41 illustrates an example computer system 1000. In particular embodiments, one or more computer systems 1000 may perform one or more steps of one or more methods described or illustrated herein. In particular embodiments, one or more computer systems 1000 may provide functionality described or illustrated herein. In particular embodiments, software running on one or more computer systems 1000 may perform one or more steps of one or more methods described or illustrated herein or may provide functionality described or illustrated herein. Particular embodiments may include one or more portions of one or more computer systems 1000. In particular embodiments, a computer system may be referred to as a processor, a controller, a computing device, a computing system, a computer, a general-purpose computer, or a data-processing apparatus. Herein, reference to a computer system may encompass one or more computer systems, where appropriate.

Computer system 1000 may take any suitable physical form. As an example, computer system 1000 may be an embedded computer system, a system-on-chip (SOC), a single-board computer system (SBC), a desktop computer system, a laptop or notebook computer system, a mainframe, a mesh of computer systems, a server, a tablet computer system, or any suitable combination of two or more of these. As another example, all or part of computer system 1000 may be combined with, coupled to, or integrated into a variety of devices, including, but not limited to, a camera, camcorder, personal digital assistant (PDA), mobile telephone, smartphone, electronic reading device (e.g., an e-reader), game console, smart watch, clock, calculator, television monitor, flat-panel display, computer monitor, vehicle display (e.g., odometer display or dashboard display), vehicle navigation system, lidar system, ADAS, autonomous vehicle, autonomous-vehicle driving system, cockpit control, camera view display (e.g., display of a rear-view camera in a vehicle), eyewear, or head-mounted display. Where appropriate, computer system 1000 may include one or more computer systems 1000; be unitary or distributed; span multiple locations; span multiple machines; span multiple data centers; or reside in a cloud, which may include one or more cloud components in one or more networks. Where appropriate, one or more computer systems 1000 may perform without substantial spatial or temporal limitation one or more steps of one or more methods described or illustrated herein. As an example, one or more computer systems 1000 may perform in real time or in batch mode one or more steps of one or more methods described or illustrated herein. One or more computer systems 1000 may perform at different times or at different locations one or more steps of one or more methods described or illustrated herein, where appropriate.

As illustrated in the example of FIG. 41, computer system 1000 may include a processor 1010, memory 1020, storage 1030, an input/output (I/O) interface 1040, a communication interface 1050, or a bus 1060. Computer system 1000 may include any suitable number of any suitable components in any suitable arrangement.

In particular embodiments, processor 1010 may include hardware for executing instructions, such as those making up a computer program. As an example, to execute instructions, processor 1010 may retrieve (or fetch) the instructions from an internal register, an internal cache, memory 1020, or storage 1030; decode and execute them; and then write one or more results to an internal register, an internal cache, memory 1020, or storage 1030. In particular embodiments, processor 1010 may include one or more internal caches for data, instructions, or addresses. Processor 1010 may include any suitable number of any suitable internal caches, where appropriate. As an example, processor 1010 may include one or more instruction caches, one or more data caches, or one or more translation lookaside buffers (TLBs). Instructions in the instruction caches may be copies of instructions in memory 1020 or storage 1030, and the instruction caches may speed up retrieval of those instructions by processor 1010. Data in the data caches may be copies of data in memory 1020 or storage 1030 for instructions executing at processor 1010 to operate on; the results of previous instructions executed at processor 1010 for access by subsequent instructions executing at processor 1010 or for writing to memory 1020 or storage 1030; or other suitable data. The data caches may speed up read or write operations by processor 1010. The TLBs may speed up virtual-address translation for processor 1010. In particular embodiments, processor 1010 may include one or more internal registers for data, instructions, or addresses. Processor 1010 may include any suitable number of any suitable internal registers, where appropriate. Where appropriate, processor 1010 may include one or more arithmetic logic units (ALUs); may be a multi-core processor; or may include one or more processors 1010.

In particular embodiments, memory 1020 may include main memory for storing instructions for processor 1010 to execute or data for processor 1010 to operate on. As an example, computer system 1000 may load instructions from storage 1030 or another source (such as, for example, another computer system 1000) to memory 1020. Processor 1010 may then load the instructions from memory 1020 to an internal register or internal cache. To execute the instructions, processor 1010 may retrieve the instructions from the internal register or internal cache and decode them. During or after execution of the instructions, processor 1010 may write one or more results (which may be intermediate or final results) to the internal register or internal cache. Processor 1010 may then write one or more of those results to memory 1020. One or more memory buses (which may each include an address bus and a data bus) may couple processor 1010 to memory 1020. Bus 1060 may include one or more memory buses. In particular embodiments, one or more memory management units (MMUs) may reside between processor 1010 and memory 1020 and facilitate accesses to memory 1020 requested by processor 1010. In particular embodiments, memory 1020 may include random access memory (RAM). This RAM may be volatile memory, where appropriate. Where appropriate, this RAM may be dynamic RAM (DRAM) or static RAM (SRAM). Memory 1020 may include one or more memories 1020, where appropriate.

In particular embodiments, storage 1030 may include mass storage for data or instructions. As an example, storage 1030 may include a hard disk drive (HDD), a floppy disk drive, flash memory, an optical disc, a magneto-optical disc, magnetic tape, or a Universal Serial Bus (USB) drive or a combination of two or more of these. Storage 1030 may include removable or non-removable (or fixed) media, where appropriate. Storage 1030 may be internal or external to computer system 1000, where appropriate. In particular embodiments, storage 1030 may be non-volatile, solid-state memory. In particular embodiments, storage 1030 may include read-only memory (ROM). Where appropriate, this ROM may be mask ROM (MROM), programmable ROM (PROM), erasable PROM (EPROM), electrically erasable PROM (EEPROM), flash memory, or a combination of two or more of these. Storage 1030 may include one or more storage control units facilitating communication between processor 1010 and storage 1030, where appropriate. Where appropriate, storage 1030 may include one or more storages 1030.

In particular embodiments, I/O interface 1040 may include hardware, software, or both, providing one or more interfaces for communication between computer system 1000 and one or more I/O devices. Computer system 1000 may include one or more of these I/O devices, where appropriate. One or more of these I/O devices may enable communication between a person and computer system 1000. As an example, an I/O device may include a keyboard, keypad, microphone, monitor, mouse, printer, scanner, speaker, camera, stylus, tablet, touch screen, trackball, another suitable I/O device, or any suitable combination of two or more of these. An I/O device may include one or more sensors. Where appropriate, I/O interface 1040 may include one or more device or software drivers enabling processor 1010 to drive one or more of these I/O devices. I/O interface 1040 may include one or more I/O interfaces 1040, where appropriate.

In particular embodiments, communication interface 1050 may include hardware, software, or both providing one or more interfaces for communication (such as, for example, packet-based communication) between computer system 1000 and one or more other computer systems 1000 or one or more networks. As an example, communication interface 1050 may include a network interface controller (NIC) or network adapter for communicating with an Ethernet or other wire-based network or a wireless NIC (WNIC); a wireless adapter for communicating with a wireless network, such as a WI-FI network; or an optical transmitter (e.g., a laser or a light-emitting diode) or an optical receiver (e.g., a photodetector) for communicating using fiber-optic communication or free-space optical communication. Computer system 1000 may communicate with an ad hoc network, a personal area network (PAN), an in-vehicle network (IVN), a local area network (LAN), a wide area network (WAN), a metropolitan area network (MAN), or one or more portions of the Internet or a combination of two or more of these. One or more portions of one or more of these networks may be wired or wireless. As an example, computer system 1000 may communicate with a wireless PAN (WPAN) (such as, for example, a BLUETOOTH WPAN), a WI-FI network, a Worldwide Interoperability for Microwave Access (WiMAX) network, a cellular telephone network (such as, for example, a Global System for Mobile Communications (GSM) network), or other suitable wireless network or a combination of two or more of these. As another example, computer system 1000 may communicate using fiber-optic communication based on 100 Gigabit Ethernet (100 GbE), 10 Gigabit Ethernet (10 GbE), or Synchronous Optical Networking (SONET). Computer system 1000 may include any suitable communication interface 1050 for any of these networks, where appropriate. Communication interface 1050 may include one or more communication interfaces 1050, where appropriate.

In particular embodiments, bus 1060 may include hardware, software, or both coupling components of computer system 1000 to each other. As an example, bus 1060 may include an Accelerated Graphics Port (AGP) or other graphics bus, a controller area network (CAN) bus, an Enhanced Industry Standard Architecture (EISA) bus, a front-side bus (FSB), a HYPERTRANSPORT (HT) interconnect, an Industry Standard Architecture (ISA) bus, an INFINIBAND interconnect, a low-pin-count (LPC) bus, a memory bus, a Micro Channel Architecture (MCA) bus, a Peripheral Component Interconnect (PCI) bus, a PCI-Express (PCIe) bus, a serial advanced technology attachment (SATA) bus, a Video Electronics Standards Association local bus (VLB), or another suitable bus or a combination of two or more of these. Bus 1060 may include one or more buses 1060, where appropriate.

In particular embodiments, various modules, circuits, systems, methods, or algorithm steps described in connection with the implementations disclosed herein may be implemented as electronic hardware, computer software, or any suitable combination of hardware and software. In particular embodiments, computer software (which may be referred to as software, computer-executable code, computer code, a computer program, computer instructions, or instructions) may be used to perform various functions described or illustrated herein, and computer software may be configured to be executed by or to control the operation of computer system 1000. As an example, computer software may include instructions configured to be executed by processor 1010. In particular embodiments, owing to the interchangeability of hardware and software, the various illustrative logical blocks, modules, circuits, or algorithm steps have been described generally in terms of functionality. Whether such functionality is implemented in hardware, software, or a combination of hardware and software may depend upon the particular application or design constraints imposed on the overall system.

In particular embodiments, a computing device may be used to implement various modules, circuits, systems, methods, or algorithm steps disclosed herein. As an example, all or part of a module, circuit, system, method, or algorithm disclosed herein may be implemented or performed by a general-purpose single- or multi-chip processor, a digital signal processor (DSP), an ASIC, a FPGA, any other suitable programmable-logic device, discrete gate or transistor logic, discrete hardware components, or any suitable combination thereof. A general-purpose processor may be a microprocessor, or, any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

In particular embodiments, one or more implementations of the subject matter described herein may be implemented as one or more computer programs (e.g., one or more modules of computer-program instructions encoded or stored on a computer-readable non-transitory storage medium). As an example, the steps of a method or algorithm disclosed herein may be implemented in a processor-executable software module which may reside on a computer-readable non-transitory storage medium. In particular embodiments, a computer-readable non-transitory storage medium may include any suitable storage medium that may be used to store or transfer computer software and that may be accessed by a computer system. Herein, a computer-readable non-transitory storage medium or media may include one or more semiconductor-based or other integrated circuits (ICs) (such, as for example, field-programmable gate arrays (FPGAs) or application-specific ICs (ASICs)), hard disk drives (HDDs), hybrid hard drives (HHDs), optical discs (e.g., compact discs (CDs), CD-ROM, digital versatile discs (DVDs), blu-ray discs, or laser discs), optical disc drives (ODDs), magneto-optical discs, magneto-optical drives, floppy diskettes, floppy disk drives (FDDs), magnetic tapes, flash memories, solid-state drives (SSDs), RAM, RAM-drives, ROM, SECURE DIGITAL cards or drives, any other suitable computer-readable non-transitory storage media, or any suitable combination of two or more of these, where appropriate. A computer-readable non-transitory storage medium may be volatile, non-volatile, or a combination of volatile and non-volatile, where appropriate.

In particular embodiments, certain features described herein in the context of separate implementations may also be combined and implemented in a single implementation. Conversely, various features that are described in the context of a single implementation may also be implemented in multiple implementations separately or in any suitable sub-combination. Moreover, although features may be described above as acting in certain combinations and even initially claimed as such, one or more features from a claimed combination may in some cases be excised from the combination, and the claimed combination may be directed to a sub-combination or variation of a sub-combination.

While operations may be depicted in the drawings as occurring in a particular order, this should not be understood as requiring that such operations be performed in the particular order shown or in sequential order, or that all operations be performed. Further, the drawings may schematically depict one more example processes or methods in the form of a flow diagram or a sequence diagram. However, other operations that are not depicted may be incorporated in the example processes or methods that are schematically illustrated. For example, one or more additional operations may be performed before, after, simultaneously with, or between any of the illustrated operations. Moreover, one or more operations depicted in a diagram may be repeated, where appropriate. Additionally, operations depicted in a diagram may be performed in any suitable order. Furthermore, although particular components, devices, or systems are described herein as carrying out particular operations, any suitable combination of any suitable components, devices, or systems may be used to carry out any suitable operation or combination of operations. In certain circumstances, multitasking or parallel processing operations may be performed. Moreover, the separation of various system components in the implementations described herein should not be understood as requiring such separation in all implementations, and it should be understood that the described program components and systems may be integrated together in a single software product or packaged into multiple software products.

Various embodiments have been described in connection with the accompanying drawings. However, it should be understood that the figures may not necessarily be drawn to scale. As an example, distances or angles depicted in the figures are illustrative and may not necessarily bear an exact relationship to actual dimensions or layout of the devices illustrated.

The scope of this disclosure encompasses all changes, substitutions, variations, alterations, and modifications to the example embodiments described or illustrated herein that a person having ordinary skill in the art would comprehend. The scope of this disclosure is not limited to the example embodiments described or illustrated herein. Moreover, although this disclosure describes or illustrates respective embodiments herein as including particular components, elements, functions, operations, or steps, any of these embodiments may include any combination or permutation of any of the components, elements, functions, operations, or steps described or illustrated anywhere herein that a person having ordinary skill in the art would comprehend.

The term “or” as used herein is to be interpreted as an inclusive or meaning any one or any combination, unless expressly indicated otherwise or indicated otherwise by context. Therefore, herein, the expression “A or B” means “A, B, or both A and B.” As another example, herein, “A, B or C” means at least one of the following: A; B; C; A and B; A and C; B and C; A, B and C. An exception to this definition will occur if a combination of elements, devices, steps, or operations is in some way inherently mutually exclusive.

As used herein, words of approximation such as, without limitation, “approximately, “substantially,” or “about” refer to a condition that when so modified is understood to not necessarily be absolute or perfect but would be considered close enough to those of ordinary skill in the art to warrant designating the condition as being present. The extent to which the description may vary will depend on how great a change can be instituted and still have one of ordinary skill in the art recognize the modified feature as having the required characteristics or capabilities of the unmodified feature. In general, but subject to the preceding discussion, a numerical value herein that is modified by a word of approximation such as “approximately” may vary from the stated value by ±0.5%, ±1%, ±2%, ±3%, ±4%, ±5%, ±10%, ±12%, or ±15%. The term “substantially constant” refers to a value that varies by less than a particular amount over any suitable time interval. For example, a value that is substantially constant may vary by less than or equal to 20%, 10%, 1%, 0.5%, or 0.1% over a time interval of approximately 10⁴ s, 10³ s, 10² s, 10 s, 1 s, 100 ms, 10 ms, 1 ms, 100 μs, 10 μs, or 1 μs. The term “substantially constant” may be applied to any suitable value, such as for example, an optical power, a pulse repetition frequency, an electrical current, a wavelength, an optical or electrical frequency, or an optical or electrical phase.

As used herein, the terms “first,” “second,” “third,” etc. may be used as labels for nouns that they precede, and these terms may not necessarily imply a particular ordering (e.g., a particular spatial, temporal, or logical ordering). As an example, a system may be described as determining a “first result” and a “second result,” and the terms “first” and “second” may not necessarily imply that the first result is determined before the second result.

As used herein, the terms “based on” and “based at least in part on” may be used to describe or present one or more factors that affect a determination, and these terms may not exclude additional factors that may affect a determination. A determination may be based solely on those factors which are presented or may be based at least in part on those factors. The phrase “determine A based on B” indicates that B is a factor that affects the determination of A. In some instances, other factors may also contribute to the determination of A. In other instances, A may be determined based solely on B.

What is claimed is:

1. A lidar system comprising:
a light source configured to emit an optical signal;
a receiver configured to detect an input optical signal comprising a portion of the emitted optical signal scattered by a target located a distance from the lidar system, wherein:
the receiver comprises an avalanche photodiode (APD) configured to receive the input optical signal and produce a photocurrent signal corresponding to the input optical signal, wherein the APD comprises a multiplication region that comprises a digital-alloy region comprising two or more semiconductor alloy materials arranged in successive layers, wherein the digital-alloy region is configured to produce at least a portion of the photocurrent signal by impact ionization; and
the receiver is configured to determine, based on the photocurrent signal produced by the APD, a round-trip time for the portion of the emitted optical signal to travel from the lidar system to the target and back to the lidar system; and
a processor configured to determine the distance from the lidar system to the target based on the round-trip time.

2. The lidar system of claim 1, wherein:
the APD further comprises an absorption region configured to absorb at least a portion of the input optical signal and produce electronic carriers corresponding to the absorbed portion of the input optical signal; and
the multiplication region further comprises a random-alloy region, wherein:
a band gap of the random-alloy region is greater than a band gap of the digital-alloy region; and
the random-alloy region is located closer to the absorption region than the digital-alloy region.

3. The lidar system of claim 1, wherein:
the APD further comprises an absorption region configured to absorb at least a portion of the input optical signal and produce electronic carriers corresponding to the absorbed portion of the input optical signal; and
the digital-alloy region is a first digital-alloy region, and the multiplication region further comprises a second digital-alloy region, wherein:
a band gap of the second digital-alloy region is greater than a band gap of the first digital-alloy region; and
the second digital-alloy region is located closer to the absorption region than the first digital-alloy region.

4. The lidar system of claim 3, wherein:
the first digital-alloy region and the second digital-alloy region have average compositions that are approximately equal; and
a period of the layers of the first digital-alloy region is greater than a period of layers of the second digital-alloy region.

5. The lidar system of claim 1, wherein the digital-alloy region is a first digital-alloy region, and the multiplication region further comprises a random-alloy region and a second digital-alloy region, wherein:
the first digital-alloy region is disposed between the random-alloy region and the second digital-alloy region; and
a band gap of the first digital-alloy region is less than band gaps of the random-alloy region and the second digital-alloy region.

6. The lidar system of claim 5, wherein:
the first digital-alloy region and the second digital-alloy region have average compositions that are approximately equal; and
a period of the layers of the first digital-alloy region is greater than a period of layers of the second digital-alloy region.

7. The lidar system of claim 1, wherein the multiplication region further comprises a first random-alloy region and a second random alloy region, wherein:
the digital-alloy region is disposed between the first and second random-alloy regions; and
a band gap of the digital-alloy region is less than band gaps of the first and second random-alloy regions.

8. The lidar system of claim 7, wherein an average composition of the digital-alloy region is approximately equal to compositions of the first and second random-alloy regions.

9. The lidar system of claim 1, wherein the digital-alloy region is a first digital-alloy region, and the multiplication region further comprises a second digital-alloy region and a third digital-alloy region, wherein:
the first digital-alloy region is disposed between the second and third digital-alloy regions; and
a band gap of the first digital-alloy region is less than band gaps of the second and third digital-alloy regions.

10. The lidar system of claim 9, wherein:
the first, second, and third digital-alloy regions have average compositions that are approximately equal; and
a period of the layers of the first digital-alloy region is greater than periods of layers of the second and third digital-alloy regions.

11. The lidar system of claim 1, wherein the digital-alloy region is a first digital-alloy region, and the multiplication region further comprises a second digital-alloy region, a first random-alloy region, and a second random-alloy region, wherein:
the second digital-alloy region is disposed between the first random-alloy region and the first digital-alloy region;
the first digital-alloy region is disposed between the second digital-alloy region and the second random-alloy region;
a band gap of the second digital-alloy region is less than a band gap of the first random-alloy region;
a band gap of the first digital-alloy region is less than the band gap of the second digital-alloy region; and
a band gap of the second random-alloy region is greater than the band gap of the first digital-alloy region.

12. The lidar system of claim 11, wherein:
the first digital-alloy region and the second digital-alloy region have average compositions that are approximately equal; and
a period of the layers of the first digital-alloy region is greater than a period of layers of the second digital-alloy region.

13. The lidar system of claim 1, wherein the multiplication region is a first multiplication region, and the APD further comprises one or more additional multiplication regions disposed in series, wherein each of the additional multiplication regions comprises an additional digital-alloy region configured to produce an additional portion of the photocurrent signal.

14. The lidar system of claim 1, wherein the digital-alloy region is an indium-aluminum-arsenide (InAlAs) digital-alloy region, wherein:
each layer of the digital-alloy region comprises one of the semiconductor alloy materials, wherein the semiconductor alloy materials comprise indium arsenide (InAs) and aluminum arsenide (AlAs); and
the digital-alloy region has an average composition InAl₁₋ₓAs, wherein x has a value from 0 to 1.

15. The lidar system of claim 14, wherein the value of x is 0.52 and the average composition of the digital-alloy region is In_{0.52}Al_{0.48}As, and wherein the APD is grown on an indium phosphide (InP) substrate.

16. The lidar system of claim 1, wherein the digital-alloy region is an indium-gallium-aluminum-arsenide (InGaAlAs) digital-alloy region, wherein:
each layer of the digital-alloy region comprises one of the semiconductor alloy materials, wherein the semiconductor alloy materials comprise indium arsenide (InAs), gallium arsenide (GaAs), and aluminum arsenide (AlAs); and
the digital-alloy region has an average composition InₓGa_{y}Al_{1-x-y}As, wherein x and y each has a value from 0 to 1 and x+y is less than 1.

17. The lidar system of claim 1, wherein the digital-alloy region is an aluminum-arsenide-antimonide (AlAsSb) digital-alloy region, wherein:
each layer of the digital-alloy region comprises one of the semiconductor alloy materials, wherein the semiconductor alloy materials comprise aluminum arsenide (AlAs) and aluminum antimonide (AlSb); and
the digital-alloy region has an average composition AlAsₓSb₁₋ₓ, wherein x has a value from 0 to 1.

18. The lidar system of claim 17, wherein the value of x is 0.56 and the average composition of the digital-alloy region is AlAs_{0.56}Sb_{0.44}, and wherein the APD is grown on an indium phosphide (InP) substrate.

19. The lidar system of claim 1, wherein the digital-alloy region is an aluminum-gallium-arsenide-antimonide (AlGaAsSb) digital-alloy region, wherein:
each layer of the digital-alloy region comprises one of the semiconductor alloy materials, wherein the semiconductor alloy materials comprise aluminum gallium antimonide (AlGaSb), gallium antimonide (GaSb), and gallium arsenide antimonide (GaAsSb); and
the digital-alloy region has an average composition AlₓGa₁₋ₓAs_{y}Sb_{1-y}, wherein x and y each has a value from 0 to 1.

20. The lidar system of claim 1, wherein the digital-alloy region is an aluminum-indium-arsenide-antimonide (AlInAsSb) digital-alloy region, wherein:
each layer of the digital-alloy region comprises one of the semiconductor alloy materials, wherein the semiconductor alloy materials comprise aluminum arsenide (AlAs), aluminum antimonide (AlSb), indium arsenide (InAs), and indium antimonide (InSb); and
the digital-alloy region has an average composition AlₓIn₁₋ₓAs_{y}Sb_{1-y}, wherein x and y each has a value from 0 to 1.

21. The lidar system of claim 20, wherein the value of x is greater than or equal to 0.7.

22. The lidar system of claim 20, wherein:
the digital-alloy region further comprises one or more layers comprising antimony (Sb);
a sequence of the layers of the AlInAsSb digital-alloy region comprises: AlSb, AlAs, AlSb, InSb, InAs, Sb; and
the APD is grown on a gallium antimonide (GaSb) substrate.

23. The lidar system of claim 1, wherein the APD further comprises:
an absorption region configured to absorb at least a portion of the input optical signal and produce electronic carriers corresponding to the absorbed portion of the input optical signal;
a substrate material located at or near a first end of the APD, wherein the substrate material is transparent to light at a wavelength of the input optical signal and is configured to receive the input optical signal and convey the input optical signal toward the absorption region;
an anti-reflection (AR) coating disposed on an exterior surface of the substrate material, the AR coating configured to reduce a reflectivity of the surface of the substrate material at the wavelength of the input optical signal; and
a reflective material located at or near a second end of the APD opposite the first end, wherein the reflective material is configured to receive a portion of the input optical signal that propagates through the APD from the first end to the second end and reflect the portion of the input optical signal back through the APD toward the absorption region.

24. The lidar system of claim 1, wherein the digital-alloy region has an average composition corresponding to an average of compositions of the layers of the semiconductor alloy materials.

25. The lidar system of claim 1, wherein each layer of the digital-alloy region comprises a binary semiconductor alloy or a ternary semiconductor alloy.

26. The lidar system of claim 1, wherein the APD further comprises an absorption region configured to absorb at least a portion of the input optical signal and produce electronic carriers corresponding to the absorbed portion of the input optical signal, the absorption region comprising a first region and a second region, wherein a band gap of the first region is greater than a band gap of the second region.

27. The lidar system of claim 26, wherein the first region is a random-alloy region, and the second region is a digital-alloy region.

28. The lidar system of claim 26, wherein the first and second regions are digital-alloy regions having approximately equal average compositions, and a period of layers of the second digital-alloy region is greater than a period of layers of the first digital-alloy region.

29. The lidar system of claim 1, wherein:
the APD further comprises an absorption region configured to absorb at least a portion of the input optical signal and produce electronic carriers corresponding to the absorbed portion of the input optical signal, the electronic carriers comprising electrons and holes; and
the digital-alloy region is an impact-ionization region configured to receive a portion of the electronic carriers from the absorption region and produce additional electronic carriers by impact ionization, wherein the portion of the photocurrent signal produced by the digital-alloy region comprises the additional electronic carriers produced by impact ionization.

30. The lidar system of claim 1, wherein the APD is fabricated using a digital-alloy growth technique, wherein the successive layers of the semiconductor alloy materials are grown using molecular-beam epitaxy (MBE).

31. The lidar system of claim 1, wherein the layers of the digital-alloy region have a period from 2 to 30 monolayers.

32. The lidar system of claim 1, wherein the APD is configured to operate with an excess noise factor of less than three.

33. The lidar system of claim 1, wherein the APD is configured to operate with a gain of greater than four.

34. The lidar system of claim 1, wherein the receiver further comprises a voltage source configured to supply a reverse-bias voltage of greater than 20 volts to the APD.

35. The lidar system of claim 1, wherein the APD is configured to detect light having one or more wavelengths between 900 nanometers (nm) and 2000 nm.

36. The lidar system of claim 1, wherein the APD has a mesa structure.

37. The lidar system of claim 1, wherein the APD has a planar structure.

38. The lidar system of claim 1, wherein:
the emitted optical signal comprises a pulse of light;
the input optical signal comprises a received pulse of light comprising a portion of the emitted pulse of light scattered by the target;
the photocurrent signal comprises a pulse of electrical current; and
the receiver further comprises a transimpedance amplifier configured to amplify the pulse of electrical current to produce a voltage pulse that corresponds to the pulse of electrical current.

39. The lidar system of claim 38, wherein the receiver further comprises:
one or more comparators, wherein each comparator is configured to produce an electrical-edge signal when the voltage pulse rises above or falls below a particular threshold voltage; and
one or more time-to-digital converters (TDCs), wherein each TDC is coupled to one of the comparators and is configured to produce a time value corresponding to a time when the electrical-edge signal was received by the TDC, wherein the round-trip time is determined based at least in part on one or more time values produced by one or more of the TDCs.

40. The lidar system of claim 38, wherein the receiver further comprises:
a voltage amplifier configured to amplify the voltage pulse to produce an amplified voltage pulse;
one or more comparators, wherein each comparator is configured to produce an electrical-edge signal when the amplified voltage pulse rises above or falls below a particular threshold voltage; and
one or more time-to-digital converters (TDCs), wherein each TDC is coupled to one of the comparators and is configured to produce a time value corresponding to a time when the electrical-edge signal was received by the TDC, wherein the round-trip time is determined based at least in part on one or more time values produced by one or more of the TDCs.

41. An avalanche photodiode (APD) configured to receive an input optical signal and produce a photocurrent signal corresponding to the input optical signal, the APD comprising:
an absorption region configured to absorb at least a portion of the input optical signal and produce electronic carriers corresponding to the absorbed portion of the input optical signal, the electronic carriers comprising electrons and holes; and
a multiplication region comprising a digital-alloy region that comprises two or more semiconductor alloy materials arranged in successive layers, wherein the digital-alloy region is configured to receive a portion of the electronic carriers from the absorption region and produce additional electronic carriers by impact ionization, wherein the photocurrent signal comprises at least a portion of the additional electronic carriers.
